(19) United States
(12) Patent Application Publication
(10) Pub. No.: US 2023/0152652 A1
(43) Pub. Date: May 18, 2023

(54) IDENTIFYING, REDUCING HEALTH RISKS, AND TRACKING OCCUPANCY IN A FACILITY

(71) Applicant: View, Inc., Milpitas, CA (US)

(72) Inventors: Nitesh Trikha, Pleasanton, CA (US); Rao P. Mulpuri, Saratoga, CA (US); Anurag Gupta, San Jose, CA (US); Tanya Makker, Milpitas, CA (US); Emily Puth, Pleasanton, CA (US); Keivan Ebrahimi, Fremont, CA (US); Aditya Dayal, Sunnyvale, CA (US); Jack Kendrick Rasmus-Vorrath, Mountain House, CA (US); Robert Michael Martinson, Palo Alto, CA (US); Ajay Malik, Milpitas, CA (US); Aaron Michael Smith, Madison, CT (US); Piers Iain Ivo Octavian MacNaughton, San Jose, CA (US)

(21) Appl. No.: 17/910,722

(22) PCT Filed: Mar. 22, 2021
(86) PCT No.: PCT/US2021/023433

§ 371 Date: Sep. 9, 2022

Related U.S. Application Data
(63) Continuation-in-part of application No. PCT/US2021/015378, filed on Jan. 28, 2021.
Application No. PCT/US2021/015378 is a continuation-in-part of application No. 17/083,128, filed on Oct. 28, 2020.
Application No. 17/083,128 is a continuation of application No. 16/664,089, filed on Oct. 25, 2019, now Pat. No. 11,294,254.
Application No. 16/664,089 is a continuation-in-part of application No. PCT/US2019/030467, filed on May 2, 2019.
Application No. PCT/US2019/030467 is a continuation-in-part of application No. PCT/US2018/029460, filed on Apr. 25, 2018.
Application No. 16/664,089 is a continuation-in-part of application No. PCT/US2018/029460, filed on Apr. 25, 2018.
(60) Provisional application No. 63/159,814, filed on Mar. 11, 2021.
(60) Provisional application No. 62/666,033, filed on May 2, 2018.
(60) Provisional application No. 62/607,618, filed on Dec. 19, 2017.
(60) Provisional application No. 62/523,606, filed on Jun. 22, 2017.
(60) Provisional application No. 62/507,704, filed on May 17, 2017.
(60) Provisional application No. 62/506,514, filed on May 15, 2017.
(60) Provisional application No. 62/490,457, filed on Apr. 26, 2017.
(60) Provisional application No. 62/967,204, filed on Jan. 29, 2020.
(60) Provisional application No. 63/115,886, filed on Nov. 19, 2020.
(60) Provisional application No. 63/041,002, filed on Jun. 18, 2020.
(60) Provisional application No. 62/993,617, filed on Mar. 23, 2020.

(51) Int. Cl. G02F 1/163; G05B 19/042; G06F 3/044; G05B 15/02; H10K 59/65; G02F 1/15; B32B 17/10; E06B 9/24; G02F 1/155; G06F 3/041; H10K 50/80; H02J 50/80; H02J 50/20; G09F 19/22; G06F 3/14; G09G 3/38

(52) U.S. Cl. CPC G02F 1/163; G05B 19/0426; G06F 3/044; G05B 15/02; H01L 27/3234; G02F 1/15; B32B 17/10513; E06B 9/24; G02F 1/155; G06F 3/0412; H01L 51/52; H02J 50/80; H02J 50/20; G05B 19/042; G09F 19/227; G06F 3/1446; G09G 3/38; H04K 3/45

(57) ABSTRACT

Disclosed herein as methods, apparatuses, non-transitory computer readable media, and systems relating to reduction and/or identification of one or more health risks in a facility. For example, by sensing a bodily characteristic of an individual in a facility, e.g., by sensing at least one environmental characteristic. For example, by sensing surface cleanliness. For example, by tracking personnel in the facility. For example, by suggesting routes in an enclosure based at least in part in personnel concentration in the facility. Disclosed herein as methods, apparatuses, non-transitory computer readable media, and systems relating to monitoring occupancy of a facility.

### RELATED APPLICATIONS

This application claims priority from U.S. Provisional Patent Application Ser. No. 63/159,814, filed on Mach 11, 2021, titled “IDENTIFYING, REDUCING HEALTH RISKS, AND TRACKING OCCUPANCY IN A FACILITY,” from U.S. Provisional Patent Application Ser. No. 63/115,886, filed on Nov. 19, 2020, titled “IDENTIFYING AND REDUCING HEALTH RISKS IN A FACILITY,” from U.S. Provisional Patent Application Ser. No. 63/041,002, filed on Jun. 18, 2020, titled “SENSING ABNORMAL BODY CHARACTERISTICS OF ENCLOSURE OCCUPANTS.” and from U.S. Provisional Patent Application Ser. No. 62/993,617, filed on Mar. 23, 2020, titled “SENSING ABNORMAL BODY CHARACTERISTICS OF ENCLOSURE OCCUPANTS.” This application also claims priority as a continuation in part from International Patent Application Serial No. PCT/US21/15378 filed Jan. 28, 2021 titled “Sensor Calibration and Operation,” which claims priority from U.S. Provisional Patent Application Ser. No. 62/967,204, filed Jan. 29, 2020, titled, “SENSOR CALIBRATION AND OPERATION.” International Patent Application Serial No. PCT/US21/15378 is also a Continuation in Part of U.S. patent application Ser. No. 17/083,128, filed Oct. 28, 2020, titled, “BUILDING NETWORK,” which is a Continuation of U.S. patent application Ser. No. 16/664,089, filed Oct. 25, 2019, titled, “BUILDING NETWORK.” U.S. patent application Ser. No. 17/083,128 is also a Continuation-in-Part of International Patent Application Serial No. PCT/US19/30467, filed May 2, 2019, titled, “EDGE NETWORK FOR BUILDING SERVICES,” which claims priority from U.S. Provisional Patent Application Ser. No. 62/666,033, filed May 2, 2018, titled, “EDGE NETWORK FOR BUILDING SERVICES.” U.S. patent application Ser. No. 17/083,128 is also a Continuation-in-Part of International Patent Application Serial No. PCT/US18/29460, filed Apr. 25, 2018, titled, “TINTABLE WINDOW SYSTEM FOR BUILDING SERVICES,” that claims priority from U.S. Provisional Patent Application Ser. No. 62/607,618, filed on Dec. 19, 2017, from U.S. Provisional Patent Application Ser. No. 62/523,606, filed on Jun. 22, 2017, from U.S. Provisional Patent Application Ser. No. 62/507,704, filed on May 17, 2017, from U.S. Provisional Patent Application Ser. No. 62/506,514, filed on May 15, 2017, and from U.S. Provisional Patent Application Ser. No. 62/490,457, filed on Apr. 26, 2017. International Patent Application Serial No. PCT/US21/15378 is also a Continuation-in-Part of U.S. patent application Ser. No. 16/447,169, filed Jun. 20, 2019, titled, “SENSING AND COMMUNICATIONS UNIT FOR OPTICALLY SWITCHABLE WINDOW SYSTEMS,” which claims priority from U.S. Provisional Patent Application Ser. No. 62/858,100, filed Jun. 6, 2019, titled, “SENSING AND COMMUNICATIONS UNIT FOR OPTICALLY SWITCHABLE WINDOW SYSTEMS.” U.S. patent application Ser. No. 16/447,169, also claims priority from U.S. Provisional Patent Application Ser. No. 62/803,324, filed Feb. 8, 2019, titled “SENSING AND COMMUNICATIONS UNIT FOR OPTICALLY SWITCHABLE WINDOW SYSTEMS,” U.S. Provisional Patent Application Ser. No. 62/768,775, filed Nov. 16, 2018, titled, “SENSING AND COMMUNICATIONS UNIT FOR OPTICALLY SWITCHABLE WINDOW SYSTEMS,” U.S. Provisional Patent Application Ser. No. 62/688,957, filed Jun. 22, 2018, titled, “SENSING AND COMMUNICATIONS UNIT FOR OPTICALLY SWITCHABLE WINDOW SYSTEMS,” and from U.S. Provisional Patent Application Ser. No. 62/666,033. U.S. patent application Ser. No. 16/447,169 is also a Continuation-in-Part of International Patent Application Serial No. PCT/US19/30467. Each of the patent applications recited above is incorporated by reference herein in its entirety.

### BACKGROUND

A sensor may be configured (e.g., designed) to measure one or more environmental characteristics, for example, temperature, humidity, ambient noise, carbon dioxide, and/or other aspects of an ambient environment. There may arise a need to know whether one or more bodily characteristics of an individual are abnormal such that they are indicative of an illness. For example, it may be beneficial to know if an individual has a bodily temperature above normal in various settings. For example, in a private setting such as a home. For example, in non-private setting such as in a workplace, hospital, airport, restaurant, or a correctional facility (e.g., jail or prison). Such need may arise in consideration of any potential harm that a diseased person may inflict on others. Individuals may test themselves for fever when they are aware or suspect such increased bodily temperature in themselves, for example, when they are distinctly uncomfortable. In some settings, an institution may have an incentive to prevent ill occupants in its institution. For example, an industrial kitchen may wish to prevent presence of ill employees handling any food items, e.g., distributed to the general public. At times it may be challenging to detect in ill person, e.g., having abnormal characteristics. For example, due to an awareness level of the individual, and/or due to a hindrance of the individual to divulge such information.

At times, it may be challenging to accurately detect an abnormal bodily characteristic (e.g., fever) for a person, when bodily characteristics vary (e.g., widely) among people. A sensor which is deployed for measuring the bodily characteristic may not be calibrated and/or may require daily calibration, which may be expensive and/or inconvenient. Moreover, certain bodily characteristics may have natural variations which are not indicative of an abnormality. Once an abnormality is detected, additional challenges may arise from attempts to track interactions of an affected person and notify potentially exposed individuals for contact tracing purposes while maintaining privacy and securing of data. At times, offering a route that reduces once's exposure to other occupants in an enclosure, may be advantageous, e.g., in reducing infections among individuals.

### SUMMARY

Various aspects disclosed herein alleviate at least part of the one or more shortcomings related to bodily characteristic(s) of an individual.

Various aspects disclosed herein relate to one or more sensors disposed in an environment having occupant(s). The sensor(s) sense various characteristics of the environment, for example, environmental characteristics that influenced by the individual(s) in the facility (e.g., having the enclosure). For example, a temperature sensor, a carbon dioxide sensor, a humidity sensor, and/or a sensor sensing volatile organic compounds, may be influenced by presence of individual(s) in the facility (e.g., having the enclosure). The environment in the facility (e.g., having the enclosure) may be mapped by sensor(s) in the facility (e.g., having the enclosure). A characteristic of the environment may have gradients, e.g., around and/or as a consequence of a presence of an individual in the environment. For example, the environment may show trends of the environmental characteristic using a thermal array of sensors. The environment may be a normal setting, for example, a workplace, an airport, a restaurant. The environment may be a dedicated inspection environment, e.g., that permits a single individual to be tested therein. The individual may be stationary or non-stationary during the testing. For example, the individual may be passing through the sensed environment, e.g., during the testing.

Various aspects disclosed herein relate to a use of relative bodily characteristics (e.g., temperature) measurements by a sensor. In some embodiments, an evaluation of relative changes of a characteristic (e.g., as opposed to making determinations based on an absolute magnitude) is used, e.g., because a temperature sensor need not measure an occupant's absolute temperature accurately in order to accurately measure a relative difference of temperature measurements taken at different times. The sensor may read 100° F. where the actual temperature of the occupant is 98.6° F. However, a particular sensor (e.g., even if not calibration) may be consistent in measuring variation accurately (e.g., within a measurement error). For example, a deviation in a later measured temperature of +3° F. from 100° F. The sensor can be in a high traffic area of a building (e.g., bathroom entrance, office entrance) and can read the bodily characteristic (e.g., forehead temperature) of a person, and broadcast the temperature (e.g., via an electromagnetic beacon), to a receiver via a communication network. The communication network can be communicatively coupled to a phone application (e.g., if the application is kept activated, without requiring identification of the person), or to a control system of the building. The control system may require identification (ID) of the person. The identification may be general (e.g., excluding personally identifiable information (PII)). The identification may be a unique identifier. A storage device can store the sensor reading along with an ID of the sensor. A person having (e.g., substantially) the same bodily characteristic can get tested at different locations in the facility (e.g., having the enclosure) (e.g., building) on the same day and get different readings (e.g., because of the different sensor calibration statuses). Over time (e.g., over a time period), the stored sensor readings corresponding to a particular sensor can be compared to analyze a bodily characteristic according to relative changes.

Various aspects disclosed herein relate to artificial intelligence (e.g., machine-learning) software on an application (app) and/or control system, which may learn over a period of time (e.g., a month) what is the typical bodily temperature of that person (e.g., for a plurality of sensors in the facility (e.g., having the enclosure) with which the individual interacted over the period). In some embodiments, if the person develops an abnormal bodily characteristic (e.g., fever), the abnormality will be detected, can be logged and/or trigger an event. For example, if the bodily characteristic passes a threshold (e.g., if the bodily temperature is more than 3° F. from normal readings).

Various aspects disclosed herein relate to the use of contact tracing to trace contact of a person identified as being potentially infected (e.g., having abnormal bodily characteristic as measured in the facility (e.g., having the enclosure), or otherwise reported as testing positive as to the abnormal bodily characteristic and/or ailment).

In another aspect, a method for detecting bodily characteristic of an individual in a facility (e.g., having an enclosure) comprises: (a) using at least one sensor to sense and/or identify an environmental characteristic of an environment in presence of the individual, which environmental characteristic is detectibly perturbed by the presence of the individual, as compared to absence of the individual from the environment; (b) analyzing (i) the sensed environmental characteristic in relation to (ii) a threshold indicative of abnormal bodily characteristic, to generate an analysis; and (c) using the analysis to generate a report of presence or absence of the indication of abnormal bodily characteristic of the individual.

In some embodiments, the environmental characteristic comprises temperature, carbon dioxide, humidity, or volatile organic compounds. In some embodiments, the bodily characteristic comprises fever, breathing, or perspiration. In some embodiments, the environment comprises an environment internal to the facility (e.g., having the enclosure) or an environment at an opening of the facility (e.g., having the enclosure). In some embodiments, the individual passes through the environment during usage of the at least one sensor to sense and/or identify the environmental characteristic. In some embodiments, the individual is stationary for at most five seconds during usage of the at least one sensor to sense the environmental characteristic. In some embodiments, the individual steps on a testing platform to facilitate sensing the environmental characteristic. In some embodiments, the individual passes by an opening to which the at least one sensor is attached during sensing of the environmental characteristic. In some embodiments, the at least the portion of the report comprises a result of the report. In some embodiments, the at least the portion of the report is sent to the individual in a form that is illegible. In some embodiments, the at least the portion of the report is sent to the individual in an audio or tactile form. In some embodiments, the at least one sensor comprises a plurality of sensors. In some embodiments, the at least one sensor comprises a plurality of sensors disposed in an ensemble. In some embodiments, the at least one sensor is communicatively coupled (e.g., connected) to a communication network. In some embodiments, the report is communicated to a mobile device of the individual via the communication network. The mobile device may comprise a circuitry (e.g., a processor). The mobile device may be an electronic mobile device. In some embodiments, the at least one sensor is communicatively coupled (e.g., connected) to a control network that controls one or more devices in the facility (e.g., having the enclosure). In some embodiments, the at least one sensor is communicatively coupled (e.g., connected wired and/or wirelessly) to a control network that controls one or more devices in a facility in which the facility (e.g., having the enclosure) is disposed. In some embodiments, the at least one sensor is communicatively coupled (e.g., connected) to a control network that controls one or more devices in the facility (e.g., having the enclosure) (e.g., facility), e.g., by considering the analysis and/or report. In some embodiments, the at least one sensor is disposed in a framing located in the interior of the facility (e.g., having the enclosure). In some embodiments, the method further comprises changing at least one portion of the framing to construct a new framing. In some embodiments, the framing holds a framed object. In some embodiments, the method further comprises changing the framed object to construct a new framing. In some embodiments, the method further comprises interacting with the framed object by a user. In some embodiments, the method further comprises providing input to the frame object by a user. In some embodiments, the method further comprises receiving output from the frame object responsive to a user. In some embodiments, the output from the frame object is received responsive to (I) a user input and/or (II) identification of the user. In some embodiments, the framing holds a framed object comprising a display construct, a board, a window, or a device. In some embodiments, the device includes an emitter, a sensor, an antenna, a radar, a dispenser, and/or an identification reader. In some embodiments, the emitter comprises a lighting, a buzzer, or a speaker. In some embodiments, the method further comprises using the identification reader to identify a code comprising a visual code, an electromagnetic code, or an audible code. In some embodiments, the visual code comprises a writing or a picture. In some embodiments, the visual code comprises letters, numbers, lines, or a geometric shape. In some embodiments, the visual code is a barcode or a quick response (QR) code. In some embodiments, the visual code comprises a machine readable code. In some embodiments, the electromagnetic code comprises ultra-wideband (UWB) radio waves, ultra-high frequency (UHF) radio waves, or radio waves utilized in global positioning system (GPS). In some embodiments, the electromagnetic code comprises electromagnetic waves of a frequency of at least about 300 MHz, 500 MHz, or 1200 MHz. In some embodiments, the electromagnetic code comprises location or time data. In some embodiments, the identification utilizes Bluetooth, UWB, UHF, and/or global positioning system (GPS) technology. In some embodiments, the electromagnetic code has a spatial capacity of at least about 1013 bits per second per meter squared (bit/s/i). In some embodiments, the at least one sensor is disposed in a blocker that is configured to controllably block a user from passing therethrough, or allow the user to pass therethrough. In some embodiments, the blocker comprises a first portion that is stationary and a second portion that controllably changes its position. In some embodiments, the first portion is a separator configured to separate one user from another. In some embodiments, the method further comprises controlling the position of the second portion at least in part by a control system. In some embodiments, the method further comprises using the control system to control one or more components of a facility in which the facility (e.g., having the enclosure) is disposed. In some embodiments, the method further comprises controlling the position of the second portion at least in part by a user. In some embodiments, the second portion comprises a transparent door. In some embodiments, the second portion comprises a turnstile. In some embodiments, the method further comprises changing at least one portion of the blocker to construct a new blocker. In some embodiments, the blocker holds, or is communicatively coupled to, a device. In some embodiments, the device includes an emitter, a sensor, an antenna, a radar, a dispenser, and/or a badge reader. In some embodiments, the emitter comprises a lighting, a buzzer, or a speaker. In some embodiments, the method further comprises changing and/or exchanging the device to construct a new blocker. In some embodiments, the method further comprises interacting with the blocker by a user. In some embodiments, the method further comprises providing input to the blocker by a user. In some embodiments, the method further comprises receiving output from the blocker responsive to a user. In some embodiments, the output from the blocker is received responsive to (I) a user input and/or (II) identification of the user. In some embodiments, the blocker comprises a board or a display construct.

In another aspect, a non-transitory computer readable program instructions for tracking a plurality of individuals in a facility, the non-transitory computer readable program instructions, when read by one or more processors, causes the one or more processors to execute operations of any of the above methods.

In some embodiments, the program instructions are inscribed in a non-transitory computer readable medium. In some embodiments, the program instructions are inscribed in non-transitory computer readable media. In some embodiments, at least two of the operations are executed by one of the one or more processors. In some embodiments, at least two of the operations are each executed by different processors of the one or more processors.

In another aspect, a non-transitory computer readable program instructions for tracking a plurality of individuals in a facility, the non-transitory computer readable program instructions, when read by one or more processors, causes the one or more processors to execute operations comprising: (a) using, or directing usage of, a sensor system to sense a first identity having a first position at a first time and a second identity having a second position at a second time, wherein the sensor system is operatively coupled to a local network disposed in the facility, which sensor system comprises a plurality of sensors configured to sense and/or identify the first identity, the first position, the first time, the second identity, the second position, and the second time; (b) tracking, or directing tracking of, movement of the first identity over a time period to generate a first tracking information, and tracking movement of the second identity over the time period to generate a second tracking information; and (c) evaluating, or directing evaluation of, a distance from the first tracking information to the second tracking information relative to a distance threshold. In some embodiments, the one or more processors are operatively (e.g., communicatively) coupled to at least one sensor configured to sense and/or identify at least one environmental characteristic.

In some embodiments, the local network is configured to facilitate control of at least one other device of the facility. In some embodiments, the program instructions are inscribed in a non-transitory computer readable medium. In some embodiments, the program instructions are inscribed in non-transitory computer readable media. In some embodiments, at least two of the operations are executed by one of the one or more processors. In some embodiments, at least two of the operations are each executed by different processors of the one or more processors.

In another aspect, an apparatus for or detecting bodily characteristic of an individual in a facility (e.g., having an enclosure), comprises one or more controllers operatively (e.g., communicatively) coupled to at least one sensor configured to sense and/or identify at least one environmental characteristic, the one or more controllers (e.g., comprising circuitry) configured to: (a) direct the at least one sensor to sense and/or identify an environmental characteristic of an environment in presence of the individual, which environmental characteristic is detectibly perturbed by the presence of the individual, as compared to absence of the individual from the environment; (b) analyze, or direct analysis of, (i) the sensed environmental characteristic in relation to (ii) a threshold indicative of abnormal bodily characteristic, to generate an analysis; and (c) use, or direct usage of, the analysis to generate a report of presence or absence of the indication of abnormal bodily characteristic of the individual.

In some embodiments, the one or more controllers are communicatively coupled to a network (e.g., a local network) configured for communication. In some embodiments, the at least two of the at least one sensor are configured to sense and/or identify the same type of environmental characteristic. For example, the plurality of sensors can comprise a plurality of temperature sensors. In some embodiments, the at least two of the at least one sensor are configured to sense and/or identify a different type of environmental characteristic. For example, the plurality of sensors can comprise a temperature sensor and a humidity sensor. In some embodiments, the environmental characteristic comprises temperature, carbon dioxide, humidity, or volatile organic compounds. The plurality of sensors can sense the same environmental characteristic and be of the same sensor type. For example, the plurality of sensors can be temperature sensors that are thermocouples. The plurality of sensors can sense the same environmental characteristic and be of a different sensor type. For example, the plurality of sensors can be temperature sensors that comprise a thermocouple and an IR sensor. In some embodiments, the bodily characteristic comprises fever, breathing, or perspiration. In some embodiments, the environment comprises an environment internal to the facility (e.g., having the enclosure) or an environment at an opening of the facility (e.g., having the enclosure). In some embodiments, the one or more sensors are communicatively coupled to the one or more controllers. In some embodiments, the one or more controllers are configured to direct the one or more sensors to detect the individual that passes through the environment during usage of the at least one sensor to sense and/or identify the environmental characteristic. In some embodiments, the one or more sensors and the at least one sensor have at least one common sensor. In some embodiments, the one or more sensors and the at least one sensor have at least one different sensor. In some embodiments, the one or more sensors and the at least one sensor have at least one common sensor type. In some embodiments, the one or more sensors and the at least one sensor have at least one different sensor type. In some embodiments, the one or more sensors are communicatively coupled to the one or more controllers. In some embodiments, the one or more controllers are configured to direct the one or more sensors to detect that individual is stationary for at most five seconds during usage of the at least one sensor to sense and/or identify the environmental characteristic. In some embodiments, the one or more sensors are communicatively coupled to the one or more controllers. In some embodiments, the one or more controllers are configured to direct the one or more sensors to detect that the individual steps on a testing platform to facilitate sensing the environmental characteristic. In some embodiments, the one or more sensors are communicatively coupled to the one or more controllers. In some embodiments, the one or more controllers are configured to direct the one or more sensors to detect that the individual passes by an opening to which the at least one sensor is attached during sensing of the environmental characteristic. In some embodiments, the one or more controllers are configured to send, or direct sending of, at least a portion of the report to the individual. In some embodiments, the at least the portion of the report comprises a result of the report. In some embodiments, the at least the portion of the report is sent to the individual in a form that is illegible. In some embodiments, the at least one sensor comprises a plurality of sensors. In some embodiments, the at least one sensor comprises a plurality of sensors disposed in an ensemble. In some embodiments, the at least one sensor is communicatively coupled (e.g., connected) to a communication network. In some embodiments, the one or more controllers are configured to communicate, or direct communication of, the report to a mobile device of the individual via the communication network. In some embodiments, the one or more controllers are configured to control, or direct control of, one or more devices in the facility (e.g., having the enclosure). In some embodiments, the one or more controllers are configured to control, or direct control of one or more devices in a facility in which the facility (e.g., having the enclosure) is disposed. In some embodiments, the one or more controllers are configured to control, or direct control of, an operation of one or more devices in the facility by considering the analysis and/or the report. In some embodiments, the at least two of (a), (b), and (c) are controlled by the same controller of the one or more controllers. In some embodiments, the at least two of (a), (b), and (c) are controlled by different controllers of the one or more controllers. In some embodiments, the at least one sensor is disposed in a framing located in the interior of the facility (e.g., having the enclosure). In some embodiments, at least one portion of the framing is configured to be alterable to construct a new framing. In some embodiments, the at least one controller is configured to (i) identify, or direct identification of, the new framing and/or one or more components of the new framing and/or (ii) establish, or direct establishment of, communication between the at least one controller and the new framing and/or establishing communication between the at least one controller and one or more components of the new framing. In some embodiments, the framing is configured to hold a framed object. In some embodiments, the framed object is configured for interaction by a user. In some embodiments, the framed object is configured for providing input by a user. In some embodiments, the framing is operatively coupled to the at least one controller. In some embodiments, the at least one controller is configured to receive output from the frame object responsive to a user. In some embodiments, the at least one controller is configured to receive output responsive to (I) a user input and/or (II) identification of the user. In some embodiments, the framing is configured to hold a framed object comprising a display construct, a board, a window, or a device. In some embodiments, the device includes an emitter, a sensor, an antenna, a radar, a dispenser, and/or an identification reader. In some embodiments, the emitter comprises a lighting, a buzzer, or a speaker. In some embodiments, the identification reader is configured to identify a visual code, an electromagnetic code, or an audible code. In some embodiments, the visual code comprises a writing or a picture. In some embodiments, the visual code comprises letters, numbers, lines, or a geometric shape. In some embodiments, the visual code is a barcode or a quick response (QR) code. In some embodiments, the visual code comprises a machine readable code. In some embodiments, the electromagnetic code comprises ultra-wideband (UWB) radio waves, ultra-high frequency (UHF) radio waves, or radio waves utilized in global positioning system (GPS). In some embodiments, the electromagnetic code comprises electromagnetic waves of a frequency of at least about 300 MHz, 500 MHz, or 1200 MHz. In some embodiments, the electromagnetic code comprises location or time data. In some embodiments, the identification utilizes Bluetooth, UWB, UHF, and/or global positioning system (GPS) technology. In some embodiments, the electromagnetic code has a spatial capacity of at least about 1013 bits per second per meter squared (bit/s/i). In some embodiments, the at least one sensor is disposed in a blocker that is configured to operatively coupled to the at least one controller. In some embodiments, the at least one controller is configured to (I) block, or direct blockage of, a user from passing therethrough, or (II) allow, or direct allowance of, the user to pass therethrough. In some embodiments, the blocker comprises a first portion that is stationary and a second portion that is configure to controllable change its position. In some embodiments, the at least one controller is configured to change, or direct changing of, the position of the blocker. In some embodiments, the first portion is a separator configured to separate one user from another. In some embodiments, the at least one controller is configured to at least partially control, or direct at least partial control of, the position of the second portion. In some embodiments, the at least one controller is configured to control, or direct control of, one or more components of a facility in which the facility (e.g., having the enclosure) is disposed. In some embodiments, the position of the second portion is configured for at least partial control by a user. In some embodiments, the second portion comprises a transparent door. In some embodiments, the second portion comprises a turnstile. In some embodiments, at least one portion of the blocker is configured to facilitate change in a configuration of the blocker to construct a new blocker. In some embodiments, the at least one controller is configured to (i) identify, or direct identification of, the new blocker and/or one or more components of the new blocker and/or (ii) establish, or direct establishment of, communication between the at least one controller and the new blocker and/or establishing communication between the at least one controller and one or more components of the new blocker. In some embodiments, the blocker is configured to hold, or is configured to communicatively couple to, a device. In some embodiments, the device includes an emitter, a sensor, an antenna, a radar, a dispenser, and/or a badge reader. In some embodiments, the emitter comprises a lighting, a buzzer, or a speaker. In some embodiments, at least one portion of the blocker is configured to facilitate changing and/or exchanging the device to construct a new blocker. In some embodiments, the at least one controller is configured to (i) identify, or direct identification of, the new blocker and/or one or more components of the new blocker and/or (ii) establish, or direct establishment of, communication between the at least one controller and the new blocker and/or establishing communication between the at least one controller and one or more components of the new blocker. In some embodiments, the blocker is configured for interacting with a user. In some embodiments, the blocker is configured for receiving input from a user. In some embodiments, the at least one controller is configured to communicatively couple to the blocker. In some embodiments, the at least one controller is configured to receive an output from the blocker responsive to a user. In some embodiments, the output from the blocker is received responsive to (I) a user input and/or (II) identification of the user. In some embodiments, the blocker comprises a board or a display construct.

In another aspect, a non-transitory computer readable product detecting bodily characteristic of an individual in a facility (e.g., having an enclosure) comprises one or more processors, which non-transitory computer readable product contains instructions inscribed thereon which, when executed by one or more processors, cause the one or more processors to execute operations comprising: (a) using at least one sensor to sense and/or identify an environmental characteristic of an environment in presence of the individual, which environmental characteristic is detectibly perturbed by the presence of the individual, as compared to absence of the individual from the environment; (b) analyzing (i) the sensed environmental characteristic in relation to (ii) a threshold indicative of abnormal bodily characteristic, to generate an analysis; and (c) using the analysis to generate a report of presence or absence of the indication of abnormal bodily characteristic of the individual.

In some embodiments, the environmental characteristic comprises temperature, carbon dioxide, humidity, or volatile organic compounds. In some embodiments, the bodily characteristic comprises fever, breathing, or perspiration. In some embodiments, the environment comprises an environment internal to the facility (e.g., having the enclosure) or an environment at an opening of the facility (e.g., having the enclosure). In some embodiments, the operations further comprise detecting the individual that passes through the environment during usage of the at least one sensor to sense and/or identify the environmental characteristic. In some embodiments, the operations further comprise detecting that the individual is stationary for at most five seconds during usage of the at least one sensor to sense and/or identify the environmental characteristic. In some embodiments, the operations further comprise detecting the individual that steps on a testing platform to facilitate sensing the environmental characteristic. In some embodiments, the operations further comprise detecting the individual that passes by an opening to which the at least one sensor is attached during sensing of the environmental characteristic. In some embodiments, the operations further comprise sending at least a portion of the report to the individual. In some embodiments, the at least the portion of the report comprises a result of the report. In some embodiments, the at least the portion of the report is sent to the individual in a form that is illegible. In some embodiments, the at least the portion of the report is sent to the individual. In some embodiments, the at least one sensor comprises a plurality of sensors. In some embodiments, the at least one sensor comprises a plurality of sensors disposed in an ensemble. In some embodiments, the at least one sensor is communicatively coupled (e.g., connected) to a communication network. In some embodiments, the operations further comprise the communicating the report to a mobile device of the individual via the communication network. In some embodiments, the at least one sensor is communicatively coupled (e.g., connected wired and/or wirelessly) to a control network that controls one or more devices in the facility (e.g., having the enclosure). In some embodiments, the at least one sensor is communicatively coupled (e.g., connected wired and/or wirelessly) to a control network that controls one or more devices in a facility in which the facility (e.g., having the enclosure) is disposed. In some embodiments, the at least one sensor is communicatively coupled (e.g., connected) to a control network that is configured to control one or more devices in the facility (e.g., having the enclosure) (e.g., facility), e.g., by considering the analysis and/or report. In some embodiments, the at least one sensor is disposed in a framing located in the interior of the facility (e.g., having the enclosure). In some embodiments, the framing is configured to facilitate changing at least one portion of the framing to construct a new framing. In some embodiments, the operations comprise (i) identify, or direct identification of, the new framing and/or one or more components of the new framing and/or (ii) establish, or direct establishment of, communication between a control system and the new framing and/or establishing communication between the control system and one or more components of the new framing. In some embodiments, the framing is configured to hold a framed object. In some embodiments, the framing is configured to facilitate changing framed object to construct a new framing. In some embodiments, the operations comprise (i) identify, or direct identification of, the new framing and/or the framed object changed and/or (ii) establish, or direct establishment of, communication between a control system and the new framing and/or establishing communication between control system and the framed object changed. In some embodiments, the framed object is configured for interaction by a user. In some embodiments, the framed object is configured for providing input to the frame object by a user. In some embodiments, the operations comprise receiving output from the frame object responsive to a user. In some embodiments, the output from the frame object is received responsive to (I) a user input and/or (II) identification of the user. In some embodiments, the framing is configured to hold a framed object comprising a display construct, a board, a window, or a device. In some embodiments, the device includes an emitter, a sensor, an antenna, a radar, a dispenser, and/or an identification reader. In some embodiments, the emitter comprises a lighting, a buzzer, or a speaker. In some embodiments, the operations comprise using the identification reader to identify a code comprising a visual code, an electromagnetic code, or an audible code. In some embodiments, the visual code comprises a writing or a picture. In some embodiments, the visual code comprises letters, numbers, lines, or a geometric shape. In some embodiments, the visual code is a barcode or a quick response (QR) code. In some embodiments, the visual code comprises a machine readable code. In some embodiments, the electromagnetic code comprises ultra-wideband (UWB) radio waves, ultra-high frequency (UHF) radio waves, or radio waves utilized in global positioning system (GPS). In some embodiments, the electromagnetic code comprises electromagnetic waves of a frequency of at least 300 MHz, 500 MHz, or 1200 MHz. In some embodiments, the electromagnetic code comprises location or time data. In some embodiments, the operation comprise identification of the identification code is based at least in part on Bluetooth, UWB, UHF, and/or global positioning system (GPS) technology. In some embodiments, the electromagnetic code has a spatial capacity of at least about 1013 bits per second per meter squared (bit/s/i). In some embodiments, the at least one sensor is disposed in a blocker that is configured to controllably block a user from passing therethrough, or allow the user to pass therethrough. In some embodiments, the blocker comprises a first portion that is stationary and a second portion that controllably changes its position. In some embodiments, the first portion is a separator configured to separate one user from another. In some embodiments, the operations comprise controlling the position of the second portion at least in part by a control system. In some embodiments, the operations comprise using the control system to control one or more components of a facility in which the facility (e.g., having the enclosure) is disposed. In some embodiments, the operations comprise controlling the position of the second portion at least in part by a user. In some embodiments, the second portion comprises a transparent door. In some embodiments, the second portion comprises a turnstile. In some embodiments, the operations comprise facilitating a change of at least one portion of the blocker to construct a new blocker. In some embodiments, facilitating a change comprises (i) identifying the new blocker and/or one or more components of the new blocker and/or (ii) establishing communication between a control system and the new blocker and/or establishing communication between the control system and one or more components of the new blocker. In some embodiments, the blocker holds, or is communicatively coupled to, a device. In some embodiments, the device includes an emitter, a sensor, an antenna, a radar, a dispenser, and/or a badge reader. In some embodiments, the emitter comprises a lighting, a buzzer, or a speaker. In some embodiments, the operations comprise facilitating a change of and/or an exchange of the device to construct a new blocker. In some embodiments, facilitating a change comprises (i) identifying the new blocker and/or one or more components of the new blocker and/or (ii) establishing communication between a control system and the new blocker and/or establishing communication between the control system and one or more components of the new blocker. In some embodiments, the operations comprise facilitating interaction of the blocker by a user. In some embodiments, the operations comprise facilitating providing input to the blocker by a user. In some embodiments, the operations comprise facilitating receiving output from the blocker responsive to a user. In some embodiments, the output from the blocker is received responsive to (I) a user input and/or (II) identification of the user. In some embodiments, the blocker comprises a board or a display construct.

In another aspect, a method of tracking a plurality of individuals in a facility (e.g., having an enclosure), comprises: (a) using a sensor system to sense and/or identify a first identity having a first position at a first time and a second identity having a second position at a second time, wherein the sensor system is operatively coupled to a network (e.g., a local network) disposed in the facility (e.g., having the enclosure), which sensor system comprises a plurality of sensors configured to sense and/or identify the first identity, the first position, the first time, the second identity, the second position, and the second time; (b) tracking movement of the first identity over time (e.g., over a time period) to generate a first tracking information, and tracking movement of the second identity over time (e.g., over a time period) to generate a second tracking information; and (c) evaluating a distance from the first tracking information to the second tracking information relative to a distance threshold.

In some embodiments, the local network is configured to facilitate control of at least one other device of the facility. In some embodiments, the local network is configured to facilitate control the facility, e.g., using a building management system. In some embodiment, the at least one other device comprises at least one other device type (e.g., respectively). In some embodiments, the at least one other device comprises a sensor, an emitter, an antenna, a router, a media display, or a tintable window. In some embodiments, the at least one other device comprises a service device (e.g., a printer, a manufacturing machine, or a beverage dispenser). In some embodiments, at least some of the plurality of sensors are integrated in one or more device ensembles. In some embodiments, the plurality of sensors and/or device ensemble comprises an accelerometer. In some embodiments, the plurality of sensors includes at least one geolocation sensor for detecting (i) the first position and the second position and/or (ii) the first identity and the second identity. In some embodiments, the at least one geolocation sensor comprises an ultrawide band (UWB) sensor, or a Bluetooth sensor. In some embodiments, the plurality of sensors includes a plurality of geolocation sensors that are synchronized in time (e.g., time synchronized). In some embodiments, the geolocation sensors comprise an ultrawide band (UWB) sensor, or a Bluetooth sensor. In some embodiments, the sensor system includes a camera to detect (i) the first position and the second position and/or (ii) the first identity and the second identity. In some embodiments, the camera is comprised of a sensor array having at least about 4000 sensors at its fundamental length scale. In some embodiments, the fundamental length scale comprises a length, a width, a radius, or a bounding radius. In some embodiments, the sensor array includes a sensor comprising a Charged Coupled Device (CCD). In some embodiments, the sensor system is comprised of a device ensemble, which device ensemble comprises (i) a plurality of sensors, or (ii) a sensor and an emitter. In some embodiments, the sensor system is comprised of a device ensemble that integrates a controller and/or a processor. In some embodiments, the sensor system is comprised of a device ensemble that comprises controllers and/or processors. In some embodiments, the sensor system is operatively coupled to a hierarchical control system comprising a plurality of controllers. In some embodiments, the sensor system is comprised of a device ensemble mounted at a fixed location in the facility (e.g., having the enclosure). In some embodiments, the fixed location is in, or attached to, a fixture of the facility (e.g., having the enclosure). In some embodiments, the fixed location is a controlled entrance of the facility (e.g., having the enclosure). In some embodiments, the facility (e.g., having the enclosure) includes a facility, building, and/or room. In some embodiments, the sensor system is comprised of a device ensemble mounted to, or embedded in, a non-fixture in the facility (e.g., having the enclosure). In some embodiments, the method further comprises: (d) associating the first position and the first time with the first identity to generate a first association, and associating the second position and the second time with the second identity to generate a second association; and (e) comparing the first association with the second association to evaluate a distance from the first identity to the second identity relative to the distance threshold. In some embodiments, the method further comprises evaluating whether the first tracking information and the second tracking information were at a distance below the distance threshold for a cumulative time relative to a time threshold. In some embodiments, the sensor system is coupled to a network (e.g., a local network) disposed in the facility (e.g., having an enclosure). In some embodiments, the network (e.g., the local network) comprises wiring disposed in an envelope of the facility (e.g., disposed in an envelope of the enclosure such as a building). In some embodiments, the method, further comprises transmitting power and communication through a single cable of the network (e.g., the local network). In some embodiments, the method further comprises using the network (e.g., the local network) to transmit at least a fourth generation, or a fifth generation cellular communication. In some embodiments, the method further comprises using the network (e.g., the local network) to transmit data comprising media. In some embodiments, the method further comprises using the network (e.g., the local network) to control an atmosphere of the facility (e.g., having the enclosure). In some embodiments, the method further comprises using the network (e.g., the local network) to control a tintable window disposed in the facility (e.g., having the enclosure). In some embodiments, the method further comprises using the network (e.g., the local network) to control the facility (e.g., having the enclosure).

In another aspect, a non-transitory computer readable program instructions for tracking a plurality of individuals in a facility, the non-transitory computer readable program instructions, when read by one or more processors, causes the one or more processors to execute operations of any of the methods above.

In some embodiments, the program instructions are inscribed in a non-transitory computer readable medium. In some embodiments, the program instructions are inscribed in non-transitory computer readable media. In some embodiments, at least two of the operations are executed by one of the one or more processors. In some embodiments, at least two of the operations are each executed by different processors of the one or more processors.

In another aspect, a non-transitory computer readable program instructions for tracking a plurality of individuals in a facility, the non-transitory computer readable program instructions, when read by one or more processors, causes the one or more processors to execute operations comprising: (a) using, or directing usage of, a sensor system to sense a first identity having a first position at a first time and a second identity having a second position at a second time, wherein the sensor system is operatively coupled to a local network disposed in the facility, which sensor system comprises a plurality of sensors configured to sense and/or identify the first identity, the first position, the first time, the second identity, the second position, and the second time; (b) tracking, or directing tracking of, movement of the first identity over a time period to generate a first tracking information, and tracking movement of the second identity over the time period to generate a second tracking information; and (c) evaluating, or directing evaluation of, a distance from the first tracking information to the second tracking information relative to a distance threshold. In some embodiments, the one or more processors are operatively coupled to a sensor system comprising a plurality of sensors configured to sense and/or identify a first identity having a first position at a first time and a second identity having a second position at a second time. In some embodiments, the sensor system is operatively coupled to a local network disposed in the facility. In some embodiments, the one or more processors are configured to control at least one other device of the facility.

In some embodiments, the local network is configured to facilitate control of at least one other device of the facility. In some embodiments, the program instructions are inscribed in a non-transitory computer readable medium. In some embodiments, the program instructions are inscribed in non-transitory computer readable media. In some embodiments, at least two of the operations are executed by one of the one or more processors. In some embodiments, at least two of the operations are each executed by different processors of the one or more processors.

In another aspect, an apparatus for tracking a plurality of individuals in a facility (e.g., having an enclosure), the apparatus comprising at least one controller (e.g., comprising circuitry), which at least one controller is configured to: (a) operatively couple to a sensor system comprising a plurality of sensors configured to sense and/or identify a first identity having a first position at a first time and a second identity having a second position at a second time, which sensor system is operatively coupled to a network (e.g., a local network) disposed in the facility (e.g., having the enclosure); (b) use, or direct use of, a sensor system to sense and/or identify the first identity having the first position at the first time and the second identity having the second position at the second time; (c) track, or direct tracking of, movement of the first identity over time (e.g., over a time period) to generate a first tracking information, and tracking movement of the second identity over time (e.g., over a time period) to generate, or direct generation of, a second tracking information; and (d) evaluate, or direct evaluation of, a distance from the first tracking information to the second tracking information relative to a distance threshold.

In some embodiments, the at least one controller is configured to control at least one other device of the facility. In some embodiments, the at least one controller is configured to control the facility, e.g., using a building management system. In some embodiment, the at least one other device comprises at least one other device type (e.g., respectively). In some embodiments, the at least one other device comprises a sensor, an emitter, an antenna, a router, a media display, or a tintable window. In some embodiments, the at least one other device comprises a service device (e.g., a printer, a manufacturing machine, or a beverage dispenser). In some embodiments, at least one of the plurality of sensors is integrated in a device ensemble that comprises (i) sensor or (ii) a sensor and an emitter. In some embodiments, the plurality of sensors includes at least one geolocation sensor for detecting (i) the first position and the second position and/or (ii) the first identity and the second identity. In some embodiments, the at least one geolocation sensor comprises an ultrawide band (UWB) sensor, or a Bluetooth sensor. In some embodiments, the plurality of sensors includes a plurality of geolocation sensors that are synchronized in time (e.g., time synchronized). In some embodiments, the geolocation sensors comprise an ultrawide band (UWB) sensor, or a Bluetooth sensor. In some embodiments, the sensor system includes a camera to detect (i) the first position and the second position and/or (ii) the first identity and the second identity. In some embodiments, the camera is comprised of a sensor array having at least about 4000 sensors at its fundamental length scale. In some embodiments, the fundamental length scale comprises a length, a width, a radius, or a bounding radius. In some embodiments, the sensor array includes a sensor comprising a Charged Coupled Device (CCD). In some embodiments, the sensor system is comprised of a device ensemble, which device ensemble comprises (i) a plurality of sensors, or (ii) a sensor and an emitter. In some embodiments, the sensor system is comprised of a device ensemble, which device ensemble comprises (i) a plurality of sensors, or (ii) a sensor and an emitter. In some embodiments, the sensor system is comprised of a device ensemble, which device ensemble integrates a controller. In some embodiments, the sensor system is operatively coupled to a hierarchical control system comprising a plurality of controllers. In some embodiments, the sensor system is comprised of a device ensemble mounted at a fixed location in the facility (e.g., having the enclosure). In some embodiments, the fixed location is in, or attached to, a fixture of the facility (e.g., having the enclosure). In some embodiments, the fixed location is a controlled entrance of the facility (e.g., having the enclosure). In some embodiments, the facility (e.g., having the enclosure) includes a facility, building, and/or room. In some embodiments, the sensor system is comprised of a device ensemble mounted to, or embedded in, a non-fixture in the facility (e.g., having the enclosure). In some embodiments, the at least one controller is further configured to: (d) associate, or direct association of, the first position and the first time with the first identity to generate a first association, and associate the second position and the second time with the second identity to generate a second association; and (e) compare, or direct comparison of, the first association with the second association to evaluate a distance from the first identity to the second identity relative to the distance threshold. In some embodiments, the apparatus further comprises evaluating whether the first tracking information and the second tracking information were at a distance below the distance threshold for a cumulative time relative to a time threshold. In some embodiments, the sensor system is coupled to a network (e.g., a local network) disposed in the facility (e.g., having an enclosure). In some embodiments, the network (e.g., the local network) comprises wiring disposed in an envelope of the facility (e.g., disposed in an envelope of the enclosure such as a building). In some embodiments, the network (e.g., the local network) is configured for power and communication transmission through a single cable. In some embodiments, the network (e.g., the local network) is configured for at least a fourth generation, or a fifth generation cellular communication. In some embodiments, the network (e.g., the local network) is configured for data transmission comprising media. In some embodiments, the network (e.g., the local network) is configured to couple to at least one antenna. In some embodiments, the network (e.g., the local network) is configured to couple to a plurality of different sensor types. In some embodiments, the network (e.g., the local network) is configured to couple to building management system configured to manage an atmosphere of the facility (e.g., having the enclosure). In some embodiments, the network (e.g., the local network) is configured to couple to a tintable window. In some embodiments, the network (e.g., the local network) is configured to couple to a hierarchical control system configure to control the facility (e.g., having the enclosure).

In another aspect, a method for tracking a plurality of individuals in a facility (e.g., having an enclosure), comprises: (A) using a sensor system to detect an identity of a first individual and of a second individual disposed in the facility (e.g., having the enclosure); (B) using the sensor system to track movement of the first individual across a first location set in the facility (e.g., having the enclosure) during a first time set, and tracking movement of the second individual across a second location set in the facility (e.g., having the enclosure) during a second time set; (C) associating the first location set and the first time set with the first individual to generate a first association, and associating the second location set and the second time set with the second individual to generate a second association; and (D) comparing the first association with the second association to evaluate a distance from the first individual to the second individual is relative to a threshold.

In some embodiments, which sensor system is operatively coupled to a local network that is configured to facilitate control of at least one other device of the facility. In some embodiments, the local network is configured to facilitate control the facility, e.g., using a building management system. In some embodiment, the at least one other device comprises at least one other device type (e.g., respectively). In some embodiments, the at least one other device comprises a sensor, an emitter, an antenna, a router, a media display, or a tintable window. In some embodiments, the at least one other device comprises a service device (e.g., a printer, a manufacturing machine, or a beverage dispenser). In some embodiments, detecting the identity of the first individual and of the second individual is conducted upon entry to the facility (e.g., having the enclosure). In some embodiments, the first location set and the second location set are specified according to a plurality of zones which subdivide the facility (e.g., having the enclosure). In some embodiments, associating the locations and the time sets is comprised of storing a plurality of times and zone locations according to the monitored movement in a plurality of buffers corresponding to the first individual and the second individual. In some embodiments, the plurality of buffers comprises a first buffer corresponding to the first individual and a second buffer corresponding to the second individual. In some embodiments, comparing the first association with the second association is conditioned upon detecting a predetermined event relating to the first individual and/or the second individual. In some embodiments, (a) detecting the identity and (b) tracking the movement, is performed at least in part by using a sensor system that comprises a device ensemble comprising (i) a plurality of sensors or (ii) a sensor and an emitter. In some embodiments, the plurality of sensors includes geolocation sensor for detecting (i) the first location set and the second location set and/or (ii) the first identity and the second identity. In some embodiments, the geolocation sensor comprises an ultrawide band (UWB) sensor, or a Bluetooth sensor. In some embodiments, the plurality of sensors includes a plurality of geolocation sensors that are synchronized in time (e.g., time synchronized). In some embodiments, the geolocation sensors comprise an ultrawide band (UWB) sensor, or a Bluetooth sensor. In some embodiments, at least one of the plurality of sensors is included in a device ensemble. In some embodiments, the device ensemble and/or the plurality of sensors comprises an accelerometer. In some embodiments, the device ensemble comprises (i) sensors or (ii) a sensor and an emitter. In some embodiments, the plurality of sensors includes a camera to detect the first identity and/or the second identity. In some embodiments, the camera is comprised of a sensor array having at least about 4000 sensors at its fundamental length scale. In some embodiments, the fundamental length scale comprises a length, a width, a radius, or a bounding radius. In some embodiments, the sensor array includes a sensor comprising a Charged Coupled Device (CCD). In some embodiments, the sensor system is comprised of a plurality of sensors, wherein at least some of the plurality of sensors are integrated in one or more device ensembles. In some embodiments, the sensor system is comprised of a device ensemble that comprises a controller and/or processor. In some embodiments, the sensor system is comprised of a device ensemble that comprises controllers and/or processors. In some embodiments, the sensor system is operatively coupled to a hierarchical control system comprising a plurality of controllers. In some embodiments, the sensor system comprises at least one sensor housed in a device ensemble mounted at, or in, a fixture of the facility (e.g., having the enclosure). In some embodiments, the sensor system is located in a controlled entrance of the facility (e.g., having the enclosure). In some embodiments, the facility (e.g., having the enclosure) includes a facility, building, and/or room. In some embodiments, at least one sensor of the sensor system is housed in a device ensemble mounted to, or in, a non-fixture disposed in the facility (e.g., having the enclosure). In some embodiments, the sensor system is coupled to a network (e.g., a local network) disposed in the facility (e.g., having an enclosure). In some embodiments, the network (e.g., the local network) comprises wiring disposed in an envelope of the facility (e.g., disposed in an envelope of the enclosure such as a building). In some embodiments, the method further comprises transmitting power and communication through a single cable of the network (e.g., the local network). In some embodiments, the method further comprises using the network (e.g., the local network) to transmit at least a fourth generation, or a fifth generation cellular communication. In some embodiments, the method further comprises using the network (e.g., the local network) to transmit data comprising media. In some embodiments, the method further comprises using the network (e.g., the local network) to control an atmosphere of the facility (e.g., having the enclosure). In some embodiments, the method further comprises using the network (e.g., the local network) to control a tintable window disposed in the facility (e.g., having the enclosure). In some embodiments, the method further comprises using the network (e.g., the local network) to control the facility (e.g., having the enclosure).

In another aspect, a non-transitory computer readable program instructions for tracking a plurality of individuals in a facility, the non-transitory computer readable program instructions, when read by one or more processors, causes the one or more processors to execute operations of any of the methods above.

In some embodiments, the program instructions are inscribed in a non-transitory computer readable medium. In some embodiments, the program instructions are inscribed in non-transitory computer readable media. In some embodiments, at least two of the operations are executed by one of the one or more processors. In some embodiments, at least two of the operations are each executed by different processors of the one or more processors.

In another aspect, a non-transitory computer readable program instructions for tracking a plurality of individuals in a facility, the non-transitory computer readable program instructions, when read by one or more processors, causes the one or more processors to execute operations comprising: (A) using, or directing usage of, a sensor system to detect an identity of a first individual and of a second individual disposed in the facility, which sensor system is operatively coupled to a local network; (B) using the sensor system to track movement of the first individual across a first location set in the facility during a first time set, and tracking movement of the second individual across a second location set in the facility during a second time set; (C) associating, or directing association of, the first location set and the first time set with the first individual to generate a first association, and associating the second location set and the second time set with the second individual to generate a second association; and (D) comparing, or directing comparison of, the first association with the second association to evaluate a distance from the first individual to the second individual is relative to a threshold. In some embodiments, the one or more processors are operatively coupled to a sensor system configured to detect an identity of a first individual and of a second individual disposed in the facility (e.g., having the enclosure).

In some embodiments, the local network is configured to facilitate control of at least one other device of the facility. In some embodiments, the program instructions are inscribed in a non-transitory computer readable medium. In some embodiments, the program instructions are inscribed in non-transitory computer readable media. In some embodiments, at least two of the operations are executed by one of the one or more processors. In some embodiments, at least two of the operations are each executed by different processors of the one or more processors.

In another aspect, an apparatus for tracking a plurality of individuals in a facility (e.g., having an enclosure), the apparatus comprising at least one controller (e.g., comprising circuitry), which at least one controller is configured to: (A) operatively couple to a sensor system configured to detect an identity of a first individual and of a second individual disposed in the facility (e.g., having the enclosure); (B) use, or direct use of, the sensor system to detect the identity of the first individual and of the second individual disposed in the facility (e.g., having the enclosure); (C) use, or direct use of, the sensor system to track movement of the first individual across a first location set in the facility (e.g., having the enclosure) during a first time set, and tracking movement of the second individual across a second location set in the facility (e.g., having the enclosure) during a second time set; (D) associate, or direct association of, the first locations and the first time set with the first individual and generate a first association, and associate, or direct association of, the second location set and the second time set with the second individual to generate a second association; and (E) compare, or direct comparison of, the first association with the second association to evaluate a distance from the first individual to the second individual relative to a threshold.

In some embodiments, the at least one controller is configured to control at least one other device of the facility. In some embodiments, the at least one controller is configured to control the facility, e.g., using a building management system. In some embodiment, the at least one other device comprises at least one other device type (e.g., respectively). In some embodiments, the at least one other device comprises a sensor, an emitter, an antenna, a router, a media display, or a tintable window. In some embodiments, the at least one other device comprises a service device (e.g., a printer, a manufacturing machine, or a beverage dispenser). In some embodiments, the at least one controller is configured to detect, or direct detection of, the identity of the first individual and of the second individual is conducted upon entry to the facility (e.g., having the enclosure). In some embodiments, the first location set and the second location set are specified according to a plurality of zones which subdivide the facility (e.g., having the enclosure). In some embodiments, the at least one controller is configured to associate, or direct association of, the locations and the time sets by storing a plurality of times and zone locations according to the monitored movement in a plurality of buffers corresponding to the first individual and the second individual. In some embodiments, the plurality of buffers comprises a first buffer corresponding to the first individual and a second buffer corresponding to the second individual. In some embodiments, the at least one controller is configured to compare, or direct comparison of, the first association with the second association conditioned upon detecting a predetermined event relating to the first individual and/or the second individual. In some embodiments, the at least one controller is configured to (a) detect, or direct detection of, the identity and (ii) track, or direct tracking of, the movement, is performed at least in part by using a sensor system that comprises a device ensemble comprising (i) a plurality of sensors or (ii) a sensor and an emitter. In some embodiments, the plurality of sensors includes geolocation sensor for detecting (i) the first location set and the second location set and/or (ii) the first identity and the second identity. In some embodiments, the geolocation sensor comprises an ultrawide band (UWB) sensor, or a Bluetooth sensor. In some embodiments, the plurality of sensors includes a plurality of geolocation sensors that are synchronized in time (e.g., time synchronized). In some embodiments, the geolocation sensors comprise an ultrawide band (UWB) sensor, or a Bluetooth sensor. In some embodiments, at least one of the plurality of sensors is included in a device ensemble. In some embodiments, the device ensemble and/or the plurality of sensors comprises an accelerometer. In some embodiments, the device ensemble comprises (i) sensors or (ii) a sensor and an emitter. In some embodiments, the plurality of sensors includes a camera to detect the first identity and/or the second identity. In some embodiments, the camera is comprised of a sensor array having at least 4000 sensors at its fundamental length scale. In some embodiments, the fundamental length scale comprises a length, a width, a radius, or a bounding radius. In some embodiments, the sensor array includes a sensor comprising a Charged Coupled Device (CCD). In some embodiments, the sensor system is comprised of a plurality of sensors, wherein at least some of the plurality of sensors are integrated in one or more device ensembles. In some embodiments, the sensor system is comprised of a device ensemble that comprises a controller and/or processor. In some embodiments, the sensor system is comprised of a device ensemble that comprises controllers and/or processors. In some embodiments, the sensor system is operatively coupled to a hierarchical control system comprising a plurality of controllers. In some embodiments, the sensor system comprises at least one sensor housed in a device ensemble mounted at, or in, a fixture of the facility (e.g., having the enclosure). In some embodiments, the sensor system is located in a controlled entrance of the facility (e.g., having the enclosure). In some embodiments, the facility (e.g., having the enclosure) includes a facility, building, and/or room. In some embodiments, at least one sensor of the sensor system is housed in a device ensemble mounted to, or in, a non-fixture disposed in the facility (e.g., having the enclosure). In some embodiments, the sensor system is coupled to a network (e.g., a local network) disposed in the facility (e.g., having an enclosure). In some embodiments, the network (e.g., the local network) comprises wiring disposed in an envelope of the facility (e.g., disposed in an envelope of the enclosure). In some embodiments, the network (e.g., the local network) is configured for power and communication transmission through a single cable. In some embodiments, the network (e.g., the local network) is configured for at least a fourth generation, or a fifth generation cellular communication. In some embodiments, the network (e.g., the local network) is configured for data transmission comprising media. In some embodiments, the network (e.g., the local network) is configured to couple to at least one antenna. In some embodiments, the network (e.g., the local network) is configured to couple to a plurality of different sensor types. In some embodiments, the network (e.g., the local network) is configured to couple to building management system configured to manage an atmosphere of the facility (e.g., having the enclosure). In some embodiments, the network (e.g., the local network) is configured to couple to a tintable window. In some embodiments, the network (e.g., the local network) is configured to couple to a hierarchical control system configure to control the facility (e.g., having the enclosure).

In another aspect, a method for monitoring disinfection of surfaces, comprises: (A) using a sensor system to sense and/or identify a plurality of temperature samples of an object surface (e.g., a surface) at a plurality of sample times; (B) comparing consecutive temperature samples of the plurality of temperature samples to generate a comparison; (C) detecting a cleaning event when the comparison indicates a temperature drop below a temperature threshold; (E) monitoring an elapsed time since a last cleaning event; and (F) generating a notification when the elapsed time exceeds a time threshold.

In some embodiments, the sensor system is disposed in the facility and is operatively coupled to a local network of the facility. In some embodiments, the local network is configured to control at least one other device of the facility that is operatively coupled to the local network. In some embodiments, the local network is configured to facilitate control the facility, e.g., using a building management system. In some embodiment, the at least one other device comprises at least one other device type (e.g., respectively). In some embodiments, the sensor system is coupled to a network (e.g., a local network) disposed in a facility (e.g., having an enclosure) in which the surface (e.g., the object surface) is disposed. In some embodiments, the network (e.g., the local network) comprises wiring disposed in an envelope of the facility (e.g., disposed in an envelope of the enclosure). In some embodiments, the method further comprises transmitting power and communication through a single cable of the network (e.g., the local network). In some embodiments, the method further comprises using the network (e.g., the local network) to transmit at least a fourth generation, or a fifth generation cellular communication. In some embodiments, the method further comprises using the network (e.g., the local network) to transmit data comprising media. In some embodiments, the method further comprises using the network (e.g., the local network) to control an atmosphere of the facility (e.g., having the enclosure). In some embodiments, the method further comprises using the network (e.g., the local network) to control a tintable window disposed in the facility (e.g., having the enclosure). In some embodiments, the method further comprises using the network (e.g., the local network) to control the facility (e.g., having the enclosure). In some embodiments, the sensor system remotely senses the temperature samples. In some embodiments, the sample times repeat according to a predetermined sampling frequency. In some embodiments, the predetermined sampling frequency is comprised of one sample at a time interval of at most one minute. In some embodiments, a number of consecutive temperature samples compared includes at least about 2, 5, 10, or 20 temperature samples. In some embodiments, the notification is sent to a designated recipient or a requesting recipient. In some embodiments, the sensor system is includes at least one sensor integrated in a device ensemble comprising (i) sensors or (ii) a sensor and an emitter. In some embodiments, the sensor system includes at least one sensor integrated in a device ensemble comprising (i) at least one controller or (ii) at least one processor. In some embodiments, the sensor system is operatively coupled to a hierarchical control system comprising a plurality of controllers.

In another aspect, a non-transitory computer readable program instructions for monitoring disinfection of surfaces of a facility, the non-transitory computer readable program instructions, when read by one or more processors, causes the one or more processors to execute operations of any of the methods above.

In some embodiments, the program instructions are inscribed in a non-transitory computer readable medium. In some embodiments, the program instructions are inscribed in non-transitory computer readable media. In some embodiments, at least two of the operations are executed by one of the one or more processors. In some embodiments, at least two of the operations are each executed by different processors of the one or more processors.

In another aspect, a non-transitory computer readable program instructions for monitoring disinfection of surfaces of a facility, the non-transitory computer readable program instructions, when read by one or more processors, causes the one or more processors to execute operations comprising: (A) using, or directing usage of, a sensor system to sense a plurality of temperature samples of an object surface at a plurality of sample times, which sensor system is disposed in the facility and is operatively coupled to a local network of the facility; (B) comparing, or directing comparison of, consecutive temperature samples of the plurality of temperature samples to generate a comparison; (C) detecting, or directing detection of, a cleaning event when the comparison indicates a temperature drop below a temperature threshold; (E) monitoring, or directing monitor of, an elapsed time since a last cleaning event; and (F) generating, or directing generation of, a notification when the elapsed time exceeds a time threshold. In some embodiments, the one or more processors are operatively coupled to the sensor system.

In some embodiments, the which local network is configured to control at least one other device of the facility that is operatively coupled to the local network. In some embodiments, the program instructions are inscribed in a non-transitory computer readable medium. In some embodiments, the program instructions are inscribed in non-transitory computer readable media. In some embodiments, at least two of the operations are executed by one of the one or more processors. In some embodiments, at least two of the operations are each executed by different processors of the one or more processors.

In another aspect, an apparatus for monitoring disinfection of surfaces (e.g., of a facility), the apparatus comprising at least one controller (e.g., comprising circuitry), which at least one controller is configured to: (A) use, or direct use of, a sensor system to sense and/or identify a plurality of temperature samples an object surface (e.g., a surface) at a plurality of sample times; (B) compare, or direct comparison of, consecutive temperature samples of the plurality of temperature samples to generate a comparison; (C) detect, or direct detection of, a cleaning event when the comparison indicates a temperature drop below a temperature threshold; (E) monitor, or direct monitoring of, an elapsed time since a last cleaning event; and (F) generating a notification when the elapsed time exceeds a time threshold.

In some embodiments, the at least one controller is operatively coupled to the sensor system. In some embodiments, the at least one controller is configured to control, or direct control of, at least one other device of the facility (e.g., to which it is configured to operatively couple). In some embodiments, the at least one controller is configured to facilitate control the facility, e.g., using a building management system. In some embodiment, the at least one other device comprises at least one other device type (e.g., respectively). In some embodiments, the sensor system is configured to remotely sense the temperature samples. In some embodiments, the at least one controller is configured to repeat the sample times according to a predetermined sampling frequency. In some embodiments, the predetermined sampling frequency is comprised of one sample at a time interval of at most one minute. In some embodiments, a number of consecutive temperature samples compared includes at least about 2, 5, 10, or 20 temperature samples. In some embodiments, the at least one controller is configured to send, or direct sending of, the notification to a designated recipient or a requesting recipient. In some embodiments, the sensor system is includes at least one sensor integrated in a device ensemble comprising (i) sensors or (ii) a sensor and an emitter. In some embodiments, the sensor system includes at least one sensor integrated in a device ensemble comprising (i) at least one controller or (ii) at least one processor. In some embodiments, the sensor system is operatively coupled to a hierarchical control system comprising a plurality of controllers. In some embodiments, the sensor system is coupled to a network (e.g., a local network) disposed in a facility (e.g., having an enclosure) in which the surface (e.g., the object surface) is disposed. In some embodiments, the network (e.g., the local network) comprises wiring disposed in an envelope of the facility (e.g., disposed in an envelope of the enclosure). In some embodiments, the network (e.g., the local network) is configured for power and communication transmission through a single cable. In some embodiments, the network (e.g., the local network) is configured for at least a fourth generation, or a fifth In some embodiments, the network (e.g., the local network) is configured for data transmission comprising media. In some embodiments, the network (e.g., the local network) is configured to couple to at least one antenna. In some embodiments, the network (e.g., the local network) is configured to couple to a plurality of different sensor types. In some embodiments, the network (e.g., the local network) is configured to couple to building management system configured to manage an atmosphere of the facility (e.g., having the enclosure). In some embodiments, the network (e.g., the local network) is configured to couple to a tintable window. In some embodiments, the network (e.g., the local network) is configured to couple to a hierarchical control system configure to control the facility (e.g., having the enclosure).

In another aspect, a method of detecting a bodily characteristic of an individual in a facility (e.g., having an enclosure), comprises: (a) using a sensor system to sense and/or identify an environmental characteristic in presence of the individual on a plurality of occasions; (b) analyzing (i) the plurality of environmental characteristic data samples, and (ii) a threshold indicative of abnormal bodily characteristic, to generate an analysis; and (c) using the analysis to generate a report of presence and/or absence of the indication of abnormal bodily characteristic of the individual.

In some embodiments, the sensor system is disposed in the facility. In some embodiments, the sensor system is operatively coupled to a local network that is configured to facilitate control of at least one other device of the facility. In some embodiments, the local network is configured to facilitate control the facility, e.g., using a building management system. In some embodiment, the at least one other device comprises at least one other device type (e.g., respectively). In some embodiments, the environmental characteristic is detectibly perturbed by the presence of the individual, as compared to absence of the individual from an environment (e.g., of a facility (e.g., having an enclosure) of the facility). In some embodiments, collecting a plurality of environmental characteristic data samples of the individual for the plurality of occasions is to quantify a normal bodily characteristic of the individual, wherein the analysis further comprises analyzing a relative difference between a recent one of the data samples and the normal qualified, and wherein the threshold is a difference threshold. In some embodiments, the sensor system comprises a plurality of sensors. In some embodiments, the sensor system comprises a device ensemble housing (i) sensors and/or (ii) a sensor and an emitter. In some embodiments, the sensor system is communicatively coupled to a network (e.g., a local network) disposed in the facility (e.g., having the enclosure). In some embodiments, the network (e.g., the local network) comprises wiring disposed in an envelope of the facility (e.g., disposed in an envelope of the enclosure). In some embodiments, the method further comprises transmitting power and communication through a single cable of the network (e.g., the local network). In some embodiments, the method further comprises using the network (e.g., the local network) to transmit at least a fourth generation, or a fifth generation cellular communication. In some embodiments, the method further comprises using the network (e.g., the local network) to transmit data comprising media. In some embodiments, the method further comprises using the network (e.g., the local network) to control an atmosphere of the facility (e.g., having the enclosure). In some embodiments, the method further comprises using the network (e.g., the local network) to control a tintable window disposed in the facility (e.g., having the enclosure). In some embodiments, the method further comprises using the network (e.g., the local network) to control the facility (e.g., having the enclosure). In some embodiments, the sensor system comprises a plurality of devices disposed in a device ensemble, and wherein the device ensemble includes an emitter, a sensor, an antenna, a radar, a dispenser, a badge reader, geolocation technology, an accelerometer, and/or an identification reader. In some embodiments, the sensor system comprises an electromagnetic sensor. In some embodiments, the sensor system comprises a first electromagnetic sensor configured to detect a first radiation range, and a second electromagnetic sensor configured to detect a second radiation range having at least one portion that does not overlap the first radiation range. In some embodiments, the sensor system comprises an infrared sensor, visible light sensor, or a depth camera. In some embodiments, the sensor system comprises a web camera. In some embodiments, the sensor system comprises visible light sensor and invisible light sensor. In some embodiments, the invisible light comprises infrared light. In some embodiments, the sensor system comprises a camera configured to distinguish an individual from its surrounding based at least in part on infrared radiation readings and/or visible radiation readings. In some embodiments, using the sensor system comprises measuring at a rate of at least about every 2 seconds (sec), 1 sec, 0.5 sec, 0.25 sec, 0.2 sec, 0.15 sec, 0.1 sec, 0.05 sec, or 0.025 sec. The sensor system may comprise a camera. The camera may be configured to take at least about 30 frames per second (frm/sec), 20 frm/sec, 10 frm/sec, 8 frm/sec, 6 frm/sec, 4 frm/sec, or 2 frm/sec. The frequency of sensing (e.g., the number of measurements per second taken, such as the number of frames per seconds taken) may be adjusted (e.g., manually and/or automatically using at least one controller, e.g., as part of the control system). Adjustment of the sensing rate may depend at least in part on an anticipated and/or average movement of occupants in the facility. For example, at an office setting, the average movement rate (e.g., velocity, or speed) of occupants may be slower than the average movement rate of occupants in a gym. Adjustment of the sensing rate may depend at least in part on an anticipated and/or average movement of occupants in a space of a facility in which the sensor system is disposed. For example, at an airport or train station, the average movement rate (e.g., velocity, or speed) of occupants in waiting areas may be slower than the average movement rate of occupants in transition areas (e.g., from a security gate to terminal(s)). The average rate may comprise a mean, median, or mode of the rate. A higher sensor sampling rate (e.g., higher rate of sensor measurements such as higher number of frames per second taken by a camera) may correspond to a higher average movement rate of individuals in a facility or a portion thereof (e.g., a space in the facility). In some embodiments, the individual is disposed at a distance of at least about 1, 2, or 3 feet horizontally away from a sensor of the sensor system, which sensor senses the sense an environmental characteristic. In some embodiments, a sensor sensing the environmental characteristic has a horizontal and/or vertical field of view of at least about 45 degrees, 55 degrees, 75 degrees, or 110 degrees, which sensor is included in the sensor system. At times, a lower resolution camera sensitive to wavelength range has a larger field of view angle as compared with a higher resolution camera sensitive to the wavelength range. The wavelength range can comprise visible, ultraviolet, or infrared wavelength ranges. In some embodiments, the method further comprises focusing at least one sensor of the sensor system on one or more facial landmark features of the individual to measure the environmental characteristics. In some embodiments, the facial landmark features comprise eyes, eye-brows, and/or nose of the individual. In some embodiments, the method further comprises focusing at least one sensor of the sensor system on depth placement of the individual to measure the environmental characteristics. In some embodiments, the method further comprises focusing at least one sensor of the sensor system on horizontal distance from the at least one sensor to the individual to measure the environmental characteristics. In some embodiments, the method further comprises focusing measurements of at least one sensor of the sensor system at least in part by considering (i) at least one facial feature of the individual and/or (ii) horizontal displacement of the individual relative to the one or more sensor. In some embodiments, the horizontal displacement is determined at least in part by using distance between facial landmark features of the individual, depth camera, and/or visible and non-visible electromagnetic sensor measurements. In some embodiments, analyzing the plurality of environmental characteristic data samples comprises using machine learning model that utilizes a learning set including measurements in the presence of an individual, in the presence of a black body, ground truth measurements, and/or simulated measurements. In some embodiments, evaluating the characteristic comprises filtering background measurements. In some embodiments, evaluating the characteristic comprises filtering environmental characteristics attributed to the background. In some embodiments, analyzing the plurality of environmental characteristic data samples comprises using machine learning model comprising a regression model or a classification model. In some embodiments, the sensor system is disposed in a framing or attached to a framing. In some embodiments, the sensor system is disposed in a kiosk configured to service at least one user. In some embodiments, the sensor system is disposed in a kiosk configured to service a plurality of users simultaneously from opposites sides of the kiosk. In some embodiments, the sensor system is disposed in a kiosk, and wherein the method further comprising servicing a plurality of users simultaneously at one side of the kiosk. In some embodiments, the sensor system is disposed in a kiosk that comprises modular units. In some embodiments, the sensor system is disposed in a kiosk that comprises one or more media displays. In some embodiments, the sensor system is disposed in a kiosk, and wherein the method further comprises interacting with one or more users remotely and/or contactlessly. In some embodiments, the sensor system is disposed in a kiosk. In some embodiments, the, and wherein the method further comprises conditionally permitting entry to at least a portion of the facility.

In another aspect, a non-transitory computer readable program instructions for detecting a bodily characteristic of an individual in a facility, the non-transitory computer readable program instructions, when read by one or more processors, causes the one or more processors to execute operations of any of the methods above.

In some embodiments, the program instructions are inscribed in a non-transitory computer readable medium. In some embodiments, the program instructions are inscribed in non-transitory computer readable media. In some embodiments, at least two of the operations are executed by one of the one or more processors. In some embodiments, at least two of the operations are each executed by different processors of the one or more processors.

In another aspect, a non-transitory computer readable program instructions for detecting a bodily characteristic of an individual in a facility, the non-transitory computer readable program instructions, when read by one or more processors, causes the one or more processors to execute operations comprising: (a) using, or directing usage of, a sensor system to sense an environmental characteristic in presence of the individual on a plurality of occasions, which sensor system is disposed in the facility and is operatively coupled to a local network; (b) analyzing, or directing analysis of, (i) the plurality of environmental characteristic data samples, and (ii) a threshold indicative of abnormal bodily characteristic, to generate an analysis; and (c) using, or directing usage of, the analysis to generate a report of presence and/or absence of the indication of abnormal bodily characteristic of the individual. In some embodiments, the one or more processors are operatively coupled to a sensor system configured to sense and/or identify an environmental characteristic.

In some embodiments, the local network is configured to facilitate control of at least one other device of the facility. In some embodiments, the program instructions are inscribed in a non-transitory computer readable medium. In some embodiments, the program instructions are inscribed in non-transitory computer readable media. In some embodiments, at least two of the operations are executed by one of the one or more processors. In some embodiments, at least two of the operations are each executed by different processors of the one or more processors.

In another aspect, an apparatus for detecting a bodily characteristic of an individual in a facility (e.g., having an enclosure), the apparatus comprising at least one controller (e.g., comprising circuitry), which at least one controller is configured to: (a) operatively couple to a sensor system configured to sense and/or identify an environmental characteristic; (b) use, or direct usage of, a sensor system to sense and/or identify an environmental characteristic in presence of the individual on a plurality of occasions; (b) analyze, or direct analysis of, (i) the plurality of environmental characteristic data samples, and (ii) a difference threshold indicative of abnormal bodily characteristic, to generate an analysis; and (c) use, or direct usage of, the analysis to generate a report of presence and/or absence of the indication of abnormal bodily characteristic of the individual.

In some embodiments, the at least one controller is configured to control, or direct control of, at least one other device of the facility. In some embodiments, the at least one controller is configured to control the facility, e.g., using a building management system. In some embodiment, the at least one other device comprises at least one other device type (e.g., respectively). In some embodiments, the environmental characteristic is detectibly perturbed by the presence of the individual, as compared to absence of the individual from the environment. In some embodiments, the at least one controller is configured to (i) collect, or direct collection of, a plurality of environmental characteristic data samples of the individual for the plurality of occasions is to quantify a normal bodily characteristic of the individual, (ii) analyze, or direct analysis of, a relative difference between a recent one of the data samples and the normal qualified, and wherein the threshold is a difference threshold. In some embodiments, the sensor system comprises a plurality of sensors. In some embodiments, the sensor system comprises a device ensemble housing (i) sensors and/or (ii) a sensor and an emitter. In some embodiments, the sensor system is communicatively coupled to a network (e.g., a local network) disposed in the facility (e.g., having the enclosure). In some embodiments, the network (e.g., the local network) comprises cabling disposed in an envelope of the facility (e.g., disposed in an envelope of the enclosure). In some embodiments, the at least one controller is configured to transmit, or direct transmission of, power and communication through a single cable of the network (e.g., the local network). In some embodiments, the at least one controller is configured to use, or direct usage of, the network (e.g., the local network) to transmit at least a fourth generation, or a fifth generation cellular communication. In some embodiments, the at least one controller is further configured to using the network (e.g., the local network) to transmit data comprising media (e.g., video, presentation, web streams, and/or web pages). In some embodiments, the at least one controller is configured to use, or direct usage of, the network (e.g., the local network) to control an atmosphere of the facility (e.g., having the enclosure). In some embodiments, the at least one controller is configured to use, or direct usage of, the network (e.g., the local network) to control a tintable window disposed in the facility (e.g., having the enclosure). In some embodiments, the at least one controller is configured to use, or direct usage of, the network (e.g., the local network) to control the facility (e.g., having the enclosure). In some embodiments, the sensor system comprises a plurality of devices disposed in a device ensemble, and wherein the device ensemble includes an emitter, a sensor, an antenna, a radar, a dispenser, a badge reader, geolocation technology, an accelerometer, and/or an identification reader. In some embodiments, the sensor system comprises an electromagnetic sensor. In some embodiments, the sensor system comprises a first electromagnetic sensor configured to detect a first radiation range, and a second electromagnetic sensor configured to detect a second radiation range having at least one portion that does not overlap the first radiation range. In some embodiments, the sensor system comprises an infrared sensor, visible light sensor, or a depth camera. In some embodiments, the sensor system comprises a web camera. In some embodiments, the sensor system comprises visible light sensor and invisible light sensor. In some embodiments, the invisible light comprises infrared light. In some embodiments, the sensor system comprises a camera configured to distinguish an individual from its surrounding based at least in part on infrared radiation readings and/or visible radiation readings. In some embodiments, the at least one controller is configured to use, or direct usage of, the sensor system at least in part by measuring at a rate of at least about every about 2 seconds, or every 1 second. In some embodiments, the sensor system is configured to measure the environmental characteristic when the individual is disposed at a distance of at least about 1, 2, or 3 feet horizontally away from a sensor of the sensor system, which sensor is configured to sense and/or identify the environmental characteristic. In some embodiments, a sensor sensing the environmental characteristic has a horizontal and/or vertical field of view of at least about 45 degrees, 55 degrees, 75 degrees, or 110 degrees, which sensor is included in the sensor system. In some embodiments, at least one sensor of the sensor system is configured to focus on one or more facial landmark features of the individual to measure the environmental characteristics. In some embodiments, the facial landmark features comprise eyes, eye-brows, and/or nose of the individual. In some embodiments, the at least one controller is configured to direct the at least one sensor of the sensor system to focus on depth placement of the individual to measure the environmental characteristics. In some embodiments, the at least one controller is configured to direct the at least one sensor of the sensor system to focus on horizontal distance from the at least one sensor to the individual to measure the environmental characteristics. In some embodiments, the at least one controller is configured to direct the at least one sensor of the sensor system to focus to focus its measurements at least in part by considering (i) at least one facial feature of the individual and/or (ii) horizontal displacement of the individual relative to the one or more sensor. In some embodiments, the horizontal displacement is determined at least in part by using distance between facial landmark features of the individual, depth camera, and/or visible and non-visible electromagnetic sensor measurements. In some embodiments, the at least one controller is configured to analyze, or direct analysis of, the plurality of environmental characteristic data samples at least in part by using machine learning model that utilizes a learning set including measurements in the presence of an individual, in the presence of a black body, ground truth measurements, and/or simulated measurements. In some embodiments, the at least one controller is configured to evaluate, or direct evaluation of, the characteristic at least in part by filtering background measurements. In some embodiments, the at least one controller is configured to evaluate, or direct evaluation of, the characteristic at least in part by filtering environmental characteristics attributed to the background. In some embodiments, the at least one controller is configured to analyze, or direct analysis of, the plurality of environmental characteristic data samples comprises at least in part by using machine learning model comprising a regression model or a classification model. In some embodiments, the sensor system is disposed in a framing or attached to a framing. In some embodiments, the sensor system is disposed in a kiosk configured to service at least one user. In some embodiments, the sensor system is disposed in a kiosk configured to service a plurality of users simultaneously from opposites sides of the kiosk. In some embodiments, the sensor system is disposed in a kiosk configured to service a plurality of users simultaneously at one side of the kiosk. In some embodiments, the sensor system is disposed in a kiosk that comprises modular units. In some embodiments, the sensor system is disposed in a kiosk that comprises one or more media displays. In some embodiments, the sensor system is disposed in a kiosk that is configured to interact with one or more users remotely and/or contactlessly. In some embodiments, the sensor system is disposed in a kiosk that is configured to conditionally permit entry to at least a portion of the facility.

In another aspect, a method of detecting occupancy in at least one enclosure of a facility, comprising: (a) using a sensor system to sense bodily signature of at least one individual disposed in the at least one enclosure of the facility over a time period, which bodily signature is characteristic of an individual; (b) analyzing the sensed bodily signature over the time period to generate an analysis; and (c) determining occupancy of the least one enclosure of the facility based at least in part on the analysis.

In some embodiments, the sensor system is operatively coupled to a local network of the facility. In some embodiments, the local network is configured to control at least one other device of the facility. In some embodiments, the local network is configured to facilitate control the facility, e.g., using a building management system. In some embodiment, the at least one other device comprises at least one other device type (e.g., respectively). In some embodiments, the at least one sensor of the sensor system is configured to sense electromagnetic radiation. In some embodiments, the at least one sensor of the sensor system is configured to sense infrared and/or visible radiation. In some embodiments, the at least one sensor of the sensor system is configured to sense depth of the at least one enclosure. In some embodiments, the at least one sensor of the sensor system is configured to sense ultra-wideband frequency radiation. In some embodiments, the at least one sensor of the sensor system is configured to movement of the at least one individual. In some embodiments, the method further comprises performing image processing of the bodily signature measured by the sensor system. In some embodiments, the method further comprises performing movement analysis of the bodily signature measured by the sensor system. In some embodiments, the method further comprises performing movement directional analysis of the bodily signature measured by the sensor system. In some embodiments, the at least one sensor of the sensor system is disposed at a ceiling of the facility. In some embodiments, the at least one enclosure is a plurality of enclosure, and wherein determining occupancy of the least one enclosure of the facility comprises determining occupancy overtime in each of the plurality of enclosures. In some embodiments, analyzing comprises using occupancy, timetable, and/or scheduling database of the facility. In some embodiments, analyzing comprises using occupancy, timetable, and/or scheduling database of the one or more individuals in facility.

In another aspect, an apparatus for detecting occupancy in at least one enclosure of a facility, comprising at least one controller configured to: (a) operatively couple to a sensor system; (b) user, or direct usage of, a sensor system to sense bodily signature of at least one individual disposed in the at least one enclosure of the facility over a time period, which bodily signature is characteristic of an individual; (c) analyze, or direct analysis of, the sensed bodily signature over the time period to generate an analysis; and (d) determine, or direct determination of occupancy of the least one enclosure of the facility based at least in part on the analysis.

In some embodiments, the at least one controller is configured to control, or direct control of, at least one other device of the facility. In some embodiments, the at least one controller is configured to control the facility, e.g., using a building management system. In some embodiment, the at least one other device comprises at least one other device type (e.g., respectively). In some embodiments, at least one sensor of the sensor system is configured to sense electromagnetic radiation. In some embodiments, at least one sensor of the sensor system is configured to sense infrared and/or visible radiation. In some embodiments, at least one sensor of the sensor system is configured to sense depth of the at least one enclosure. In some embodiments, at least one sensor of the sensor system is configured to sense ultra-wideband frequency radiation. In some embodiments, at least one sensor of the sensor system is configured to movement of the at least one individual. In some embodiments, the at least one controller is configured to perform, or direct performance of, image processing of the bodily signature measured by the sensor system. In some embodiments, the at least one controller is configured to perform, or direct performance of, movement analysis of the bodily signature measured by the sensor system. In some embodiments, the at least one controller is configured to perform, or direct performance of, movement directional analysis of the bodily signature measured by the sensor system. In some embodiments, at least one sensor of the sensor system is disposed at a ceiling of the facility. In some embodiments, the at least one enclosure is a plurality of enclosure, and wherein determining occupancy of the least one enclosure of the facility comprises determining occupancy over time in each of the plurality of enclosures. In some embodiments, analyzing comprises using occupancy, timetable, and/or scheduling database of the facility. In some embodiments, analyzing comprises using occupancy, timetable, and/or scheduling database of the one or more individuals in facility.

In some embodiments, the at least one controller disclosed herein comprises circuitry (e.g., electrical circuitry). The at least one controller is configured in, or includes, a processor.

In another aspect, the present disclosure provides methods that use any of the systems and/or apparatuses disclosed herein, e.g., for their intended purpose.

In another aspect, the present disclosure provides systems, apparatuses (e.g., controllers), and/or non-transitory computer-readable medium (e.g., software) that implement any of the methods disclosed herein.

In another aspect, an apparatus comprises at least one controller that is programmed to direct a mechanism used to implement (e.g., effectuate) any of the method disclosed herein, wherein the at least one controller is operatively coupled to the mechanism.

In another aspect, an apparatus comprises at least one controller that is configured (e.g., programmed) to implement (e.g., effectuate) the method disclosed herein. The at least one controller may implement any of the methods disclosed herein.

In some embodiments, one controller of the at least one controller is configured to perform two or more operations. In some embodiments, two different controllers of the at least one controller are configured to each perform a different operation.

In another aspect, a system comprises at least one controller that is programmed to direct operation of at least one another apparatus (or component thereof), and the apparatus (or component thereof), wherein the at least one controller is operatively coupled to the apparatus (or to the component thereof). The apparatus (or component thereof) may include any apparatus (or component thereof) disclosed herein. The at least one controller may direct any apparatus (or component thereof) disclosed herein.

In another aspect, a computer software product, comprising a non-transitory computer-readable medium in which program instructions are stored, which instructions, when read by a computer, cause the computer to direct a mechanism disclosed herein to implement (e.g., effectuate) any of the method disclosed herein, wherein the non-transitory computer-readable medium is operatively coupled to the mechanism. The mechanism can comprise any apparatus (or any component thereof) disclosed herein.

In another aspect, the present disclosure provides a non-transitory computer-readable medium comprising machine-executable code that, upon execution by one or more computer processors, implements any of the methods disclosed herein.

In another aspect, the present disclosure provides a non-transitory computer-readable medium comprising machine-executable code that, upon execution by one or more computer processors, effectuates directions of the controller(s) (e.g., as disclosed herein).

In another aspect, the present disclosure provides a computer system comprising one or more computer processors and a non-transitory computer-readable medium coupled thereto. The non-transitory computer-readable medium comprises machine-executable code that, upon execution by the one or more computer processors, implements any of the methods disclosed herein and/or effectuates directions of the controller(s) disclosed herein.

In another aspect, the present disclosure provides a non-transitory computer readable program instructions, the non-transitory computer readable program instructions, when read by one or more processors, causes the one or more processors to execute any operation of the methods disclosed herein, any operation performed (or configured to be performed) by the apparatuses disclosed herein, and/or any operation directed (or configured to be directed) by the apparatuses disclosed herein.

In some embodiments, the program instructions are inscribed in a non-transitory computer readable medium. In some embodiments, the program instructions are inscribed in non-transitory computer readable media. In some embodiments, at least two of the operations are executed by one of the one or more processors. In some embodiments, at least two of the operations are each executed by different processors of the one or more processors.

The content of this summary section is provided as a simplified introduction to the disclosure and is not intended to be used to limit the scope of any invention disclosed herein or the scope of the appended claims.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

These and other features and embodiments will be described in more detail with reference to the drawings.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings or figures (also “Fig.” and “Figs.” herein), of which:

FIG. 1A and FIG. 1B schematically show various enclosures with individuals disposed therein;

FIG. 2A and FIG. 2B schematically show various enclosures with individuals disposed therein;

FIGS. 3A-3D schematically show various admission related apparatuses;

FIGS. 4A-4B schematically show various admission related apparatuses in functional environments;

FIGS. 5A-5B schematically show various admission related apparatuses in functional environments;

FIGS. 6A-6B schematically show various admission related apparatuses in functional environments;

FIG. 7 shows an admission flowchart;

FIG. 8 shows an admission flowchart;

FIG. 9 schematically shows a schematic example of a sensor arrangement;

FIG. 10 shows a schematic example of a sensor arrangement and sensor data;

FIG. 11 depicts a time dependent graph of carbon dioxide concentrations;

FIG. 12 shows a topographical map of measured property values;

FIG. 13 schematically shows an apparatus and its components and connectivity options;

FIG. 14 schematically shows a schematic example of sensor arrangement and sensor data;

FIG. 15 schematically shows apparatus and connectivity of components for detecting abnormal condition(s) and providing a report;

FIG. 16 shows a flowchart for comparing relative sensor data;

FIG. 17 schematically shows apparatus and interactions for monitoring building occupant(s);

FIG. 18 shows a flowchart related to contact tracing;

FIG. 19 shows a flowchart related to movement prediction;

FIG. 20 shows a flowchart related to monitoring cleaning status of surfaces;

FIG. 21 schematically shows a control system and its various components;

FIG. 22 shows a flowchart related to sensor data processing;

FIG. 23 schematically depicts a controller;

FIG. 24 schematically depicts a processing system;

FIG. 25 schematically shows a person and sensors;

FIG. 26 schematically depicts a flowchart for reporting measured characteristic (e.g., temperature) of a user;

FIGS. 27A-27B schematically depict various sensor ensembles and data processing sequence;

FIG. 28 schematically shows various framing systems and users;

FIG. 29 schematically shows various framing systems; and

FIG. 30 schematically shows various framing system portions.

The figures and components therein may not be drawn to scale. Various components of the figures described herein may not be drawn to scale.

### DETAILED DESCRIPTION

While various embodiments of the invention have been shown, and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein might be employed.

Terms such as “a,” “an,” and “the” are not intended to refer to only a singular entity but include the general class of which a specific example may be used for illustration. The terminology herein is used to describe specific embodiments of the invention(s), but their usage does not delimit the invention(s).

When ranges are mentioned, the ranges are meant to be inclusive, unless otherwise specified. For example, a range between value 1 and value 2 is meant to be inclusive and include value 1 and value 2. The inclusive range will span any value from about value 1 to about value 2. The term “adjacent” or “adjacent to,” as used herein, includes “next to,” “adjoining,” “in contact with,” and “in proximity to.”

As used herein, including in the claims, the conjunction “and/or” in a phrase such as “including X, Y, and/or Z”, refers to in inclusion of any combination or plurality of X, Y, and Z. For example, such phrase is meant to include X. For example, such phrase is meant to include Y. For example, such phrase is meant to include Z. For example, such phrase is meant to include X and Y. For example, such phrase is meant to include X and Z. For example, such phrase is meant to include Y and Z. For example, such phrase is meant to include a plurality of Xs. For example, such phrase is meant to include a plurality of Ys. For example, such phrase is meant to include a plurality of Zs. For example, such phrase is meant to include a plurality of Xs and a plurality of Ys. For example, such phrase is meant to include a plurality of Xs and a plurality of Zs. For example, such phrase is meant to include a plurality of Ys and a plurality of Zs. For example, such phrase is meant to include a plurality of Xs and Y. For example, such phrase is meant to include a plurality of Xs and Z. For example, such phrase is meant to include a plurality of Ys and Z. For example, such phrase is meant to include X and a plurality of Ys. For example, such phrase is meant to include X and a plurality of Zs. For example, such phrase is meant to include Y and a plurality of Zs.

The term “operatively coupled” or “operatively connected” refers to a first element (e.g., mechanism) that is coupled (e.g., connected) to a second element, to allow the intended operation of the second and/or first element. The coupling may comprise physical or non-physical coupling. The non-physical coupling may comprise signal-induced coupling (e.g., wireless coupling). Coupled can include physical coupling (e.g., physically connected), or non-physical coupling (e.g., via wireless communication).

An element (e.g., mechanism) that is “configured to” perform a function includes a structural feature that causes the element to perform this function. A structural feature may include an electrical feature, such as a circuitry or a circuit element. A structural feature may include a circuitry (e.g., comprising electrical or optical circuitry). Electrical circuitry may comprise one or more wires. Optical circuitry may comprise at least one optical element (e.g., beam splitter, mirror, lens and/or optical fiber). A structural feature may include a mechanical feature. A mechanical feature may comprise a latch, a spring, a closure, a hinge, a chassis, a support, a fastener, or a cantilever, and so forth. Performing the function may comprise utilizing a logical feature. A logical feature may include programming instructions. Programming instructions may be executable by at least one processor. Programming instructions may be stored or encoded on a medium accessible by one or more processors.

In some embodiments, an enclosure comprises an area defined by at least one structure. The at least one structure may comprise at least one wall. An enclosure may comprise and/or enclose one or more sub-enclosure. The at least one wall may comprise metal (e.g., steel), clay, stone, plastic, glass, plaster (e.g., gypsum), polymer (e.g., polyurethane, styrene, or vinyl), asbestos, fiber-glass, concrete (e.g., reinforced concrete), wood, paper, or a ceramic. The at least one wall may comprise wire, bricks, blocks (e.g., cinder blocks), tile, drywall, or frame (e.g., steel frame).

In some embodiments, a plurality of devices are operatively (e.g., communicatively) coupled to a control system. The plurality of devices may be disposed in a facility (e.g., including a building and/or room). The control system may comprise the hierarchy of controllers. The devices may comprise an emitter, a sensor, or a (e.g., tintable) window (e.g., IGU). The device may be any device as disclosed herein. At least two of the plurality of devices may be of the same type. For example, two or more IGUs may be coupled to the control system. At least two of the plurality of devices may be of different types. For example, a sensor and an emitter may be coupled to the control system. At times the plurality of devices may comprise at least about 20, 50, 100, 500, 1000, 2500, 5000, 7500, 10000, 50000, 100000, or 500000 devices. The plurality of devices may be of any number between the aforementioned numbers (e.g., from about 20 devices to about 500000 devices, from about 20 devices to about 50 devices, from about 50 devices to about 500 devices, from about 500 devices to about 2500 devices, from about 1000 devices to about 5000 devices, from about 5000 devices to about 10000 devices, from about 10000 devices to about 100000 devices, or from about 100000 devices to about 500000 devices). For example, the number of windows in a floor may be at least about 5, 10, 15, 20, 25, 30, 40, or 50. The number of windows in a floor can be any number between the aforementioned numbers (e.g., from 5 to 50, from 5 to 25, or from 25 to 50). At times the devices may be in a multi-story building. At least a portion of the floors of the multi-story building may have devices controlled by the control system (e.g., at least a portion of the floors of the multi-story building may be controlled by the control system). For example, the multi-story building may have at least about 2, 8, 10, 25, 50, 80, 100, 120, 140, or 160 floors that are controlled by the control system. The number of floors (e.g., devices therein) controlled by the control system may be any number between the aforementioned numbers (e.g., from about 2 to about 50, from about 25 to about 100, or from about 80 to about 160). The floor may be of an area of at least about 150 m², 250 m², 500 m², 1000 m², 1500 m², or 2000 square meters (m²). The floor may have an area between any of the aforementioned floor area values (e.g., from about 150 m² to about 2000 m², from about 150 m² to about 500 m², from about 250 m² to about 1000 m², or from about 1000 m² to about 2000 m²).

In some embodiments, the enclosure comprises one or more openings. The one or more openings may be reversibly closable. The one or more openings may be permanently open. A fundamental length scale of the one or more openings may be smaller relative to the fundamental length scale of the wall(s) that define the enclosure. A fundamental length scale may comprise a diameter of a bounding circle, a length, a width, or a height. The fundamental length scale may be abbreviated herein as “FLS.” A surface of the one or more openings may be smaller relative to the surface the wall(s) that define the enclosure. The opening surface may be a percentage of the total surface of the wall(s). For example, the opening surface can measure about 30%, 20%, 10%, 5%, or 1% of the walls(s). The wall(s) may comprise a floor, a ceiling or a side wall. The closable opening may be closed by at least one window or door. The enclosure may be at least a portion of a facility. The enclosure may comprise at least a portion of a building. The building may be a private building and/or a commercial building. The building may comprise one or more floors. The building (e.g., floor thereof) may include at least one of: a room, hall, foyer, attic, basement, balcony (e.g., inner or outer balcony), stairwell, corridor, elevator shaft, façade, mezzanine, penthouse, garage, porch (e.g., enclosed porch), terrace (e.g., enclosed terrace), cafeteria, and/or Duct. In some embodiments, an enclosure may be stationary and/or movable (e.g., a train, a plane, a ship, a vehicle, or a rocket).

In some embodiments, the enclosure encloses an atmosphere. The atmosphere may comprise one or more gases. The gases may include inert gases (e.g., argon or nitrogen) and/or non-inert gases (e.g., oxygen or carbon dioxide). The enclosure atmosphere may resemble an atmosphere external to the enclosure (e.g., ambient atmosphere) in at least one external atmosphere characteristic that includes: temperature, relative gas content, gas type (e.g., humidity, and/or oxygen level), debris (e.g., dust and/or pollen), and/or gas velocity. The enclosure atmosphere may be different from the atmosphere external to the enclosure in at least one external atmosphere characteristic that includes: temperature, relative gas content, gas type (e.g., humidity, and/or oxygen level), debris (e.g., dust and/or pollen), and/or gas velocity. For example, the enclosure atmosphere may be less humid (e.g., drier) than the external (e.g., ambient) atmosphere. For example, the enclosure atmosphere may contain the same (e.g., or a substantially similar) oxygen-to-nitrogen ratio as the atmosphere external to the enclosure. The velocity of the gas in the enclosure may be (e.g., substantially) similar throughout the enclosure. The velocity of the gas in the enclosure may be different in different portions of the enclosure (e.g., by flowing gas through to a vent that is coupled with the enclosure).

Certain disclosed embodiments provide a network infrastructure in the enclosure (e.g., a facility such as a building). The network may be installed when an envelope of an enclosure (e.g., a building) is constructed, and/or before an interior of the enclosure is constructed. The network may comprise wiring (e.g., cables) residing in the envelope of the enclosure (e.g., external walls of the enclosure such as a building). The network infrastructure is available for various purposes such as for providing communication and/or power services. The communication services may comprise high bandwidth (e.g., wireless and/or wired) communications services. The communication services can be to occupants of a facility and/or users outside the facility (e.g., building). The network infrastructure may work in concert with, or as a partial replacement of, the infrastructure of one or more cellular carriers. The network infrastructure can be provided in a facility that includes electrically switchable windows. Examples of components of the network infrastructure include a high speed backhaul. The network infrastructure may include at least one cable, switch, physical antenna, transceivers, sensor, transmitter, receiver, radio, processor and/or controller (that may comprise a processor). The network infrastructure may be operatively coupled to, and/or include, a wireless network. The network infrastructure may comprise wiring. One or more sensors can be deployed (e.g., installed) in an environment as part of installing the network and/or after installing the network. The network may be an encrypted network. The network may comprise one or more levels of encryption.

In some embodiments, the network infrastructure is operatively coupled to one or more sensors disposed in the enclosure. The sensor(s) may be configured to detect an environmental characteristic influenced by an individual present in the enclosure, and/or any gradient of that characteristic in the environment. The sensor may be able to sense and/or identify an abnormal influence on that environmental characteristic by the individual (e.g., excessive heat, perspiration, VOC, and/or carbon dioxide emission). In some embodiment, the sensor is configured to sense and/or identify one or more bodily characteristics emitted and/or expelled (e.g., directly) from the individual (e.g., heat, perspiration (e.g., humidity), VOCs (e.g., odor), and/or carbon dioxide). The bodily characteristic may comprise sebum, or urine. The VOCs can be reaction product(s) of compounds excreted by the individual. For example, formaldehyde, or (e.g., cyclic) methylsiloxane. In some embodiment, the sensor is configured to sense and/or identify one or more bodily characteristics of the individual (e.g., directly sense the individual). The sensor may be operatively coupled to a network (e.g., the network infrastructure disclosed herein). The sensed data may be analyzed and/or recorded. The analyzed data may be utilized to provide a report and/or alert. For example, the analyzed data may send an alert if the sensed data confines to a rule. The rule may comprise if the data is outside a threshold window, inside a threshold window, above a threshold, or below a threshold. The threshold may be a value or a function. The threshold may evolve in time, e.g., as more data emerges. The rule may be predetermined, e.g., by a user, by a third party, by a global and/or jurisdictional standard, or by any combination thereof.

In some embodiments, the abnormal bodily characteristic is related to an illness. The illness may relate to an inflammation. The illness may comprise pathogen (e.g., bacterial or viral) related infections. The pathogen may cause common cold, pneumonia or flu like symptoms. The pathogen may include streptococcus. The pathogen may comprise rhino, influenza, or corona virus. The illness may relate to an epidemic. The illness may relate to a respiratory and/or inflammatory disease. The illness may relate to an epithelial tissue and/or neuronal infectious disease. The illness may relate to a severe and/or acute disease. The illness may relate to nose, ear and/or throat infections. The illness may be contagious (e.g., by individuals). The illness may infect the bronchia and/or lungs. The illness may infect one or more internal organs and/or blood. The illness may comprise pneumonia, or flu. The illness may be caused by microorganisms, e.g., that invade at least one bodily tissue. The illness may be contagious having an Ro factor of at least about 0.5, 1, 1.5, 2, 2.5, or 3.

In some embodiments, one or more sensors may transmit the analyzed data, report and/or alert. The transmission may be to an individual and/or to a user. For example, the report may be transmitted to a party of interest. The party of interest may be an establishment head, a facility owner, a user, a tested individual. The data may be saved, analyzed and/or reported in compliance with jurisdictional rules and regulations. The report, notice, alert, and/or data may be transmitted to wired and/or wireless device (e.g., cell phone). For example, an individual tested may receive a sound, vibration, picture or written notice (e.g., alert). The transmission may comprise an encoding. The encoding may comprise one signal for an abnormal characteristic (e.g., suggesting an ill individual), and a second signal for a normal characteristic (e.g., suggesting a healthy individual). For example, a cell phone of a person my vibrate once when a temperature sensor does not sense an elevated temperature for the person and vibrate twice when the temperature sensor senses an elevated temperature for the person.

In some embodiments, the sensor(s) are disposed in an environment. A sensor may be attached to (or disposed in) at least one wall, ceiling, or floor of an enclosure. In an example, the sensor or an ensemble of sensors may dispose on the floor or in the floor. The ensemble of sensors may comprise a weight sensor, a movement sensor, and accelerometer, an audio sensor, or an optical sensor. At least one sensor in the ensemble may be able to sense and/or identify a presence of an individual, e.g., by sensing a person's weight, by sensing a person's sound, by sensing a person's obstruction of light, by sensing an approaching object associated with the person. For example, when an individual resides on a platform coupled to a weight sensor, the weight sensor may be able to sense and/or identify a weight associated with an individual. For example, when an individual obstructs a light ray (e.g., IR light ray) sensed by an optical sensor, the optical sensor may be able to sense and/or identify the obstruction of light. A requested position of the individual (e.g., testing station) may be marked on the floor (e.g., in a form of a shape such as a circle, square, or the letter X). The sensor(s) may be mounted on the door (e.g., door frame), or on the window (e.g., window frame). The enclosure may facilitate testing of a single individual or a plurality of individuals. There may be a single testing station (e.g., a kiosk) disposed in an enclosure, or a plurality of testing stations. Testing stations of the plurality of testing stations may be sufficiently distant to prevent contamination between individuals in the same room (e.g., prevents inter-contamination of individuals). The distance may be predefined and/or adjusted and/or defined per jurisdictional, global, and/or third party standards. The person may freely walk over and/or past the designated testing area or stay there for a time. The time in which the individual may be required to remain (e.g., substantially) stationary on the testing area may be at most about 1 second (sec), 3 sec, 5 sec, 10 sec, 30 sec, or 60 sec. The time in which the individual may be required to remain (e.g., substantially) stationary on the testing area may be any value between the aforementioned values (e.g., from about 1 sec to about 60 sec, from about 1 sec, to about 5 sec, from about 5 sec to about 30 sec, or from about 30 sec to about 60 sec). An individual may pass by the sensor(s) and be tested on every passing. This may allow for automatic testing of an individual multiple times in a single day, depending on how many times the individual passes by the testing station (e.g., by the sensor(s)). A plurality of test results may increase confidence in the results, reduce error values, and/or enable identification of relative changes between test results obtained at different times. If any of the sensors have a high fidelity, the sensor(s) may be able to provide information of trends of the characteristic in the individual in absolute and/or relative terms, e.g., over periods of time such as at least an hour, a day, a week, a month, or a year. If a sensor is uncalibrated or uncalibratable, and the sensor results are consistent over periods of usage, then the sensor may be able to provide information of trends of the characteristic in the individual in relative terms, e.g., over periods of time such as at least an hour, a day, a week, a month, or a year.

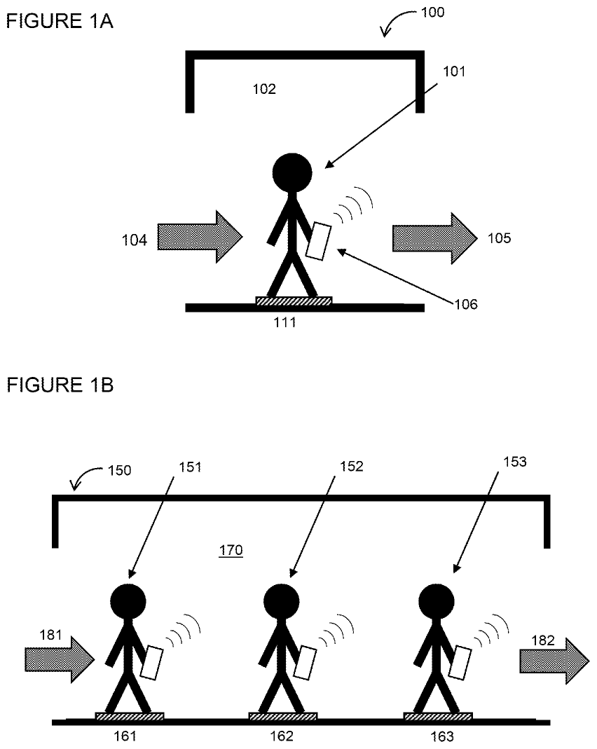

FIG. 1A shows a vertical cross sectional example of an enclosure 100 (e.g., a room) with an individual 101 therein, which enclosure has an environment 102 (e.g., atmosphere) and a testing platform 111. The enclosure has an ingress direction 104 and an egress direction 105. The individual can enter the enclosure from the ingress direction and exit the enclosure through the egress direction. The individual 102 can wait on the testing platform 111 for sensor(s) to sense and/or identify the environmental characteristic for a period of time (e.g., as indicated herein), or naturally walk by the testing station. The individual 102 may have a communication device 106 to which the analysis of the test may be communicated. the communication device may be communicatively coupled to a network (e.g., network infrastructure) of the facility in which the enclosure is disposed. The communication device may be a mobile device (e.g., cell phone, iPad, or laptop). The communication device may be a hand-held device. The network may be configured to support at least fourth or fifth generation cellular network communication.

The testing station (e.g., kiosk) may contain one or more sensors, e.g., that perform the environmental position and/or detect the presence of the individual. The testing station may be devoid of at least a sensor that perform the environmental position. The testing station may be devoid of at least a sensor that detect the presence of the individual. For example, a weight sensor may detect the presence of the individual and be disposed in testing platform. The temperature sensor that may detect the temperature of the environment in the enclosure may be disposed in the testing platform, or elsewhere in the enclosure. For example, an optical sensor (e.g., sensor sensitive to electromagnetic radiation such as in the infrared and/or visible range) may detect the presence of the individual and be disposed in the enclosure outside of the platform (e.g., not in the testing platform). The platform may be devoid of the one or more sensors. The testing platform may direct the individual where to position in order for the testing to be (e.g., optimally) performed. The ingress and/or ingress to the enclosure (e.g., doors) may be closed during testing. The sensor(s) may be disposed at a fixture of a facility (e.g., testing station, entrance hall, or conference room). The fixture may comprise a framing, a wall, a ceiling, or a floor. The framing may comprise a door framing or a window framing.

In some embodiments, an occupancy sensor is operatively coupled to the network. The occupancy sensor may be configured to sense and/or identify motion of, electromagnetic radiation associated with, and/or identification tag of, an occupant in the facility (or entering the facility). For example, the sensor may comprise a visible or an IR sensor. At times, the occupancy sensor may be unable to identify an identity of the occupant. The IR sensor may detect heat signature characteristic of individuals. The IR sensor may be part of a sensor system (e.g., a device ensemble). Data of the IR sensor may be integrated with visible data and/or motion data. The sensor system may be operatively coupled to the network and/or to the control system of the facility. The occupancy sensor (e.g., as part of the sensing system) may be utilized to determine density of individuals in an enclosure of the facility in which the occupancy sensor(s) is disposed and/or user of the enclosure by occupants (e.g., over time). The occupancy sensor may be operatively coupled to at least one processor. The occupancy sensor may be configured to detect movement of occupants. For example, the occupancy sensor may detect electromagnetic radiation emitted by and/or reflected from an occupant (e.g., IR radiation such as forming a heat signature of the individual), which detention may occur overtime. In some embodiments, using the occupancy sensor (e.g., as part of a sensor system such as a device ensemble) comprises measuring at a rate of at least about every 2 seconds (sec), 1 sec, 0.5 sec, 0.25 sec, 0.2 sec, 0.15 sec, 0.1 sec, 0.05 sec, or 0.025 sec. The occupancy sensor may comprise a camera. The camera may be configured to take at least about 30 frames per second (frm/sec), 20 frm/sec, 10 frm/sec, 8 frm/sec, 6 frm/sec, 4 frm/sec, or 2 frm/sec. The frequency of sensing (e.g., the number of measurements per second taken, such as the number of frames per seconds taken) may be adjusted (e.g., manually and/or automatically using at least one controller, e.g., as part of the control system). The camera may comprise an IR and/or a visible camera. The sensor system may be configured to detect a location of the occupant, e.g., relative to the facility, relative to the enclosure in which it is disposed, and/or in absolute coordinates (e.g., using a GPS or any other anchored geo-location technology). Detection of the occupant overtime and space may be utilized to determine a movement (e.g., including a movement direction) of the occupant. The movement direction of the occupant may comprise utilizing a tracking algorithm. Determination of occupancy and/or movement of the occupant may be determined to an accuracy of at least about 80%, 85%, 90%, 95%, or 99%. The tracking algorithm may be a tracking algorithms such as is disclosed in “Simple object tracking with OpenCV” by Adrian Rosebrock published on Jul. 23, 2018 and available at https://www.pyimagesearch.com/2018/07/23/simple-object-tracking-with-opencv, which is incorporated herein by reference in its entirety.

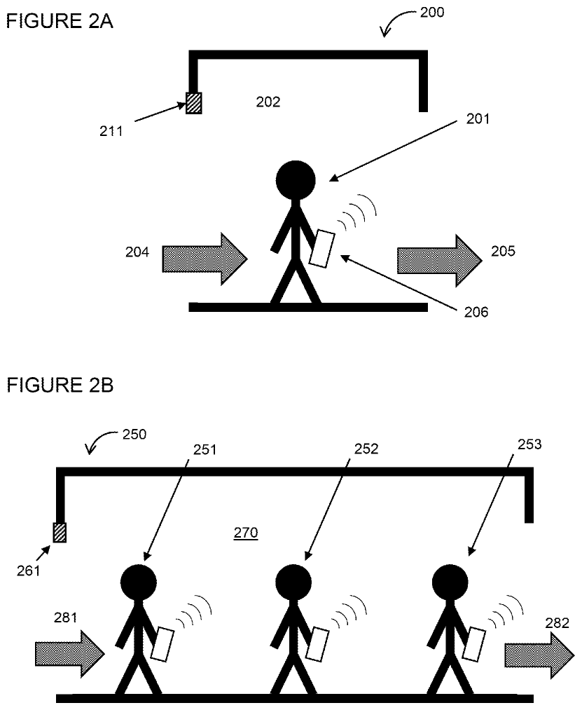

FIG. 1B shows a vertical cross sectional example of an enclosure 150 (e.g., a room) with individuals 151, 152, and 153 therein, which enclosure has an environment 170 (e.g., atmosphere) and testing platforms 161, 162, 162 above which the individuals stand and/or pass. The enclosure has an ingress direction 181 and an egress direction 182. The individual can enter the enclosure from the ingress direction and exit the enclosure through the egress direction through openings (e.g., doors). FIG. 2A shows a vertical cross sectional example of an enclosure 200 (e.g., a room) with an individual 201 therein, which enclosure has an environment 202 (e.g., atmosphere) and sensor(s) 211. The enclosure has an ingress direction 204 and an egress direction 105. The individual can enter the enclosure from the ingress direction and exit the enclosure through the egress direction. The individual 202 can enter through an opening (e.g., door) onto which the sensor(s) 211 attaches, so that sensor(s) can sense the environmental characteristic. The individual can naturally walk by the sensor(s) 211 or wait there for a period. The individual 202 may have a communication device 206 to which the analysis of the test may be communicated.

FIG. 2B shows a vertical cross sectional example of an enclosure 250 (e.g., a room) with individuals 251, 252, and 253 therein, which enclosure has an environment 270 (e.g., atmosphere) and sensor(s) 261. The individuals 251, 252, and 253 can enter through an opening (e.g., door) onto which the sensor(s) 261 attaches, so that sensor(s) can sense the environmental characteristic. The enclosure has an ingress direction 281 and an egress direction 282. The individual can enter the enclosure from the ingress direction and exit the enclosure through the egress direction through openings (e.g., doors).

In some embodiments, the control system is operatively (e.g., communicatively) coupled to an ensemble of devices (e.g., sensors and/or emitters). The ensemble facilitates the control of the environment and/or the alert. The control may utilize a control scheme such as feedback control, or any other control scheme delineated herein. The ensemble may comprise at least one sensor configured to sense and/or identify electromagnetic radiation. The electromagnetic radiation may be (humanly) visible, infrared (IR), or ultraviolet (UV) radiation. The at least one sensor may comprise an array of sensors. For example, the ensemble may comprise an IR sensor array (e.g., a far infrared thermal array such as the one by Melexis). The IR sensor array may have a resolution of at least 32×24 pixels, or 640×480 pixels. The IR sensor may be coupled to a digital interface. The ensemble may comprise an IR camera. The ensemble may comprise a sound detector. The ensemble may comprise a microphone. The ensemble may comprise any sensor and/or emitter disclosed herein. The ensemble may include CO₂, VOC, temperature, humidity, electromagnetic light, pressure, and/or noise sensors. The sensor may comprise a gesture sensor (e.g., RGB gesture sensor), an acetometer, or a sound sensor. The sounds sensor may comprise an audio decibel level detector. The sensor may comprise a meter driver. The ensemble may include a microphone and/or a processor. The ensemble may comprise a camera (e.g., a 4K pixel camera), a UWB sensor and/or emitter, a UHF sensor and/or emitter, a Bluetooth (abbreviated herein as “BLE”) sensor and/or emitter, a processor. The camera may have any camera resolution disclosed herein. One or more of the devices (e.g., sensors) can be integrated on a chip. The sensor ensemble may be utilized to determine presence of occupants in an enclosure, their number and/or identity (e.g., using the camera). The sensor ensemble may be utilized to control (e.g., monitor and/or adjust) one or more environmental characteristics in the enclosure environment.

The sensor(s) attached to the opening (e.g., door and/or window) by which the individual passes, may contain one or more sensors. The one or more sensors may perform the environmental position and/or detect the presence of the individual. The sensor(s) attached to the opening may be devoid of at least a sensor that perform the environmental position. The sensor(s) attached to the opening may be devoid of at least a sensor that detect the presence of the individual. For example, an environmental characteristic influenced by the individual (e.g., temperature) may be disposed in the sensor(s) attached to the opening or disposed elsewhere in the enclosure. For example, a sensor that senses the presence of the individual (e.g., optical sensor) may be attached to the opening, or disposed elsewhere in the enclosure. The system detecting an environmental characteristic(s) influenced by an individual may be devoid of any sensor that does not detect environmental characteristic(s). A sensor that does not detect environmental characteristic(s) may detect a presence of an individual (e.g., a weight sensor, or a camera). In some embodiments, a sensor that detects an environmental characteristic also detects the presence of an individual (e.g., infrared sensor, humidity sensor, or carbon dioxide sensor). In some embodiments, one or more openings in the enclosure remain open at least in part during the testing. For example, a door may be kept open while the sensors sense the temperature of an environment of the opening (e.g., and thus any perturbation thereof). The perturbation may be caused by an individual. An individual may have a typical manner of perturbing an environmental characteristic (e.g., within normal and/or abnormal range). In some embodiments, sensor(s) detecting whether a person influences an environmental change indicative of normal and/or abnormal personal characteristics is sufficient, e.g., and there is no additional requirement for a sensor dedicated to indicating presence or absence of the individual. For example, high fidelity (e.g., high resolution) sensors measuring a personal characteristic may be sufficient. For example, a sensor that (e.g., markedly) perturbs an ambient environmental characteristic may be sufficient. A high fidelity sensor may have more than one single pixel detector. A high fidelity sensor may comprise a plurality (e.g., an array) of single pixel detectors. A high fidelity sensor may be configured to detect a span of values of the detectable properties. For example, an amplitude span (e.g., range). For example, a wavelength span (e.g., including a plurality of wavelengths). For example, a thermal detector may be an optical detector (e.g., an infrared (IR) detector), and may be able to detect a plurality of IR wavelengths (e.g., within a wavelength range). A marked perturbation may have a high signal to noise ratio that is detectibly different from a signal at ambient conditions. In some embodiments, sensor(s) detecting the environmental characteristic (e.g., temperature) form an array of sensors. The array of sensors may be included in an ensemble. The ensemble and/or sensor(s) therein may have a small FLS, small form factor (e.g., volume to height ratio), may be of low cost, may be Bluetooth enabled (e.g., comprise a Bluetooth adaptor), and/or require low power. The small FLS may be of at most about 20 millimeters (mm), 10 mm, 8 mm, 6 mm, 5 mm, 4 mm, 3 mm, 2 mm or 1 mm. The small FLS may be of any value between the aforementioned values (e.g., from about 20 mm to about 1 mm, from about 20 mm to about 8 mm, or from about 8 mm to about 1 mm). The low power required by the ensemble and/or sensor(s) therein may be of at most about 1500 microwatts (W), 1000 W, 800 W, 500 W, or 250 W. The low power required by the ensemble and/or sensor(s) therein may be between any of the abovementioned power values (e.g., from about 1500 W to about 250 W, from about 1500 W to about 500 W, or from about 500 W to about 250 W).

In some embodiments, the testing station includes a barrier. The barrier may selectively allow an individual to pass therethrough. The barrier may comprise one or more doors that (i) hinder an occupant from walking therethrough (e.g., block passage of the occupant) when the door(s) are closed or (ii) allow the occupant to walk past the door(s) when they are open. The doors may comprise a transparent material or a non-transparent material. The door may comprise glass, polymeric, or metallic material. The door may swivel about a hinge. The door may slide, e.g., on bearings. The door may be a rolling door, e.g., about an axle. The door may be operatively coupled (e.g., connected) to one or more posts. The door may be operatively coupled (e.g., connected) to a separator. The separator may facilitate separation of occupants. The separator may comprise a cavity. The cavity may comprise one or more circuitry. The door may automatically and/or reversibly open and close. Closure and opening of the door may be controller by one or more controllers (e.g., as disclosed herein). The door may be operatively coupled to an actuator configured to facilitate opening and/or closing the door, e.g., upon signal received from the controller(s). The actuator may be operatively coupled to the controller(s), e.g., via a network. The separator may or may not comprise at least one controller configured to control the opening and/or closing of the door. The separator may comprise the actuator. The barrier apparatus may include a security gate, a bar, a stile such as a turnstile (e.g., tripod turnstile), and/or a swing gate. The turnstiles may be instead or in addition to the door. The bar and/or stile may comprise any material disclosed herein (e.g., door material) The barrier may comprise an access control barrier. The door may be a fraction of an average individual height. The fraction may be at least about 0.25, 0.3, 0.4, 0.5, 0.75, 1, 1.25, or 1.5 times a height of an average individual.

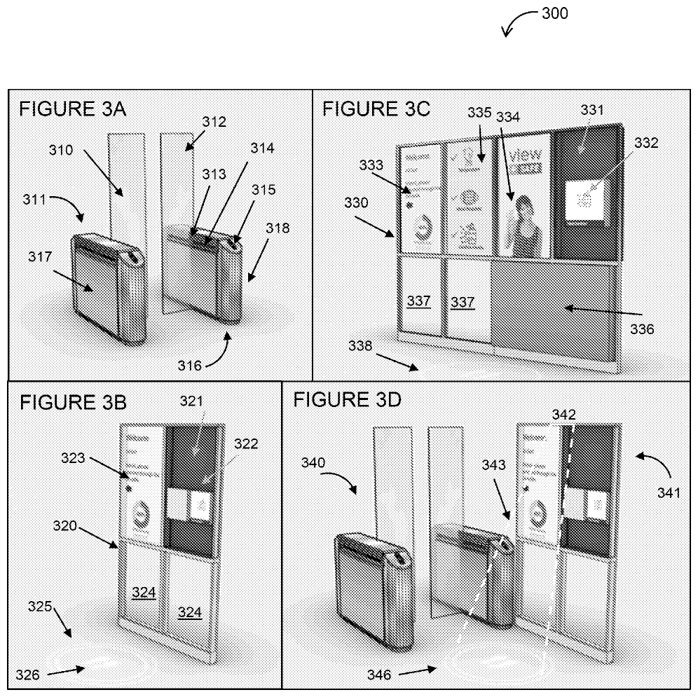

FIG. 3A shows an example of a door 310 coupled to a separator 311, and a door 312 coupled to a separator 316 by a hinge 313. Separator 316 comprises compartments 314 and 315 that may comprise apparatus(es) for validating and/or interacting with an individual. The cavities may comprise one or more sensors, e.g., that senses one or more characteristic of the environment and/or of the individual, e.g., while passing along the compartment and/or standing next to it. For example, the sensor may sense passing of the individual, and/or the identity of the individual. The compartments may comprise signaling emitters such as sound and/or light. The signaling may indicate if the individual is allowed to pass through the doors, or if the door mechanism malfunctions. For example, a red light may signal lack of authorization to enter, a green light may signal authorization to enter, and an orange light may signal malfunction. The sound may comprise a mechanical (e.g., buzzing sound), or a recording sound (e.g., human voice). The sound may contain a decipherable message (e.g., a sentence). The separator may be stationary. The separator may comprise a non-corrugated surface (e.g., a smooth surface) such as surface 317. The separator may comprise a rough and/or corrugated surface such as 318. The separator may comprise one or more slits and/or holes. The separator may comprise on or more lightings (e.g., disposed in the compartment). The slit and/or hole may facilitate transmission of environmental characteristic from the ambient environment to the sensor(s) disposed in the separator and/or emissions (e.g., sound and/or light) to travel from the separator interior into the ambient environment.

In some embodiments, the testing station includes one or more frames. The frames may hold an object. The frames and/or framed object may be modular. For example, the relative location of the frames and/or framed object may be altered. The framed object may comprise a window (e.g., tintable window), a board, and/or a display construct. The display construct may comprise a monitor (e.g., a computer or a television monitor). The display construct may comprise a light emitting diode (LED) array such as an organic LED array. The Organic LED array may be at least partially transparent (T-OLED). Examples of display construct, their operation and control can be found in U.S. Provisional Patent Application Ser. No. 62/975,706, filed on Feb. 12, 2020, titled “TANDEM VISION WINDOW AND MEDIA DISPLAY,” that is incorporated herein by reference in its entirety. The display construct may be disposed in the frame as a stand-alone framed object. The display construct may be disposed on a window (e.g., a tintable window). The framed object may comprise one or more dispensing and/or sanitation related apparatuses. The dispensing apparatuses may be configured to dispense a glove, a mask, a sanitation liquid, a badge, paper (e.g., tissue). The dispensing apparatus may be a printer (e.g., dispensing printed stickers or papers). The frame may comprise wiring. The frame may comprise one or more devices including a sensor, an emitter, an antenna, a controller, a circuitry, and/or a power source. The testing station may be operatively (e.g., communicatively) coupled to the network (e.g., and to one or more controllers). The display construct (e.g., OLED display) may display messages to an individual seeking to enter the facility. The display construct may display an image of a receptionist. The receptionist may be stationed in the facility or outside of the facility. The receptionist image may be of a live receptionist (e.g., interacting with the individual via video conferencing). The receptionist image may be of an animation. The testing station may comprise a signaling image. The signaling image may be stationary or non-stationary. The signaling image may be changing or non-changing over time. The signaling image may be permanent, or non-permanent (e.g., ephemeral). The signaling image may be transparent or non-transparent. The signaling image may be affixed (e.g., to a fixture of the enclosure such as a floor), or non-affixed. For example, the signaling image may comprise a sticker. The signaling image comprise a painting. The signaling image may comprise carving, embossing, or embroidery. The signaling image may be part of a fabric, e.g., a carpet. The signaling image may be a projection of light. The projection of flight may be changing or non-changing over time. The testing framing may comprise a projector projecting lighting on the individual and/or on the floor to form the signaling image. The projected lighting may signal an individual where to stand (e.g., a circle may be projected signaling the individual to stand in the circle). The projected lighting may signal an individual in what direction to stand (e.g., the projected lighting may comprise footprints of a stationary individual disposed in a direction, signaling the individual to stand in the direction). The projected lighting may signal an individual in what direction to walk (e.g., the projected lighting may comprise footprints of a walking individual disposed in a direction, signaling the individual to walk in the direction). The projection may be in a color. The projection may be a white projection. The color may signal if the individual is ready to proceed to the next stage in the admission process (e.g., a green color indicating that the individual is free to enter the facility). The color may signal if the individual is not ready to proceed to the next stage in the admission process (e.g., a red color indicating that the individual is unable to enter the facility). The color may signal an error or malfunction (e.g., an orange or yellow color indicating that there is an error in the process and/or in one of the components of the testing station).

FIG. 3B shows an example of a testing station comprising framing 320, and framed objects such as a board 321 comprising dispensing apparatus 322 attached thereto, display construct 323 displaying a message, and windows 324. The frame comprises a projector configured to project a signaling image (e.g., 325 and 326) of white light. The signaling image comprises circles 325 and footprint 326 of a stationary individual. The signaling image signals an individual to stand in the circles 325, facing the framing 320. The signaling image may facilitate close proximity and/or directionality of the individual to be sensed by the one or more sensors disposed in the framing 320. Any of the framed objects and/or frames may be modular. The signaling image may facilitate proximity of the individual to the dispensing apparatus and/or image projected by the display construct, thus facilitating the admission process to the facility. The framing may comprise any material disclosed herein (e.g., polymeric, metal, transparent, and/or non-transparent). The frame may comprise one or more holes and/or slits. The slit and/or hole may facilitate transmission of environmental characteristic from the ambient environment to the sensor(s) disposed in the separator and/or emissions (e.g., sound and/or light) to travel from the separator interior into the ambient environment.

FIG. 3C shows an example of a testing station comprising framing 330, and framed objects such as a board 331 comprising dispensing apparatus 332 attached thereto, display construct 333 displaying a message, display construct 334 displaying a receptionist, board 335 on which a poster is affixed, board 336, and windows 337. The testing station depicted in the example shown in FIG. 3C projects a signaling image 338. Any of the framed objects and/or frames (e.g., of FIGS. 3B-3D) may be modular.

In some embodiments, the framing apparatus (e.g., framing system) and the barrier apparatus are disposed in a reception area of the facility. The framing apparatus may be disposed in close proximity (e.g., contacting or non-contacting) the barrier apparatus. For example, the framing apparatus may be disposed in a walking distance from the barrier apparatus. The walking distance may comprise at most about 10, 8, 5, 3, or 2 average steps of an individual. FIG. 3D shows an example of a testing station comprising door and separator apparatus 340 and framing 341 disposed adjacent to each other in a walking distance of about one or two steps. The framing 341 comprises a projector 342 disposed in an internal volume of the framing, which projector projects light 434 to form a signaling image 346 on the floor adjacent to the framing 341. The framing apparatus may be utilized as a kiosk servicing one or more user (e.g., simultaneously).

The testing station may comprise a framing apparatus comprising framing (e.g., including a mullion and a transom) that frames one or more framed objects. An external surface of the framed object may comprise a smooth or a rough portion. The rough portion may be due to embossing, sanding, or scratching of the surface. The rough portion may comprise intrusions, extrusions, or an applicant. The applicant may comprise a mesh or a cloth. The rough portion may comprise a regular pattern or an irregular pattern. The framed object may be hollow or non-hollow. The framed object may comprise an internal cavity. The internal cavity may include at least one device (e.g., sensor, emitter, controller, circuitry (e.g., processor), computer, memory, radar, or antenna). The internal cavity may comprise a transceiver. The internal cavity may comprise a circuitry. The internal cavity may comprise wiring. The internal cavity may have a Bluetooth, Global Positioning System (GPS), UHF, and/or ultrawideband (UWB) device. the internal cavity may comprise a modem. The framed object may comprise one or more slits and/or holes. The framed object may comprise on or more lightings (e.g., disposed in the compartment). The slit and/or hole may facilitate transmission of environmental characteristic from the ambient environment to the sensor(s) disposed in the separator and/or emissions (e.g., sound and/or light) to travel from the separator interior into the ambient environment.

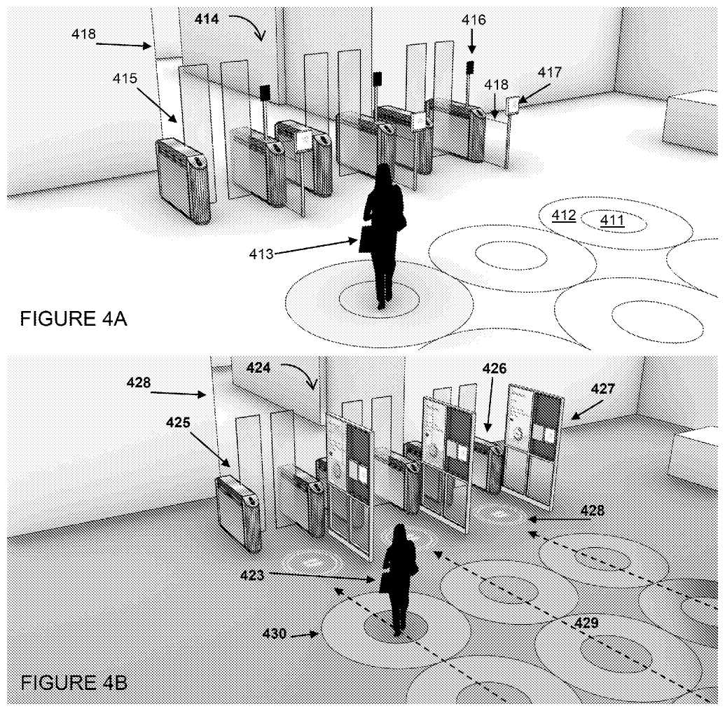

In some embodiments, the framing apparatus or the barrier apparatus are disposed in a reception area of the facility. The entrance is to the facility may comprise one or more signaling images, e.g., signaling individuals where to stand. The signaling image may signal individuals to stand at a prescribed distance from each other. The signaling image may comprise an inner shape of allowed standing area and a rim of non-allowed standing area. The signaling image may comprise a shape (e.g., a geometric shape). The shape may comprise an ellipsoid (e.g., a circle), or a polygon. The polygon may comprise a triangle (e.g., equilateral), rectangle (e.g., square), pentagon, hexagon, heptagon, or octagon. The polygon may be a right polygon. The rim may be of the same shape as the inner shape. The rim may be of a different shape from the inner shape. FIG. 4A shows an example of a reception area in a facility that comprises signaling shape having an internal shape 411 where an individual is allowed to stand (e.g., while waiting to engage with the testing station), and a rim 412 in which individuals should not stand, which internal shape and rim have a circular shape. The signaling shapes signal individuals such as 413 where to stand as they are waiting to interact with testing station 414, which testing station 414 comprises a barrier apparatus 415, a dispensing station 417, and a device housing 416 (e.g., including any device disclosed herein such as a sensor, and/or emitter). The device housing may comprise a device ensemble. In the example shown in FIG. 4A, the testing station is disposed in an entry way 418 to the facility. An individual 413 that wishes to enter the facility will have to cross testing station 414 to enter the facility, e.g., by opening the doors of testing station 414.

In some embodiments, the dispensing apparatus is operatively coupled to the network. The dispensing apparatus may be manually or automatically controlled. For example, the dispensing apparatus may be controlled by the controller(s). The dispensing apparatus may be operatively coupled (e.g., wired and/or wirelessly) to the network. The dispensing apparatus may be operatively (e.g., communicatively) coupled to the barrier apparatus and/or to the framing apparatus. The dispensing apparatus may be physically coupled (e.g., using an intermediate board) to the framing apparatus and/or barrier apparatus, e.g., for support and/or stability. The dispensing apparatus may be uncoupled and/or not-connected with the network. FIG. 4A shown an example in which the dispensing apparatus 417 is coupled to the barrier apparatus via a transparent board 418. The board can be any board disclosed herein.

FIG. 4B shown an example of a testing station 424 that comprises barrier apparatuses 425 and 426 and framing apparatus 427 disposed next to barrier apparatus 426. The testing station 424 is disposed in an entry way 428 to the facility such that an individual 423 will have to pass through the doors of testing station 428 to enter into the facility. Individuals are directed along signaling images (e.g., 430, comprising an internal circle and a circular rim) along a direction illustrated by broken lined arrows (e.g., 429) towards the testing station 424. An individual is further directed by projected image 428 to interact with the framing apparatus 427 and (if allowed) pass through the doors of barrier apparatus 426 in order to enter into the facility trough entry way 428.

In some embodiments, a testing station is disposed in an admission area of a facility. The admission may comprise one or more doors. The doors may be part of the testing station or not part of the testing station. The entry way may be restricting and allow a small number of individuals (e.g., at most 5, 4, 3, 2, or 1) to pass therethrough, or may be less restricting and allow a larger number of individuals to pass therethrough. The testing station may include one or more barrier apparatuses and/or one or more framing apparatuses. At least two barrier apparatuses in the testing station may be different from each other. At least two barrier apparatuses in the testing station may be similar to each other (e.g., 425 and 426 in FIG. 4B). At least two framing apparatuses in the testing station may be different from each other. At least two framing apparatuses in the testing station may be similar to each other. For example, in FIG. 4B all the framing apparatuses (e.g., 427) are similar to each other.

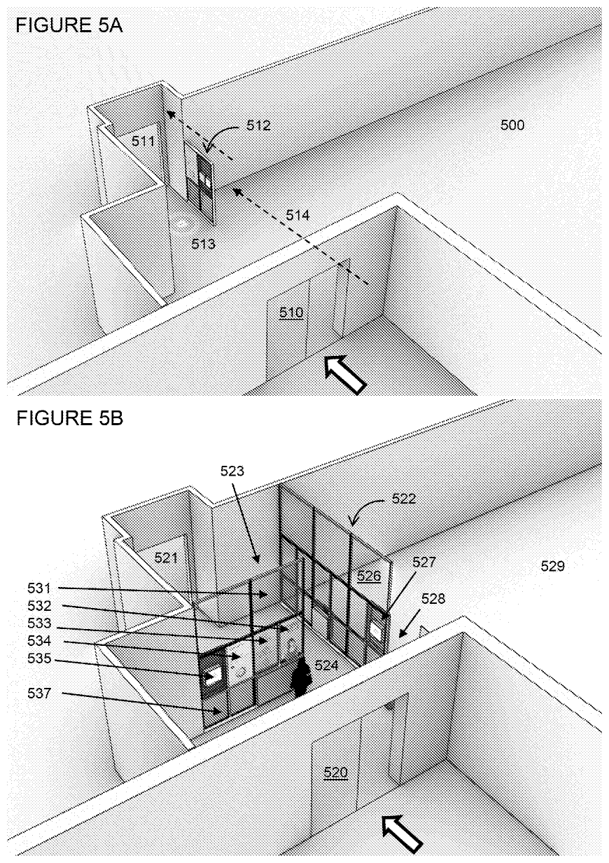

FIG. 5A shows an example of a facility having entry doors including door 510, and entry way 511. Testing station 512 comprising framing apparatus 512 that projects signaling image 513 is disposed next to entry way 511, which testing station is disposed on the way 514 from door 510 to entry way 511. The testing station 512 excludes a barrier apparatus. The walkway to entry way 511 is not restrictive and allows individuals to enter both enclosure 500 and entry way 511.

FIG. 5B shows an example of a facility having entry doors including door 520, and entry way 521. Testing station comprising framing apparatus 522 and 523. The testing station is disposed on the way that an individual 525 would take from door 520 to entry way 521. The testing station excludes a barrier apparatus. The walkway from door 520 to entry way 521 is more restrictive as compared to that of FIG. 5A in that it allows one individual (as opposed to several individuals) to comfortable enter both enclosure 529 and entry way 521. In the example shown in FIG. 5B, the framing apparatuses 522 and 523 are disposed at an angle from each other (e.g. about 90 degree angle). The framing apparatuses 522 and 523 are different. The framing apparatus 522 includes windows such as 526, and dispensing apparatus 527. The framing apparatus 523 includes windows such as 531, a display construct 532 that displays, e.g., a receptionist, a board 533 onto which a poster is affixed, a white board 534 displaying a message, a dispensing apparatus 535, and opaque (e.g., and textured) boards 537.

In some embodiments, the reception area may comprise components of the testing station (e.g., a barrier apparatus and a framing apparatus). At least two of the components may be the same. At least two of the components may be different. The two components may be disposed (e.g., substantially) parallel to each other. The two components may be disposed at an angle from each other. For example, the two components may form an angle with each other, which angle may be at least about 30 degrees (°), 60°, 90°, 120°, or 180°. The angle may have any value between the aforementioned values.

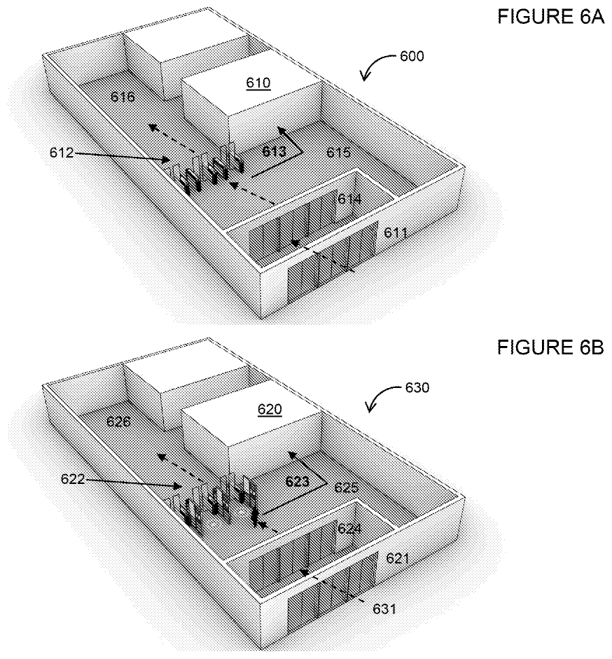

In some embodiments, the testing station is disposed in an enclosure comprising a secondary (e.g., manual and/or more rigorous) testing station. FIG. 6A shows an example of a testing station 612 comprising barrier apparatuses disposed at an entry pass way into a facility 600, which testing station 612 is disposed in a walkway of an individual that enters the facility through external doors 611, internal doors 614, reception area 615, and into the facility 616. The barrier apparatuses of 612 are disposed parallel to each other. When an individual is unable to pass the barrier apparatus 612 (e.g., since the individual fails the test), the individual is directed 613 to a secondary testing station 610. A nurse and/or security officer (present in person, present in image form through a display construct, or virtual through a display construct), interview and/or test the individual more rigorously as compared to the examination in testing station 612. FIG. 6B shows an example of a testing station 622 comprising parallel barrier apparatuses and framing apparatuses disposed at an entry pass way into a facility 630, which testing station 622 is disposed in a walkway of an individual that enters the facility through external doors 621 in a direction 631, which individual enters through internal doors 624, reception area 625, and into the facility 626. The barrier apparatuses of 622 are disposed parallel to each other. The framing apparatuses of 622 are disposed parallel to each other. The barrier apparatuses of 622 are disposed parallel to the framing apparatuses. Every framing apparatus of testing station 622 is disposed adjacent (e.g., contacting or not contacting) to at least one barrier apparatus. Every barrier apparatus of testing station 622 is disposed adjacent (e.g., contacting or not contacting) to at least one framing apparatus. A framing apparatus of the testing station 622 forms a pair with one barrier apparatus. When an individual is unable to pass the barrier apparatus 622 (e.g., since the individual fails the test), the individual is directed 623 to a secondary testing station 620.

In some embodiments, a framing apparatus forms a pair with a barrier apparatus. The framing apparatus and/or barrier apparatus may be coupled to a network (e.g., via wired and/or wireless communication). The framing apparatus and barrier apparatus may or may not be directly operatively (e.g., communicatively) coupled to each other. The framing apparatus and barrier apparatus may be operatively (e.g., communicatively) coupled to each other via the network. The framing apparatus and/or barrier apparatus may comprise at least one controller (e.g., disposed therein or thereon). The framing apparatus and barrier apparatus may be operatively (e.g., communicatively) coupled to at least one controller (e.g., via the network).

In some embodiments, an individual entering the facility undergoes one or more reception procedures (e.g., operations). The reception operations may relate to entry to an admission process, equipment dispensing, bodily characteristics (e.g., sanitation), barrier, and/or to a secondary check. If the individual is a non-employee, then the operations involve a host escorting the individual into the facility and/or signature of an agreement (e.g., non-disclosure agreement). The operations may be at any order.

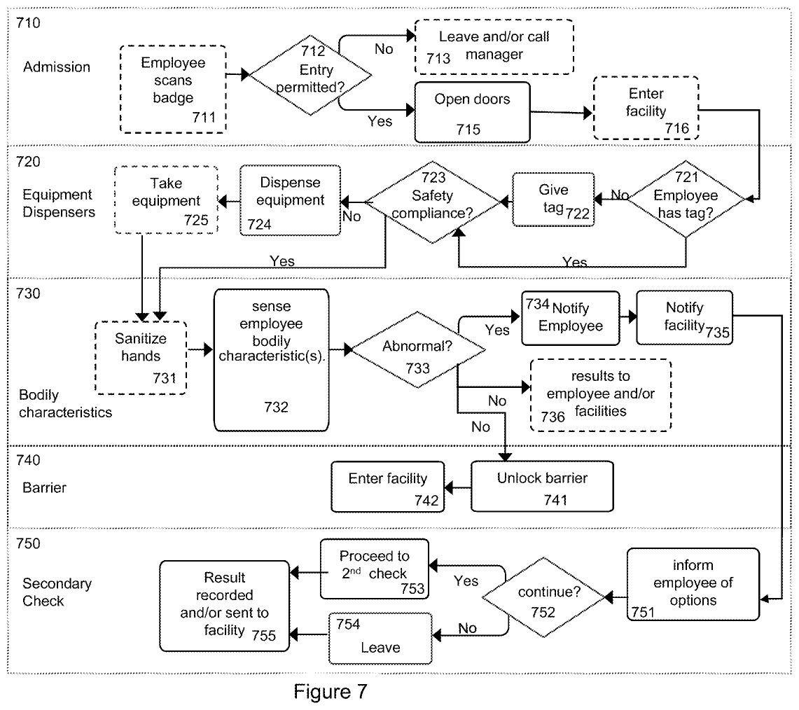

FIG. 7 shows a flowchart depicting the various operation relate to personnel (e.g., an employee) undergoing admission process 710, equipment dispensing 720, bodily characteristics 730, barrier 740, and a secondary check 750. Optional operations are depicted in dotted lines in FIG. 7. In the admission operation 710, the employee can optionally scan 711 the badge allowing him to enter the facility. The testing system assesses in 712 whether the employee is permitted into the facility. If the employee is not allowed to enter, then the employee is optionally directed to leave the facility and/or call a manager in operation 713. For example, the testing system can analyze whether the employee is pre-authorized to enter (e.g., the employee is in the employee roster, and no special direction to restrict the employee from entry is on file). If the employee is authorized to enter, the doors open in operation 715 and the employee either enters the facility directly in 716 or is directed to the equipment dispensing operation 720. The testing system then analyzes whether the employee has a tag in operation 721 (e.g., by scanning and/or sensing an identification of the employee using the tag). If the employee does not have a tag, the testing system can dispense and/or allow the employee a new tag in operation 722, which new tag is assigned to the employee. In operation 723, the testing system analyses whether the employee complies with equipment related safety protocols of the jurisdiction in which the facility is disposed and/or safety protocol of the facility (e.g., wearing protective gear such as a mask, lab coat, steal toed shoes, and/or safety goggles). If the employee does not comply, the testing system may dispense the required equipment in 724 or block the employee from entry until the employee appears with the safety compliance (blocking operation not shown). The testing system may ascertain that the employee has taken the equipment in optional operation 725. The employee will then undergo an operation 730 related to bodily characteristics (e.g., temperature or cough) in which the employee optionally (e.g., within jurisdictional and/or facility protocol) sanitizes any required body parts (e.g., hands) in operation 731, one or more bodily characteristics are sensed in operation 732 (e.g., using one or more sensors), the testing system then analyzes whether the bodily characteristic(s) are normal or abnormal (e.g., using threshold(s) and/or characteristic signature). If the bodily characteristic(s) of the employee are normal, then the testing system unlocks the barrier in operation 741 of the barrier operational stage 740, and the employee enters the facility in operation 742. Results of the analysis of the bodily characteristic(s) can be optionally sent to the employee and/or facility in operation 736. If the bodily characteristic(s) are found to be abnormal in 733, then the employee is notified in 734 and the facility is notified in 735. The employee is then informed of various options in operation 751. The employee should chooses in operation 752 (e.g., by entering the information into the system) if the employee wishes to continue with the admission process. If the employee wishes to continue, the employee is directed to proceed to a secondary check in operation 753 (e.g., a manual and/or more rigorous examination of the employee). If the employee does not wish to continue the admission process, the employee is sent away in operation 752. The results of the employee decision are sent to the facility and/or recorded.

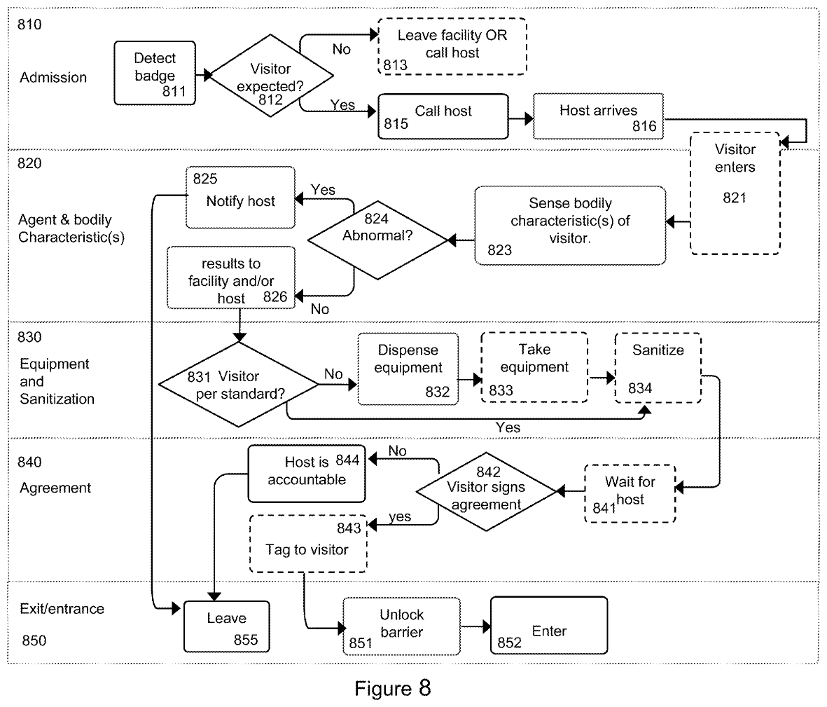

FIG. 8 shows a flowchart depicting various operation relate to personnel (e.g., a visitor, e.g., non-employee) undergoing admission process 810, agent and bodily characteristics 820, equipment dispensing 830, barrier 840, and entry into the facility 850. Optional operations are depicted in dotted lines in FIG. 8. In the admission operation 810, the testing system tries to detect an employee badge (e.g., tag). If the employee tag is detected, then the operations in FIG. 7 take place. If the tag is not detected (and the individual is not in the employee roster), then the testing system classifies the individual as a visitor. The testing system verifies if the visitor is allowed access into the facility in operation 812 checking if the visitor is expected. For example, the testing system can analyze whether the visitor is pre-authorized to enter (e.g., the visitor is in the visitor roster, and no special direction to restrict the visitor from entry is on file). If the visitor is not allowed to enter the facility, then the visitor is optionally directed to leave the facility and/or call a host in operation 813. If the visitor is authorized to enter, the visitor host is called in 815, and once the host arrives in 816, the doors and the visitor either enters the facility directly in 821 or is directed to the equipment dispensing operation 820. The testing system then senses (e.g., using sensor(s)) whether the bodily characteristic(s) of the visitor are within normal range or are abnormal in operation 823. If the bodily characteristic(s) are normal, then the host is notified in operation 825 and the employee is requested to leave the facility in operation 855. If the bodily characteristic(s) are not abnormal (e.g., are within normal range), then the results are notified (e.g., transmitted) to the facility and/or host in operation 826, and the visitor continues to the equipment and sanitation operation stage. In operation 831, the testing system analyses whether the visitor complies with equipment related safety protocols (e.g., standards) of the jurisdiction in which the facility is disposed and/or safety protocol of the facility (e.g., wearing protective gear such as a mask, lab coat, steal toed shoes, and/or safety goggles). If the employee does not comply, the testing system may dispense the required equipment in 832 or block the employee from entry until the employee appears with the safety compliance (blocking operation not shown). The system may ascertain that the employee has taken the equipment in optional operation 833. The employee may optionally be requested to sanitize body part(s) (e.g., hands) in operation 834. If the visitor is complies with equipment related safety protocols (e.g., standards), then the visitor may optionally be requested to sanitize body part(s) (e.g., hands) in operation 834. The testing system may or may not verify sanitation (e.g., using sensor(s)). Once the visitor complies with the equipment and sanitation operation stage 830, the visitor starts operation 840 relating to an agreement. The visitor is directed to wait for the host (e.g., if the host was did not arrive) in operation 841, and the visitor is requested to sign an agreement (e.g., non-disclosure agreement) in operation 842. If the visitor signs the agreement, a badge (e.g., tag) may be provided to the visitor in operation 843. If the visitor does not sign the agreement, then the host is accountable to the visitor in 844 (e.g., may ask the visitor to leave in operation 855). Once the visitor signs the agreement, the testing system unlocks the barrier in operation 851 of the exit/entrance operational stage 850, and the employee enters the facility in operation 852. Results of the analysis of the bodily characteristic(s) can be optionally sent to the visitor and/or facility. If the bodily characteristic(s) of the visitor are found to be abnormal, then the visitor may be notified (e.g., using a message such as through email, phone, text, sound, image, or print). The visitor may be informed of various options. The visitor should chooses (e.g., by entering the information into the system) if the visitor wishes to continue with the admission process. If the visitor wishes to continue, the visitor is directed to proceed to a secondary check (e.g., a manual and/or more rigorous examination of the employee). If the visitor does not wish to continue the admission process, the visitor is sent away from the facility. The results of the visitor decision may be sent to the facility and/or recorded.

In some embodiments, the testing system is operatively coupled to one or more controllers. The controllers are configured to control one or more devices of the facility. The analysis of the testing system may be carried out at least in part by the one or more controllers that control the facility (e.g., that may comprise or may operatively couple to a building management system).

In some embodiments, one or more sensors are attached to a mobile traveler. The traveler can be animate or inanimate. For example, the senor(s) can be carried by a person, that walks about a facility. For example, the sensor(s) can be carried by a transitory robot (e.g., self-propelled vehicle). For example, an airborne vehicle (e.g., a drone) or a ground transported vehicle (e.g., a wheeled vehicle). A location of the traveler may be known. The traveler and/or tested individual may identify its location. The location of the traveler and/or tested individual may be identified at least in part via electromagnetic radiation related technology, for example, via satellite (e.g., GPS), Bluetooth, UHF and/or UWB technology. The location of the traveler may be identified at least in part via at least one sensor in the facility (e.g., a radar, a moment sensor, an antenna, and/or an optical sensor (e.g., a camera such as a video camera)). The location of the traveler and/or tested individual may be identified at least in part via the mobile device (e.g., cellular phone) that the individual and/or traveler is carrying.

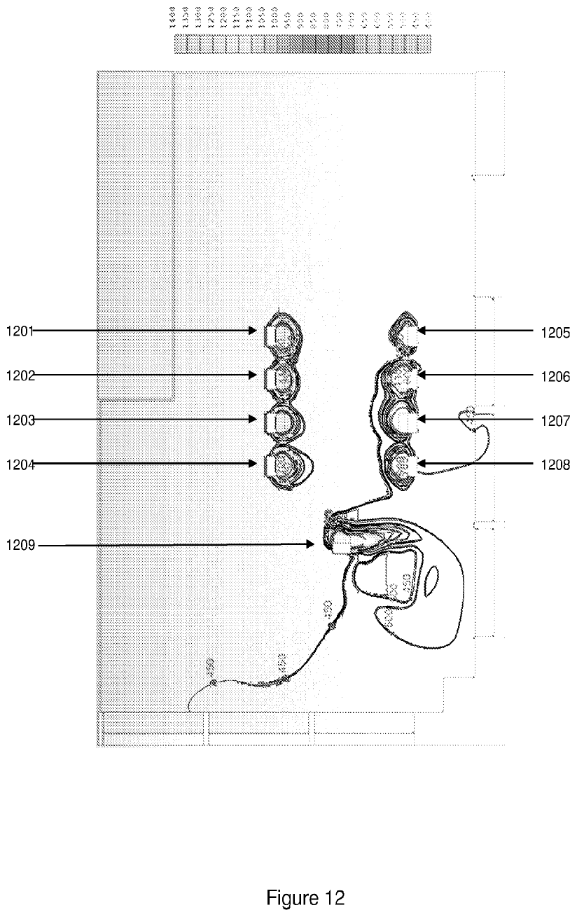

In some embodiments, an environmental property excreted and/or influenced by an individual has a propagation pattern in the environment. The propagation pattern may have a distinct and/or identified pattern, e.g., that can be measured by one or more sensors. For example, a heat emitted by an individual has a diffusion pattern in an environment atmosphere. For example, a carbon dioxide emission by an individual, has an emission pattern in an environment. For example, the carbon dioxide can be more pronounced around the mouth and the nose of the individual, e.g., and the expulsion rate, direction, pressure, and/or speed can be measured. In the example shown in FIG. 12, shows a contour map example of a horizontal (e.g., top) view of an office environment depicting various levels of CO₂ concentrations. Based on the expulsion of CO, and its concentration variation in the room, positions of nine individuals 1201-1209 can be identified. Moreover, the individuals 1201-1204 can be identified as facing individuals 1205-1208, and individual 1209 can be identified as positioned between the group of individuals 1201-1204 and the group of individuals 1205-1208, and normal thereto. Additionally, by considering the contour map, one can postulate that a wind is blowing in the direction from individuals 1201-1204 towards individuals 1205-1208, with the wind having an uneven affect in the room. The wind appears to have greater affect in the direction from individuals 1201 and 1205 towards individual 1209. The wind is least affecting individuals 1201 and 1205, more affecting individuals 1202 and 1206, even more affecting individuals 1203 and 1207, even more affecting individuals 1204 and 1208, and mostly affecting individual 1209. The wind could enter through an opening such as a vent, an open window, or an open door. Thus, a sensed environmental property in the room can be utilized (at least in party) to locate individual(s) in an enclosure.

The enclosure may have an ambient pressure and/or temperature. The enclosure may have a pressure different from an ambient pressure (e.g., lower and/or higher than the ambient pressure). The enclosure may have a temperature different from an ambient temperature (e.g., lower and/or higher than the ambient temperature). The enclosure be a specialized enclosure (e.g., configured to hold the pressure and/or temperature different from ambient temperature). The ambient pressure may be one atmosphere. The ambient temperature may be about 25° C. The ambient pressure and atmosphere may be standard pressure and atmosphere.

In some examples, data from a plurality of sensors (e.g., of the same type or of different types) can be utilized to assess the environment and individual(s) effect on the environment. Such assessment may shed light on the wellbeing of the individual (e.g., having normal or abnormal bodily characteristics). For example, temperature, humidity, and/or carbon dioxide patterns in an environment may be utilized to locate and/or assess the wellbeing of individual(s). data from the plurality of (e.g., different type of) sensors can be correlated (e.g., cross correlated).

In some embodiments, owners and/or users of the data may take actions if the individual exhibits one or more abnormal characteristics. For example, they may initiate medical treatment of the individual, quarantine the individual, and/or take steps to remove the individual (e.g., to reduce risk of harming others). In some embodiments, the control system of the facility may initiate an action. For example, the control system may after, or direct alteration of, the status of one or more devices operatively coupled to a building management system. For example, the control system may after, or direct alteration of, the status of an HVAC system, a lightening system, or a buzzer. For example, lighting may flash, buzzer will buzz, or ventilation will increase, in response to the result.

In some embodiments, an enclosure includes one or more sensors. The sensor may facilitate controlling the environment of the enclosure such that occupants of the enclosure may have an environment that is more comfortable, delightful, beautiful, healthy, productive (e.g., in terms of occupant performance), easer to live (e.g., work) in, or any combination thereof. The sensor(s) may be configured as low or high resolution sensors. Sensor may provide on/off indications of the occurrence and/or presence of a particular environmental event (e.g., one pixel sensors). In some embodiments, the accuracy and/or resolution of a sensor may be improved via artificial intelligence analysis of its measurements. Examples of artificial intelligence techniques that may be used include: reactive, limited memory, theory of mind, and/or self-aware techniques know to those skilled in the art). Sensors may be configured to process, measure, analyze, detect and/or react to one or more of: data, temperature, humidity, sound, force, pressure, electromagnetic waves, position, distance, movement, flow, acceleration, speed, vibration, dust, light, glare, color, gas(es), and/or other aspects (e.g., characteristics) of an environment (e.g., of an enclosure). The gases may include volatile organic compounds (VOCs). The gases may include carbon monoxide, carbon dioxide, water vapor (e.g., humidity), oxygen, radon, and/or hydrogen sulfide.

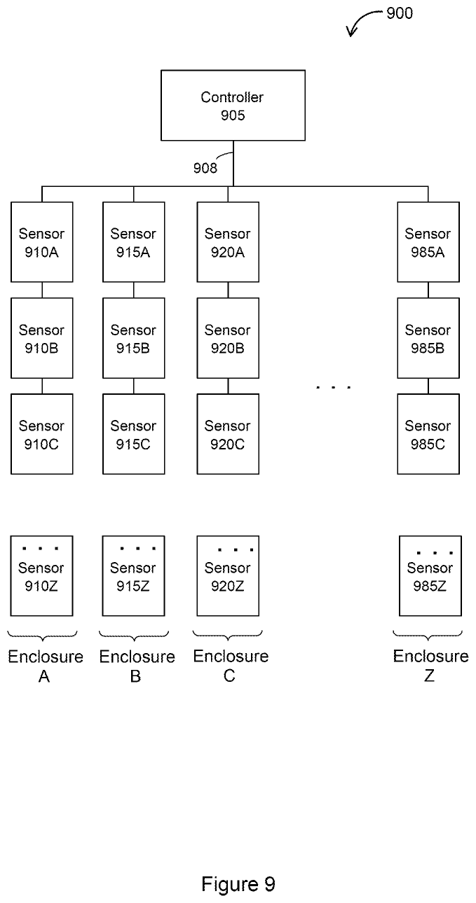

In some embodiments, processing sensor data comprises performing sensor data analysis. The sensor data analysis may comprise at least one rational decision making process, and/or learning. The sensor data analysis may be utilized to adjust and environment, e.g., by adjusting one or more components that affect the environment of the enclosure. The data analysis may be performed by a machine based system (e.g., a circuitry). The circuitry may be of a processor. The sensor data analysis may utilize artificial intelligence. The sensor data analysis may rely on one or more models (e.g., mathematical models). In some embodiments, the sensor data analysis comprises linear regression, least squares fit, Gaussian process regression, kernel regression, nonparametric multiplicative regression (NPMR), regression trees, local regression, semiparametric regression, isotonic regression, multivariate adaptive regression splines (MARS), logistic regression, robust regression, polynomial regression, stepwise regression, ridge regression, lasso regression, elasticnet regression, principal component analysis (PCA), singular value decomposition, fuzzy measure theory, Borel measure, Han measure, risk-neutral measure, Lebesgue measure, group method of data handling (GMDH), Naive Bayes classifiers, k-nearest neighbors algorithm (k-NN), support vector machines (SVMs), neural networks, support vector machines, classification and regression trees (CART), random forest, gradient boosting, or generalized linear model (GLM) technique. FIG. 9 shows an example of a diagram 900 of an arrangement of sensors distributed among enclosures. In the example shown in FIG. 9, controller 905 is communicatively linked 908 with sensors located in enclosure A (sensors 910A, 910B, 910C, . . . 910Z), enclosure B (sensors 915A, 915B, 915C, 915Z), enclosure C (sensors 920A, 920B, 920C, . . . 920Z), and enclosure Z (sensors 985A, 985B, 985C, . . . 985Z). Communicatively linked comprises wired and/or wireless communication. In some embodiments, a sensor ensemble includes at least two sensors of a differing types. In some embodiments, a sensor ensemble includes at least two sensors of the same type. In the example shown in FIG. 9, sensors 910A, 910B, 910C, . . . 910Z of enclosure A represent an ensemble. An ensemble of sensors can refer to a collection of diverse sensors. In some embodiments, at least two of the sensors in the ensemble cooperate to determine environmental parameters, e.g., of an enclosure in which they are disposed. For example, a sensor ensemble may include a carbon dioxide sensor, a carbon monoxide sensor, a volatile organic chemical sensor, an ambient noise sensor, a visible light sensor, a temperature sensor, and/or a humidity sensor. A sensor ensemble may comprise other types of sensors, and claimed subject matter is not limited in this respect. The enclosure may comprise one or more sensors that are not part of an ensemble of sensors. The enclosure may comprise a plurality of ensembles. At least two of the plurality of ensembles may differ in at least one of their sensors. At least two of the plurality of ensembles may have at least one of their sensors that is similar (e.g., of the same type). For example, an ensemble can have two motion sensors and one temperature sensor. For example, an ensemble can have a carbon dioxide sensor and an IR sensor. The ensemble may include one or more devices that are not sensors. The one or more other devices that are not sensors may include sound emitter (e.g., buzzer), and/or electromagnetic radiation emitters (e.g., light emitting diode). In some embodiments, a single sensor (e.g., not in an ensemble) may be disposed adjacent (e.g., immediately adjacent such as contacting) another device that is not a sensor. The controller may be communicatively coupled to the sensor ensemble or may be a part of the sensor ensemble.

Sensors of a sensor ensemble may collaborate with one another. A sensor of one type may have a correlation with at least one other type of sensor. A situation in an enclosure may affect one or more of different sensors. Sensor readings of the one or more different may be correlated and/or affected by the situation. The correlations may be predetermined. The correlations may be determined over a period of time (e.g., using a learning process). The period of time may be predetermined. The period of time may have a cutoff value. The cutoff value may consider an error threshold (e.g., percentage value) between a predictive sensor data and a measured sensor data, e.g., in similar situation(s). The time may be ongoing. The correlation may be derived from a learning set (also referred to herein as “training set”). The learning set may comprise, and/or may be derived from, real time observations in the enclosure. The observations may include data collection (e.g., from sensor(s)). The learning set may comprise sensor(s) data from a similar enclosure. The learning set may comprise third party data set (e.g., of sensor(s) data). The learning set may derive from simulation, e.g., of one or more environmental conditions affecting the enclosure. The learning set may compose detected (e.g., historic) signal data to which one or more types of noise were added. The correlation may utilize historic data, third party data, and/or real time (e.g., sensor) data. The correlation between two sensor types may be assigned a value. The value may be a relative value (e.g., strong correlation, medium correlation, or weak correlation). The learning set that is not derived from real-time measurements, may serve as a benchmark (e.g., baseline) to initiate operations of the sensors and/or various components that affect the environment (e.g., HVAC system, and/or tinting windows). Real time sensor data may supplement the learning set, e.g., on an ongoing basis or for a defined time period. The (e.g., supplemented) learning set may increase in size during deployment of the sensors in the environment. The initial learning set may increase in size, e.g., with inclusion of additional (i) real time measurements, (ii) sensor data from other (e.g., similar) enclosures, (iii) third party data, (iv) other and/or updated simulation.

In some embodiments, data from sensors may be correlated. Once a correlation between two or more sensor types is established, a deviation from the correlation (e.g., from the correlation value) may indicate an irregular situation and/or malfunction of a sensor of the correlating sensors. The malfunction may include a slippage of a calibration. The malfunction may indicate a requirement for re-calibration of the sensor. A malfunction may comprise complete failure of the sensor. In an example, a movement sensor may collaborate with a carbon dioxide sensor. In an example, responsive to a movement sensor detecting movement of one or more individuals in an enclosure, a carbon dioxide sensor may be activated to begin taking carbon dioxide measurements. An increase in movement in an enclosure, may be correlated with increased levels of carbon dioxide. In another example, a motion sensor detecting individuals in an enclosure may be correlated with an increase in noise detected by a noise sensor in the enclosure. In some embodiments, detection by a first type of sensor that is not accompanied by detection by a second type of sensor may result in a sensor posting an error message. For example, if a motion sensor detects numerous individuals in an enclosure, without an increase in carbon dioxide and/or noise, the carbon dioxide sensor and/or the noise sensor may be identified as having failed or as having an erroneous output. An error message may be posted. A first plurality of different correlating sensors in a first ensemble may include one sensor of a first type, and a second plurality of sensors of different types. If the second plurality of sensors indicate a correlation, and the one sensor indicates a reading different from the correlation, there is an increased likelihood that the one sensor malfunctions. If the first plurality of sensors in the first ensemble detect a first correlation, and a third plurality of correlating sensors in a second ensemble detect a second correlation different from the first correlation, there is an increased likelihood that the situation to which the first ensemble of sensors is exposed to is different from the situation to which the third ensemble of sensors are exposed to.

Sensors of a sensor ensemble may collaborate with one another. The collaboration may comprise considering sensor data of another sensor (e.g., of a different type) in the ensemble. The collaboration may comprise trends projected by the other sensor (e.g., type) in the ensemble. The collaboration may comprise trends projected by data relating to another sensor (e.g., type) in the ensemble. The other sensor data can be derived from the other sensor in the ensemble, from sensors of the same type in other ensembles, or from data of the type collected by the other sensor in the ensemble, which data does not derive from the other sensor. For example, a first ensemble may include a pressure sensor and a temperature sensor. The collaboration between the pressure sensor and the temperature sensor may comprise considering pressure sensor data while analyzing and/or projecting temperature data of the temperature sensor in the first ensemble. The pressure data may be (i) of a pressure sensor in the first ensemble, (ii) of pressure sensor(s) in one or more other ensembles, (iii) pressure data of other sensor(s) and/or (iv) pressure data of a third party.

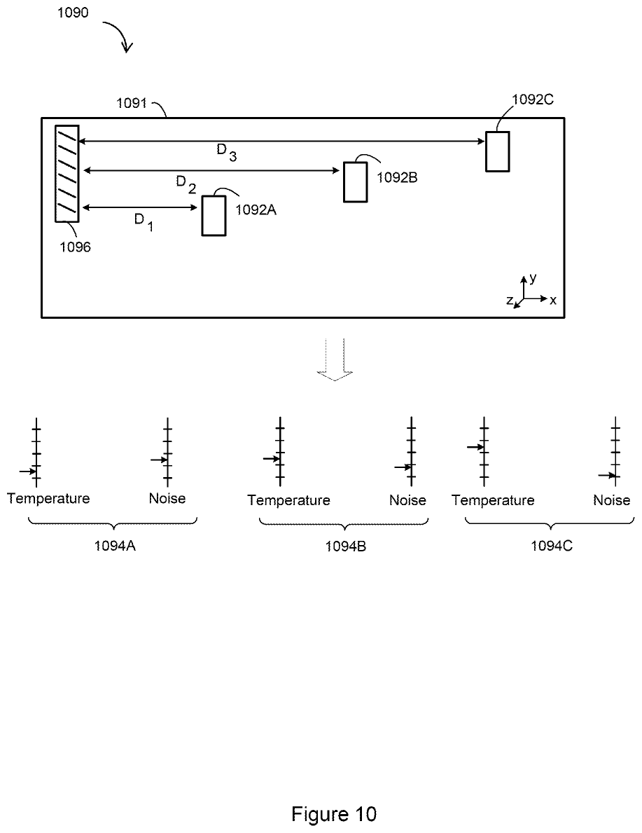

In some embodiments, sensor ensembles, are distributed throughout an enclosure. Sensors of a same type may be dispersed in an enclosure, e.g., to allow measurement of environmental parameters at various locations of an enclosure. Sensors of the same type may measure a gradient along one or more dimensions of an enclosure. A gradient may include a temperature gradient, an ambient noise gradient, or any other variation (e.g., increase or decrease) in a measured parameter as a function of location from a point. A gradient may be utilized in determining that a sensor is providing erroneous measurement (e.g., the sensor has a failure). FIG. 10 shows an example of a diagram 1090 of an arrangement of sensor ensembles in an enclosure. In the example of FIG. 10, ensemble 1092A is positioned at a distance D₁ from vent 1096. Sensor ensemble 1092B is positioned at a distance D₂ from vent 1096. Sensor ensemble 1092C is positioned at a distance Da from vent 1096. In the example of FIG. 10, vent 1096 corresponds to an air conditioning vent, which represents a relatively constant source of cooling air and a relatively constant source of white noise. Thus, in the example of FIG. 10, temperature and noise measurements are made by sensor ensemble 1092A. Temperature and noise measurements made by sensor 1092A are shown by output reading profile 1094A. Output reading profile 1094A indicates a relatively low temperature and a significant amount of noise. Temperature and noise measurements made by sensor ensemble 1092B are shown by output reading profile 1094B. Output reading profile 1094B indicates a somewhat higher temperature, and a somewhat reduced noise level. Temperature and noise measurements made by sensor ensemble 1092C are shown by output reading profile 1094C. Output reading profile 1094C indicates a temperature somewhat higher than the temperature measured by sensor ensemble 1092B and 1092A. Noise measured by sensor ensemble 1092C indicates a lower level than noise measured by sensor ensemble 1092A and 1092B. In an example, if a temperature measured by sensor ensemble 1092C indicates a lower temperature than a temperature measured by sensor ensemble 1092A, one or more processors and/or controllers may identify sensor ensemble 1092C sensor as providing erroneous data.

In another example of a temperature gradient, a temperature sensor installed near a window may measure increased temperature fluctuations with respect to temperature fluctuations measured by a temperature sensor installed at a location opposite the window. A sensor installed near a midpoint between the window and the location opposite the window may measure temperature fluctuations in between those measured near a window with respect to those measured at the location opposite the window. In an example, an ambient noise sensor installed near an air conditioning (or near a heating vent) may measure greater ambient noise than an ambient noise sensor installed away from the air conditioning or heating vent.

In some embodiments, a sensor of a first type cooperates with a sensor of a second type. In an example, an infrared radiation sensor may cooperate with a temperature sensor. Cooperation among sensor types may comprise establishing a correlation (e.g., negative or positive) among readings from sensors of the same type or of differing types. For example, an infrared radiation sensor measuring an increase in infrared energy may be accompanied by (e.g., positively correlated to) an increase in measured temperature. A decrease in measured infrared radiation may be accompanied by a decrease in measured temperature. In an example, an infrared radiation sensor measuring an increase in infrared energy that is not accompanied by a measurable increase in temperature, may indicate failure or degradation in operation of a temperature sensor.

In some embodiments, one or more sensors are included in an enclosure. For example, an enclosure may include at least 1, 2, 4, 5, 8, 10, 20, 50, or 500 sensors. The enclosure may include a number of sensors in a range between any of the aforementioned values (e.g., from about 1 to about 1000, from about 1 to about 500, or from about 500 to about 1000). The sensor may be of any type. For example, the sensor may be configured (e.g., and/or designed) to measure concentration of a gas (e.g., carbon monoxide, carbon dioxide, hydrogen sulfide, volatile organic chemicals, or radon). For example, the sensor may be configured (e.g., and/or designed) to measure ambient noise. For example, the sensor may be configured (e.g., and/or designed) to measure electromagnetic radiation (e.g., RF, microwave, infrared, visible light, and/or ultraviolet radiation). For example, the sensor may be configured (e.g., and/or designed) to measure security-related parameters, such as (e.g., glass) breakage and/or unauthorized presence of personnel in a restricted area. Sensors may cooperate with one or more (e.g., active) devices, such as a radar or lidar. The devices may operate to detect physical size of an enclosure, personnel present in an enclosure, stationary objects in an enclosure and/or moving objects in an enclosure.

In some embodiments, the sensor is operatively coupled to at least one controller. The coupling may comprise a communication link. A communications link (e.g., FIG. 9, 908) may comprise any suitable communications media (e.g., wired and/or wireless). The communication link may comprise a wire, such as one or more conductors arranged in a twisted-pair, a coaxial cable, and/or optical fibers. A communications link may comprise a wireless communication link, such as Wi-Fi, Bluetooth, ZigBee, cellular, or optical. One or more segments of the communications link may comprise a conductive (e.g., wired) media, while one or more other segments of a communications link may comprise a wireless link. The communication network may comprise one or more levels of encryption. The communication network may be communicatively coupled to the cloud and/or to one or more servers external to the facility. The communication network may support at least a third generation (3G), fourth generation wireless (4G), or fifth-generation wireless (5G) communication. The communication network may support cellular signals external and/or internal to the facility. The downlink communication network speeds may have a peak data rate of at least about 5 Gigabits per second (Gb/s), 10 Gb/s, or 20 Gb/s. The uplink communication network speeds may have a peak data rate of at least about 2 Gb/s, 5 Gb/s, or 10 Gb/s.

In some embodiments, the enclosure is a facility (e.g., building). The enclosure may comprise a wall, a door, or a window. In some embodiments, at least two enclosures of a plurality of enclosures are disposed in the facility. In some embodiments, at least two enclosures of a plurality of enclosures are disposed different facilities. The different facilities may be a campus (e.g. and belong to the same entity). At least two of the plurality of enclosures may reside in the same floor of the facility. At least two of the plurality of enclosures may reside in different floors of the facility. Enclosures of FIG. 9, such as enclosures A, B, C, and Z, may correspond to enclosures located on the same floor of a building, or may correspond to enclosures located on different floors of the building. Enclosures of FIG. 9 may be located in different buildings of a multi-building campus. Enclosures of FIG. 9 may be located in different campuses of a multi-campus neighborhood.

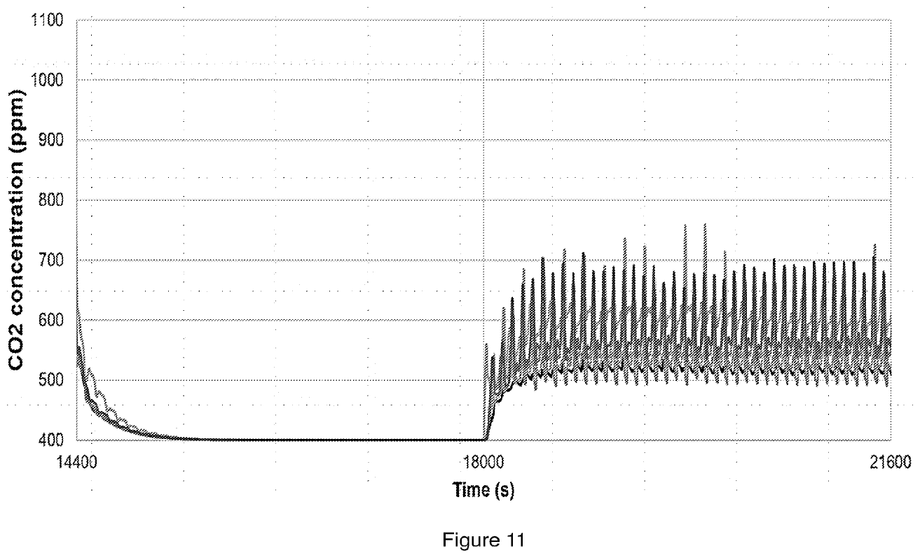

In an example, for gas sensors disposed in a room (e.g., in an office environment), a relevant parameter may correspond to gas (e.g., CO₂) levels, where desired levels are typically in a range of about 1000 ppm or less. In an example, a CO₂ sensor may determine that self-calibration should occur during a time window where CO₂ levels are minimal such as when no occupants are in the vicinity of the sensor (e.g. see CO₂ levels before 18000 seconds in FIG. 11). Time windows during which fluctuations in CO₂ levels are minimal, may correspond to, e.g., a one-hour period during lunch from about 12:00 PM to about 1:00, and during closed business hours. FIG. 12 shows a contour map example of a horizontal (e.g., top) view of an office environment depicting various levels of CO₂ concentrations. The gas (CO₂) concentrations may be measured by sensors placed at various locations of the enclosure (e.g., office).

Positional and/or stationary characteristics (e.g., placement of walls and/or windows) of the enclosure may be utilized in measuring the characteristics of a give environment. The positional and/or stationary characteristics of the enclosure may be derived independently (e.g., from 3^{rd} party data and/or from non-sensor data). The positional and/or stationary characteristics of the enclosure may be derived using data from the one or more sensors disposed in the environment. When the environment is minimally disturbed with respect to the measured environmental characteristic (e.g., when no one is present in an environment, and/or when the environment is quiet), some sensor data may be used to sense and/or identify position of (e.g., stationary and/or non-stationary) objects to determine the environment. Determining the position of objects comprises determining an (e.g., human) occupancy in the environment. Distance and/or location related measurements may utilize sensor(s) such as radar and/o ultrasonic sensors. Distance and location related measurements may derive from sensors that to not traditionally correlated to location and/or distance. Objects disposed in, or that are part of, an enclosure may have distinct sensor signatures. For example, location of people in the enclosure may correlate to distinct temperature, humidity and/or CO₂ signatures. For example, location of a wall may correlate to an abrupt change in the distribution of temperature, humidity and/or CO₂ in the enclosure. For example, location of a window or door (whether open or closed) may correlate to a change in the distribution of temperature, humidity and/or CO₂ next to the window or door. The one or more sensors in the enclosure may monitor any environmental changes and/or correlates such changes to changes in subsequently monitored values. In some cases, lack of fluctuations in monitored values may be used as an indication that a sensor is damaged, and that the sensor may need to be remove or replaced.

In some embodiments, a sensor transmits (e.g., beacons) data to a receiver, e.g., a sensor or suite of sensors. The suite of sensors can also be referred to as an “ensemble of sensors.” The sensors in the suite of sensors can be analogous to those deployed in a space of an enclosure.

In some embodiments, a plurality of sensors is assembled into a sensor suite (e.g., sensor ensemble). At least two sensors of the plurality of sensors may be of a different type (e.g., are configured to measure different properties). Various sensor types can be assembled together (e.g., bundled up) and form a sensor suite. The plurality of sensors may be coupled to one electronic board. The electrical connection of at least two of the plurality of sensors in the sensor suit may be controlled (e.g., manually and/or automatically). For example, the sensor suite may be operatively coupled to, or comprise, a controller (e.g., a microcontroller). The controller may control and on/off connectivity of the sensor to electrical power. The controller can thus control the time (e.g., period) at which the sensor will be operative.

In some embodiments, one or more sensors are added or removed from a community of sensors, e.g., disposed in the enclosure and/or in the sensor suite (e.g., sensor ensemble). Newly added sensors may inform (e.g., beacon) other members of a community of sensor of its presence and relative location within a topology of the community. Examples of sensor community(ies) can be found, for example, in U.S. Provisional Patent Application Ser. No. 62/958,653, filed Jan. 8, 2020, titled “SENSOR AUTOLOCATION,” that is incorporated by reference herein in its entirety. Examples of sensor, and sensor ensembles can be found, for example, U.S. Provisional Patent Application Ser. No. 62/967,204, filed Jan. 29, 2020 titled “SENSOR CALLIBRATION AND OPERATION,” that is incorporated by reference herein in its entirety. These examples include methods of their use, software and apparatuses in which they are utilized and/or included.

Sensors of a sensor ensemble may be organized into a sensor module. A sensor ensemble may comprise a circuit board, such as a printed circuit board, in which a number of sensors are adhered or affixed to the circuit board. Sensors can be removed from a sensor module. For example, a sensor may be plugged and/or unplugged from the circuit board. Sensors may be individually activated and/or deactivated (e.g., using a switch). The circuit board may comprise a polymer. The circuit board may be transparent or non-transparent. The circuit board may comprise metal (e.g., elemental metal and/or metal alloy). The circuit board may comprise a conductor. The circuit board may comprise an insulator. The circuit board may comprise any geometric shape (e.g., rectangle or ellipse). The circuit board may be configured (e.g., may be of a shape) to allow the ensemble to be disposed in a mullion (e.g., of a window). The circuit board may be configured (e.g., may be of a shape) to allow the ensemble to be disposed in a frame (e.g., door frame and/or window frame). The mullion and/or frame may comprise one or more holes to allow the sensor(s) to obtain (e.g., accurate) readings. The circuit board may include an electrical connectivity port (e.g., socket). The circuit board may be connected to a power source (e.g., to electricity). The power source may comprise renewable or non-renewable power source.

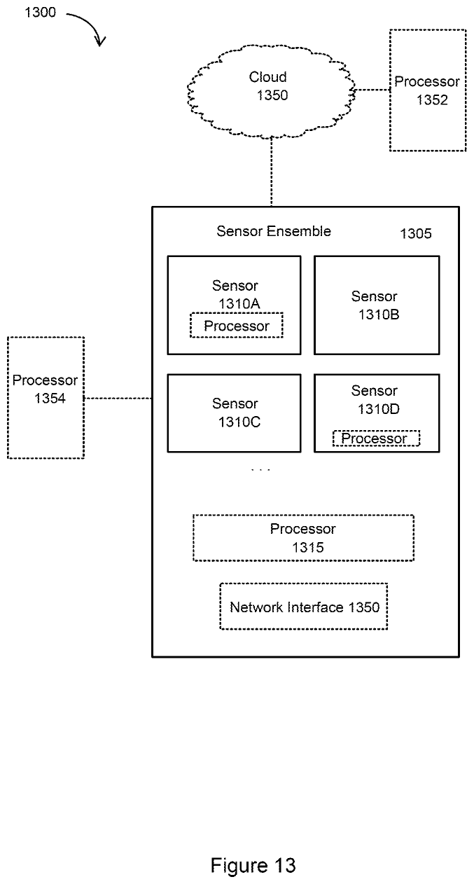

FIG. 13 shows an example of a diagram 1300 of an ensemble of sensors organized into a sensor module. Sensors 1310A, 1310B, 1310C, and 1310D are shown as included in sensor ensemble 1305. An ensemble of sensors organized into a sensor module may include at least 1, 2, 4, 5, 8, 10, 20, 50, or 500 sensors. The sensor module may include a number of sensors in a range between any of the aforementioned values (e.g., from about 1 to about 1000, from about 1 to about 500, or from about 500 to about 1000). Sensors of a sensor module may comprise sensors configured or designed for sensing a parameter comprising, temperature, humidity, carbon dioxide, particulate matter (e.g., between 2.5 μm and 10 μm), total volatile organic compounds (e.g., via a change in a voltage potential brought about by surface adsorption of volatile organic compound), ambient light, audio noise level, pressure (e.g. gas, and/or liquid), acceleration, time, radar, lidar, radio signals (e.g., ultra-wideband radio signals), passive infrared, glass breakage, or movement detectors. The sensor ensemble (e.g., 1305) may comprise non-sensor devices, such as buzzers and light emitting diodes. Examples of sensor ensembles and their uses can be found in U.S. patent application Ser. No. 16/447,169, filed Jun. 20, 2019, titled “SENSING AND COMMUNICATIONS UNIT FOR OPTICALLY SWITCHABLE WINDOW SYSTEMS,” that is incorporated herein by reference in its entirety.

In some embodiments, an increase in the number and/or types of sensors may be used to increase a probability that one or more measured property is accurate and/or that a particular event measured by one or more sensor has occurred. In some embodiments, sensors of sensor ensemble may cooperate with one another. In an example, a radar sensor of sensor ensemble may determine presence of a number of individuals in an enclosure. A processor (e.g., processor 1315) may determine that detection of presence of a number of individuals in an enclosure is positively correlated with an increase in carbon dioxide concentration. In an example, the processor-accessible memory may determine that an increase in detected infrared energy is positively correlated with an increase in temperature as detected by a temperature sensor. In some embodiments, network interface (e.g., 1350) may communicate with other sensor ensembles similar to sensor ensemble. The network interface may additionally communicate with a controller.

Individual sensors (e.g., sensor 1310A, sensor 1310D, etc.) of a sensor ensemble may comprise and/or utilize at least one dedicated processor. A sensor ensemble may utilize a remote processor (e.g., 1354) utilizing a wireless and/or wired communications link. A sensor ensemble may utilize at least one processor (e.g., processor 1352), which may represent a cloud-based processor coupled to a sensor ensemble via the cloud (e.g., 1350). Processors (e.g., 1352 and/or 1354) may be located in the same building, in a different building, in a building owned by the same or different entity, a facility owned by the manufacturer of the window/controller/sensor ensemble, or at any other location. In various embodiments, as indicated by the dotted lines of FIG. 13, sensor ensemble 1305 is not required to comprise a separate processor and network interface. The sensor ensemble can be an architectural element. These entities may be separate entities and may be operatively coupled to ensemble 305. The dotted lines in FIG. 13 designate optional features. In some embodiments, onboard processing and/or memory of one or more ensemble of sensors may be used to support other functions (e.g., via allocation of ensembles(s) memory and/or processing power to the network infrastructure of a building).

In some embodiments, a plurality of sensors of the same type may be distributed in an enclosure. At least one of the plurality of sensors of the same type, may be part of an ensemble. For example, at least two of the plurality of sensors of the same type, may be part of at least two ensembles. The sensor ensembles may be distributed in an enclosure. An enclosure may comprise a conference room. For example, a plurality of sensors of the same type may measure an environmental parameter in the conference room. Responsive to measurement of the environmental parameter of an enclosure, a parameter topology of the enclosure may be generated. A parameter topology may be generated utilizing output signals from any type of sensor of sensor ensemble, e.g., as disclosed herein. Parameter topologies may be generated for any enclosure of a facility such as conference rooms, hallways, bathrooms, cafeterias, garages, auditoriums, utility rooms, storage facilities, equipment rooms, and/or elevators.

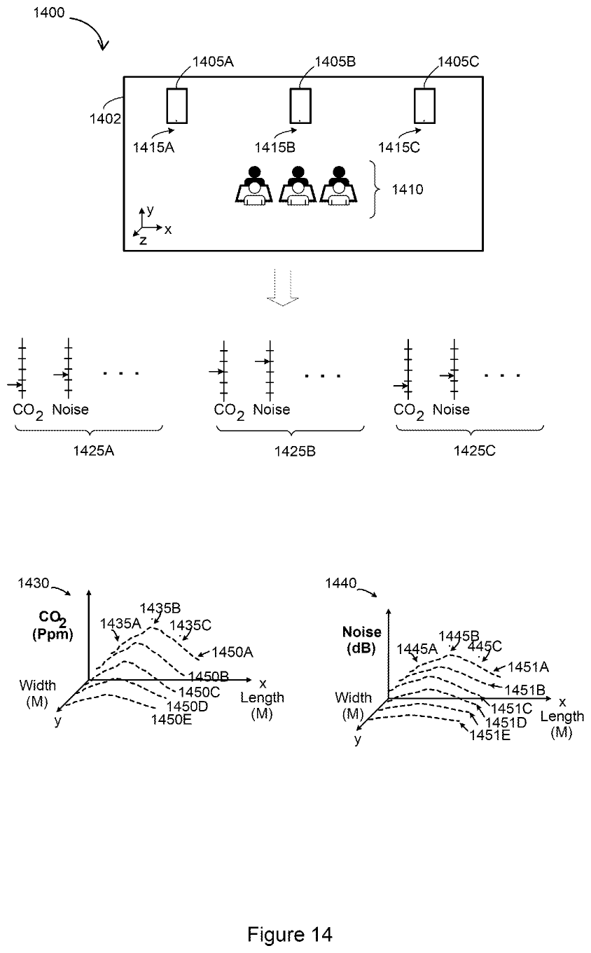

FIG. 14 shows an example of a diagram 1400 of an arrangement of sensor ensembles distributed within an enclosure. In the example shown in FIG. 14, a group 1410 of individuals are seated in conference room 1402. The conference room includes an “X” dimension to indicate length, a “Y” dimension to indicate height, and a “Z” dimension to indicate depth. XYZ being directions a Cartesian coordination system. Sensor ensembles 1405A, 1405B, and 1405C comprise sensors can operate similar to sensors described in reference to sensor ensemble 1305 of FIG. 13. At least two sensor ensembles (e.g., 1405A, 1405B, and 1405C) may be integrated into a single sensor module. Sensor ensembles 1405A, 1405B, and 1405C can include a carbon dioxide (CO₂) sensor, an ambient noise sensor, or any other sensor disclosed herein. In the example shown in FIG. 14, a first sensor ensemble 1405A is disposed (e.g., installed) near point 1415A, which may correspond to a location in a ceiling, wall, or other location to a side of a table at which the group 1410 of individuals are seated. In the example shown in FIG. 14, a second sensor ensemble 1405B is disposed (e.g., installed) near point 1415B, which may correspond to a location in a ceiling, wall, or other location above (e.g., directly above) a table at which the group 1410 of individuals are seated. In the example shown in FIG. 14, a third sensor ensemble 1405C may be disposed (e.g., installed) at or near point 1415C, which may correspond to a location in a ceiling, wall, or other location to a side of the table at which the relatively small group 1410 of individuals are seated. Any number of additional sensors and/or sensor modules may be positioned at other locations of conference room 1402. The sensor ensembles may be disposed anywhere in the enclosure. The location of an ensemble of sensors in an enclosure may have coordinates (e.g., in a Cartesian coordinate system). At least one coordinate (e.g., of x, y, and z) may differ between two or more sensor ensembles, e.g., that are disposed in the enclosure. At least two coordinates (e.g., of x, y, and z) may differ between two or more sensor ensembles, e.g., that are disposed in the enclosure. All the coordinates (e.g., of x, y, and z) may differ between two or more sensor ensembles, e.g., that are disposed in the enclosure. For example, two sensor ensembles may have the same x coordinate, and different y and z coordinates. For example, two sensor ensembles may have the same x and y coordinates, and a different z coordinate. For example, two sensor ensembles may have different x, y, and z coordinates.

In particular embodiments, one or more sensors of the sensor ensemble provide readings. In some embodiments, the sensor is configured to sense and/or identify a parameter. The parameter may comprise temperature, particulate matter, volatile organic compounds, electromagnetic energy, pressure, acceleration, time, radar, lidar, glass breakage, movement, or gas. The gas may comprise a Nobel gas. The gas may be a gas harmful to an average human. The gas may be a gas present in the ambient atmosphere (e.g., oxygen, carbon dioxide, ozone, chlorinated carbon compounds, or nitrogen). The gas may comprise radon, carbon monoxide, hydrogen sulfide, hydrogen, oxygen, water (e.g., humidity). The electromagnetic sensor may comprise an infrared, visible light, ultraviolet sensor. The infrared radiation may be passive infrared radiation (e.g., black body radiation). The electromagnetic sensor may sense radio waves. The radio waves may comprise wide band, or ultra-wideband radio signals. The radio waves may comprise pulse radio waves. The radio waves may comprise radio waves utilized in communication. The gas sensor may sense a gas type, flow (e.g., velocity and/or acceleration), pressure, and/or concentration. The readings may have an amplitude range. The readings may have a parameter range. For example, the parameter may be electromagnetic wavelength, and the range may be a range of detected wavelengths.

In some embodiments, the sensor data is responsive to the environment in the enclosure and/or to any inducer(s) of a change (e.g., any environmental disruptor) in this environment. The sensors data may be responsive to emitters operatively coupled to (e.g., in) the enclosure (e.g., an occupant, appliances (e.g., heater, cooler, ventilation, and/or vacuum), opening). For example, the sensor data may be responsive to an air conditioning duct, or to an open window. The sensor data may be responsive to an activity taking place in the room. The activity may include human activity, and/or non-human activity. The activity may include electronic activity, gaseous activity, and/or chemical activity. The activity may include a sensual activity (e.g., visual, tactile, olfactory, auditory, and/or gustatory). The activity may include an electronic and/or magnetic activity. The activity may be sensed by a person. The activity may not be sensed by a person. The sensors data may be responsive to the occupants in the enclosure, substance (e.g., gas) flow, substance (e.g., gas) pressure, and/or temperature.

In one example, sensor ensembles 1405A, 1405B, and 1405C include carbon dioxide (CO₂) sensor, and an ambient noise sensor. A carbon dioxide sensor of sensor ensemble 1405A may provide a reading as depicted in sensor output reading profile 1425A. A noise sensor of sensor ensemble 1405A may provide a reading also depicted in sensor output reading profile 1425A. A carbon dioxide sensor of sensor ensemble 1405B may provide a reading as depicted in sensor output reading profile 1425B. A noise sensor of sensor ensemble 1405B may provide a reading also as depicted in sensor output reading profile 1425B. Sensor output reading profile 1425B may indicate higher levels of carbon dioxide and noise relative to sensor output reading profile 1425A. Sensor output reading profile 1425C may indicate lower levels of carbon dioxide and noise relative to sensor output reading profile 1425B. Sensor output reading profile 1425C may indicate carbon dioxide and noise levels similar to those of sensor output reading profile 1425A. Sensor output reading profiles 1425A, 1425B, and 1425C may comprise indications representing other sensor readings, such as temperature, humidity, particulate matter, volatile organic compounds, ambient light, pressure, acceleration, time, radar, lidar, ultra-wideband radio signals, passive infrared, and/or glass breakage, movement detectors.

In some embodiments, data from a sensor in a sensor in the enclosure (e.g., and in the sensor ensemble) is collected and/or processed (e.g., analyzed). The data processing can be performed by a processor of the sensor, by a processor of the sensor ensemble, by another sensor, by another ensemble, in the cloud, by a processor of the controller, by a processor in the enclosure, by a processor outside of the enclosure, by a remote processor (e.g., in a different facility), by a manufacturer (e.g., of the sensor, of the window, and/or of the building network). The data of the sensor may have a time indicator (e.g., may be time stamped). The data of the sensor may have a sensor location identification (e.g., be location stamped). The sensor may be identifiably coupled with one or more controllers.

In particular embodiments, sensor output reading profiles 1425A, 1425B, and 1425C may be processed. For example, as part of the processing (e.g., analysis), the sensor output reading profiles may be plotted on a graph depicting a sensor reading as a function of a dimension (e.g., the “X” dimension) of an enclosure (e.g., conference room 1402). In an example, a carbon dioxide level indicated in sensor output reading profile 1425A may be indicated as point 1435A of CO₂ graph 1430 of FIG. 14. In an example, a carbon dioxide level of sensor output reading profile 1425B may be indicated as point 1435B of CO₂ graph 1430. In an example, a carbon dioxide level indicated in sensor output reading profile 425C may be indicated as point 1435C of CO₂ graph 1430. In an example, an ambient noise level indicated in sensor output reading profile 1425A may be indicated as point 1445A of noise graph 1440. In an example, an ambient noise level indicated in sensor output reading profile 1425B may be indicated as point 1445B of noise graph 1440. In an example, an ambient noise level indicated in sensor output reading profile 1425C may be indicated as point 1445C of noise graph 1440.

In some embodiments, processing data derived from the sensor comprises applying one or more models. The models may comprise mathematical models. The processing may comprise fitting of models (e.g., curve fitting). The model may be multi-dimensional (e.g., two or three dimensional). The model may be represented as a graph (e.g., 2 or 3 dimensional graph). For example, the model may be represented as a contour map (e.g., as depicted in FIG. 13). The modeling may comprise one or more matrices. The model may comprise a topological model. The model may relate to a topology of the sensed parameter in the enclosure. The model may relate to a time variation of the topology of the sensed parameter in the enclosure. The model may be environmental and/or enclosure specific. The model may consider one or more properties of the enclosure (e.g., dimensionalities, openings, and/or environmental disrupters (e.g., emitters)). Processing of the sensor data may utilize historical sensor data, and/or current (e.g., real time) sensor data. The data processing (e.g., utilizing the model) may be used to project an environmental change in the enclosure, and/or recommend actions to alleviate, adjust, or otherwise react to the change.

In particular embodiments, sensor ensembles 1405A, 1405B, and/or 1405C, may be capable of accessing a model to permit curve fitting of sensor readings as a function of one or more dimensions of an enclosure. In an example, a model may be accessed to generate sensor profile curves 1450A, 1450B, 1450C, 1450D, and 1450E, utilizing points 1435A, 1435B, and 1435C of CO₂ graph 1430. In an example, a model may be accessed to generate sensor profile curves 1451A, 1451B, 1451C, 1451B, and 1451E utilizing points 1445A, 1445B, and 1445C of noise graph 1440. Additional models may utilize additional readings from sensor ensembles (e.g., 1405A, 1405B, and/or 1405C) to provide curves in addition to sensor profile curves 1450 and 1451 of FIG. 14. Sensor profile curves generated in response to use of a model may sensor output reading profiles indicate a value of a particular environmental parameter as a function of a dimension of an enclosure (e.g., an “X” dimension, a “Y” dimension, and/or a “Z” dimension).

In certain embodiments, one or more models utilized to form curves 1450A-1450E and 1451A-1451E) may provide a parameter topology of an enclosure. In an example, a parameter topology (as represented by curves 1450A-1450E and 1451A-1451E) may be synthesized or generated from sensor output reading profiles. The parameter topology may be a topology of any sensed parameter disclosed herein. In an example, a parameter topology for a conference room (e.g., conference room 1402) may comprise a carbon dioxide profile having relatively low values at locations away from a conference room table and relatively high values at locations above (e.g., directly above) a conference room table. In an example, a parameter topology for a conference room may comprise a multi-dimensional noise profile having relatively low values at locations away from a conference table and slightly higher values above (e.g., directly above) a conference room table.

In some embodiments, sensor data corresponding to an individual is collected upon arrival and an entry station or admittance location to an enclosure (e.g., facility). See for example, FIGS. 4A and 4B for admittance location examples. In some embodiments, sensor data corresponding to the individual continues to be collected using additional sensors deployed throughout the facility, e.g., as the individual moves in the enclosure and as movement of the individual within the facility is tracked. Thus, abnormal bodily characteristics can be detected with at least one sensor located in a low, regular, and/or high traffic area of a facility at different times and/or with at least one sensor. The individual may be located in various areas of the facility at different times (e.g., times when the individual has moved into another area). The at least one sensor may be a plurality of sensors distributed in the enclosure, and configured to track the bodily characteristic of the individual at the different locations of the enclosure. The sensor data may be obtained from a single sensor having consistency in measurement results that can be compared at different times. In some embodiments, the sensor readings obtained at different times are compared to detect relative changes that may be indicative of a corresponding abnormality affecting the individual (e.g., if they exceed a threshold).

In some embodiments, sensor data is collected, compiled, and related to the individual person for whom measurements are obtained. The relation may comprise identification (ID) of the individual. The identification may or may not comprise personal data of the individual (e.g., name, home address, phone number, governmental identification number, fingerprint, retina scan, bodily features, and/or facial features). Sensor data (e.g., comprising raw and/or processed measurements) may be communicated to a database (e.g., via a controller or compiler) along with a respective sensor ID, and a time stamp (e.g., including time, and/or date). The person can be identified with a tag comprising geo-location technology, image processing of a person's face, size, gait, blood pressure, infrared (IR) signature, heart rate and/or any other personal characteristics (e.g., using radar, IR and the like). The geo-location technology may comprise radio frequency (e.g., RFID) chip. The geo-location technology may comprise BLE, GPS, or UWB technology. The communication can be to at least one software application (e.g., executing in a mobile device of the individual or of another person) and/or to a control system operatively coupled to the enclosure (e.g., building). The application (e.g., control system and/or phone app) may keep a table (for one or more users) of sensor IDs, bodily characteristic (e.g., temperature), and time stamp (e.g., time and date). Data may be collected overtime to determine a “normal” for each uniquely identified individual (e.g., building occupant). The collected data can be used as a baseline for deviation from the norm of that individual. Analysis of the collected data in the database relating to an individual may be performed on the basis of relative sensor data (e.g., for a particular sensor). For example, relative sensor measurements of the person collected at different times may be compared. Since relative measurements are being used, the sensor from which the data is obtained may not need to be calibrated. Absolute values of the sensor data may be immaterial as long as the increments measured by the sensor are accurate (e.g., as long as the relative measurements are accurate).

In some embodiments, if a relative difference between sensor measurement exceeds a threshold, an event is triggered (e.g., a notification event). In order to ascertain a relative difference threshold to be used as a trigger that identifies an abnormal condition, a person can be monitored overtime to learn personal bodily characteristic behavior (e.g., oscillations) and behavioral patterns. Monitoring may be performed using a learning module. The learning module may include artificial intelligence (Ai) comprised of machine learning. In one example, an individual occupant and/or user of an enclosure (e.g., wherein the user has a unique identifier such as “123”) may routinely work out at lunch time, and thus their temperature and heartrate may usually increase dramatically during that time period. The Ai may take this into account when considering an adverse variation in characteristics for user #123. For example, a temperature, blood pressure, heart rate, etc., of the individual may change according to normal cycles during the course of a day; and these patterns (which may be unique for the individual) may be recorded and norms for the corresponding individual may be established. Seasonal variables and/or other extrinsic factors (referred to herein as “paradigms”) can be input to the ML for improved accuracy. Some such paradigms can be quantified when sensor data is collected. Quantified values can be stored together with the sensor data for use in data analysis, e.g., to determine normal ranges of bodily characteristics of the individual during various paradigms. Once an abnormal condition has been detected for an individual, a report may be generated. Optionally, a notification system may be activated to provide a notification to the affected individual. In some embodiments, notifications are (e.g., also) sent to contactees who may have been exposed to the affected individual.

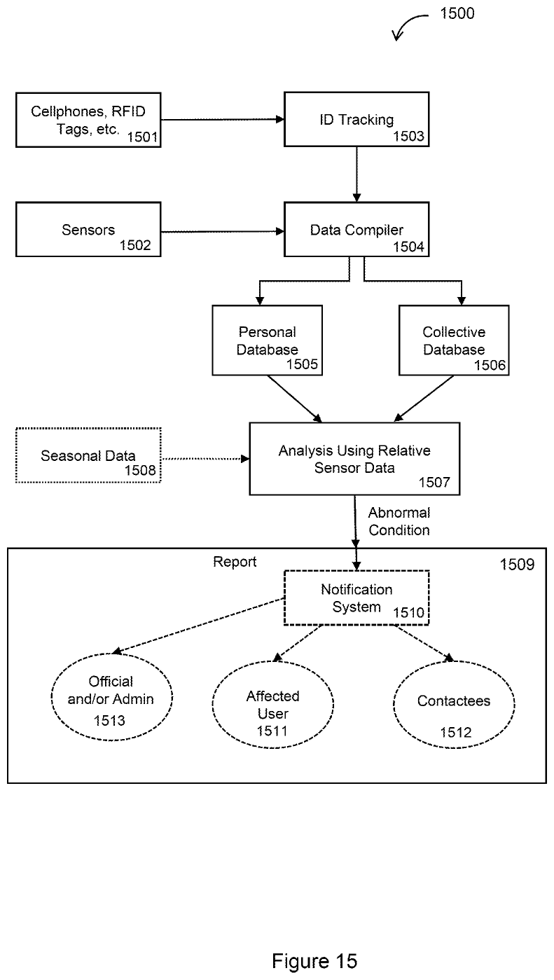

FIG. 15 shows a monitoring system 1500 to monitor one or more characteristic of an individual. To facilitate the identification of individual users within a facility, an individual may possess a trackable devices 1501 such as a cellphone, smartphone, or RFID tag (e.g., incorporated into an identification/access badge). One or more sensors 1502 (e.g., sensor ensembles) may be deployed at a controlled access point and/or arbitrary locations throughout a facility for sensing characteristics of the users at various times. In some embodiments, a trackable device is not needed, provided that individuals can be identified relying only on sensor data (e.g., facial recognition using camera images, or any other unique identifiable characteristic(s) of the individual).

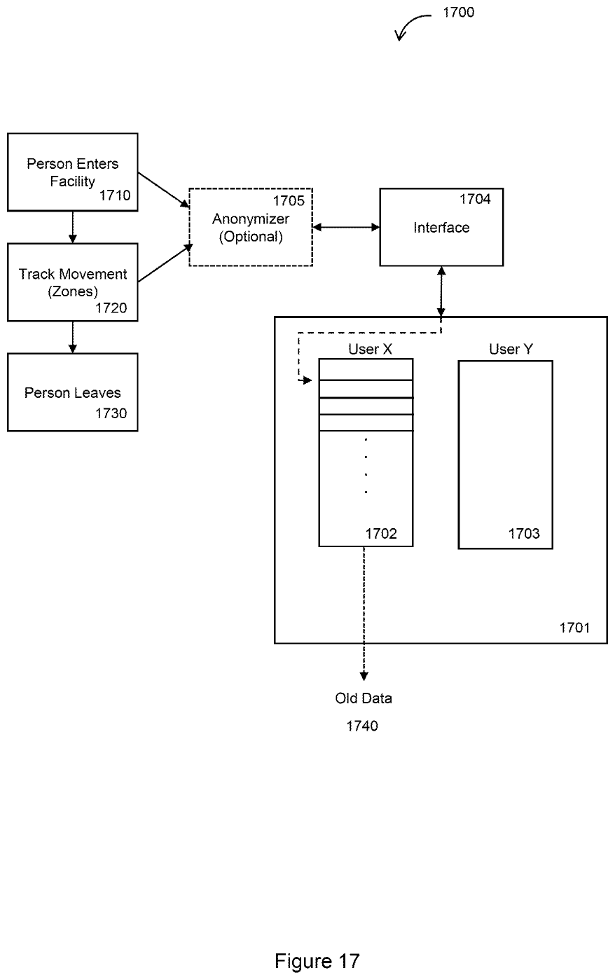

A controller system includes modules for ID and location tracking 1503 and a data compiler 1504. Using sensor data from sensors 1502 and user identifiers from ID tracking module 1503, data compiler 1504 organizes the sensor data according to individuals (e.g., users), sensor ID, time, and date, to support the analysis of a bodily characteristic of each tracked user over a span of time. The organized data can be stored in a personal database 1505 and/or a collective database 1506. Personal database 1505 may be stored in a mobile device carried by the user (e.g., a smartphone executing the corresponding app) or other personal device such as a laptop computer. Collective database 1506 may be stored in a networked controller in the facility or external to the facility (e.g., remotely via a cloud). Use of collective database 1506 may be beneficial in connection with tracking multiple users, and optionally performing notifications and contact tracing as described below (e.g., FIG. 17).

For users represented in database 1505 and/or 1506, the stored sensor data is analyzed according to relative changes of bodily characteristics 1507. The analysis can use learning module (e.g., artificial intelligence comprising machine learning). Learning module 1507 may be implemented in the networked controller or in the dedicated user device (e.g., smartphone). In some embodiments, when new sensor data for a corresponding user is obtained and entered into database 1505 or 1506, the analysis module 1507 makes a determination whether sufficient data is stored in order to identify a relevant normal for the sensed characteristic that can be used for a comparison. Seasonal data 1508, other environmental, and/or other circumstantial factors may be provided to analysis module 1507, e.g., to improve determinations of the appropriate normal to be applied. A report is provided in 1509 by the analysis module. When the newly collected sensor data indicates an abnormal condition (e.g., a difference between the new sensor data and the calculated norm is greater than a threshold), a notification system 1510 is optionally activated, e.g., to send out various notifications (e.g., a text message or email) to an affected user 1511, and/or contactees 1512 who may have been in proximity to user 1511 during the abnormal condition (e.g., for a time period above a time-threshold), and/or to a central administrator and/or health official 1513.

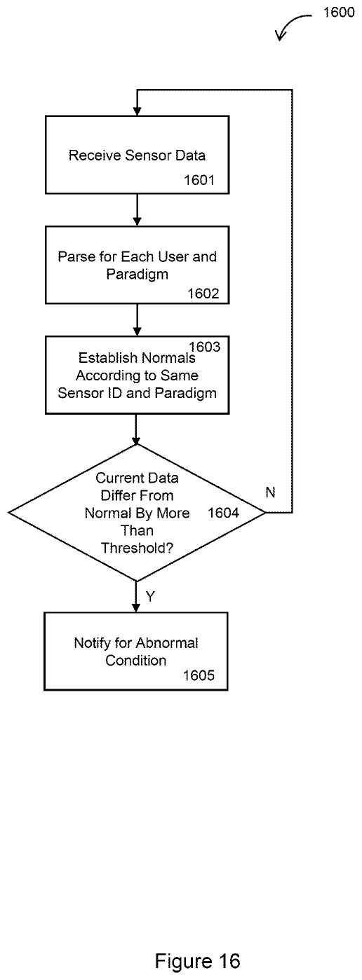

FIG. 16 shows a flowchart of a method 1600 for processing sensor data and detecting abnormal bodily characteristics (e.g., conditions). The method of FIG. 16 may be performed by a centralized controller (e.g., in a network for a facility and/or a cloud-based server) and/or by a dedicated user device. At 1601, new sensor data is received which may comprise a sensor measurement of a bodily characteristic of an individual (e.g., user), a sensor ID, time and date of the measurement, user ID, and/or (optionally) any paradigm values that may characterize extrinsic factors that may have a predictable influence on the bodily characteristic (e.g., user activity schedules). At 1602, the incoming data is parsed into the personal and/or collective database, e.g., so that a profile can be built up for each user in which sensor data for the user is aggregated according to shared paradigms, for example. Bodily characteristic analysis is performed/updated at 1603 where respective normals for a user can be established in connection with a sensor ID and/or any relevant paradigms. Establishing normals corresponding to the sensor ID may enable the analysis to rely on relative changes in sensor measurements. In the event that sensors are available which have a calibrated accuracy that allows reliance on absolute magnitudes of sensor measurements, then the parsing of data and the establishment of normals can be performed without regard to sensor ID. At 1604, an established normal is compared to the new sensor data. If the difference is less than a threshold then there is a return to 1601 in order to continue to receive and process new sensor data. If the difference is greater than the threshold then notification of an abnormal condition is generated at 1605. An appropriate magnitude for the threshold may depend upon the type of bodily characteristic being monitored and/or upon demographic classifications of a particular user (e.g., sex, age, and/or body type).

In some embodiments, tracking of users in a facility provides a basis for identifying potential contactees of users for whom abnormal bodily characteristics are detected. For example, an opt-in building-secure contact tracing system may store times and locations of user movements for correlation. A tracing system may utilize (1) occupancy data for (e.g., anonymized or identifiable) application users, and (2) adequate data infrastructure for retaining the timeframes of their presence. As part of, or separately from, the user tracking and compilation of sensor data for users during their occupancy in a facility (e.g., including at least one building), each user may carry a user device that automatically connects to a network infrastructure upon entering the facility. Based at least in part on interaction with the user device(s), the timeframes of user occupancy can be locally and/or remotely retained (e.g., stored in a tracking database). In some embodiments, tracking of users is based at least in part on communication between the user carried ID device (e.g., smartphone, RFID badge, or laptop) and a wireless and/or wired network infrastructure based at least in part on geo-localization methods such as GPS tracking, ranging, triangulation, WiFi presence, short-range communication such as UWB, and/or other methods. In some embodiments, user tracking is accomplished without a user carried device, e.g., by utilizing remote sensing and identification relying on sensors (e.g., in device ensembles) deployed throughout a facility (e.g. using as facial recognition).

In some embodiments, anonymized or non-anonymized tracking statistics are maintained over a rolling time period (e.g., several days, a week, several weeks, months, or years). For each person with a registered user ID, locations and times in the facility may be stored. When a particular user is identified with an abnormal condition, the locations and times of their movements in the building may be retrieved as search criteria for extracting the user IDs and times for other facility occupants which converge with the affected user (e.g., within a distance and optionally for a time above a time-threshold). A push notification to other facility users (e.g., coworkers or cohabitants) on site in a timeframe of potential exposure, may occur in an anonymized or identified fashion. In some embodiments, local retention of potential exposure timeframes serves to facilitate adherence to medical guidelines (e.g., in the jurisdiction) on proper quarantining and/or sanitation procedures, e.g., enabling a targeted response to affected person(s) and/or to those facility areas most frequented by the affected person(s).

FIG. 17 shows a tracing system 1700 which can operate on a standalone basis or as part of a bodily characteristic monitoring system embedded in a network in a facility. A presence logging database 1701 includes a plurality of presence logs or buffers for each registered user ID, such as a buffer 1702 for a User X and a buffer 1703 for user Y. Each buffer compiles an array of times and locations for which the respective user was tracked during a rolling time period defined by a specified retention time, coupled with measurements of one or more sensor types. Data that has been stored in a buffer for longer than the retention time can be optionally discarded 1740 as old data (e.g., to mitigate personal security concerns for data that is no longer likely to be needed in connection with contact tracing functions). New tracking data is entered into database 1701 via an interface 1704 which may include resources on the network. The network may be a controller network. Optionally, an anonymizer 1705 may be coupled to interface 1704 which converts tracking data based on actual user IDs into anonymous identifiers for storage in database 1701. Anonymizer 1705 may be comprised of a high-level security device that prevents user tracking information as stored in database 1701 from revealing user movements if database 1701 is compromised. Anonymizer 1705 is configured to mask user data when it is stored and to unmask data for the limited purpose of sending notifications when the anonymized data is used to identify potential contactees. At 1710 in FIG. 17, each person entering a facility presents themselves for authorized access. The time and place of entry are forwarded through interface 1704 (and optionally through anonymizer 1705) for storing in a corresponding presence log for that person. During their time at the facility, movements of the person are tracked at 1720. Tracking may be recorded as times spent within predetermined areas (e.g., zones) of the facility, e.g., in order to reduce data storage requirements and/or processing times. A zone may be a fixed region or may be defined dynamically according to the types of usage and/or changing number of occupants in a space. Continuous tracking data (e.g., by sensors located thorough the facility) may be forwarded through interface 1704 (and optionally through anonymizer 1705) for storing in the corresponding presence log. When the person leaves the facility at 1730, the tracking ceases.

In some embodiments, the bodily characteristic tracking sensors may be disposed throughout a facility. There may be a plurality of sensor types required to (e.g., accurately) track one characteristics of an individual throughout the facility. There may be a single sensor type required to (e.g., accurately) track one characteristics of an individual throughout the facility. In some embodiments, the sensor network tracks one bodily characteristic of individual(s) in the facility. In some embodiments, the sensor network tracks a plurality of different bodily characteristics of individual(s) in the facility. The tracking a bodily characteristic of an individual in the facility may comprise recording an identification of an individual, location of the individual in the facility, time and date of the measurement, a type of sensor measurement (e.g., infrared sensor measurements), and optionally another type of sensor measurement (if required to accurately reflect the bodily characteristic of the individual, e.g., visible sensor measurements).

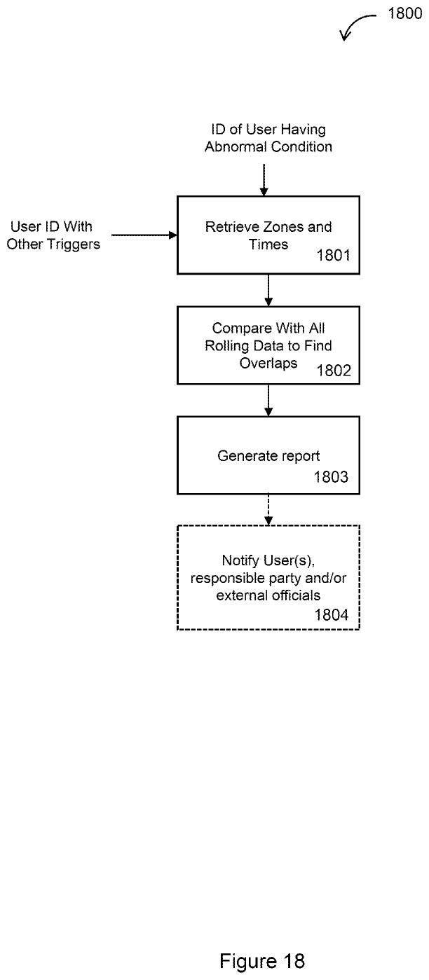

FIG. 18 shows a flowchart of a method for contact tracing based at least in part on a presence logging database. A retrieval of facility zones and times for which a particular user was present in the facility, which is performed at 1801, may be initiated either upon automated detection of a user having an abnormal bodily characteristic (e.g., elevated temperature) or upon occurrence of other triggering events such as a report from a user and/or a health official to a facility and/or network administrator, that the user has been stricken with a bodily abnormality (e.g., an illness). At 1802, the retrieved location (e.g., zones) and times are compared with the rolling data of times and locations stored for other users, e.g., in order to find adjacent location within a distance threshold optionally for a time that exceeds a time threshold and generate a result in report 1803. The result may optionally trigger notification 1804 (i) to the particular user, (ii) to users possibly affected by being proximal to the particular user for an excessive amount of time, (iii) to responsible parties of the facility, of the establishment residing in the facility, and/or of the establishment owning the facility and/or (iv) to jurisdictional officials (e.g., health and/or government officials). At times, generation of the report and the optional notification may occur for select type(s) of abnormal bodily characteristics identified (e.g., to fever, and not to abnormal perspiration).

In some embodiments, the availability of tracking data for facility occupants is utilized to aid in maintenance of physical distances between occupants (e.g., maintain social distancing above a distance threshold). A user may notify the network (e.g., using a software application—app) of his/her destination. For example, a user sitting at an office desk would like to go to conference room X. The app may use the tracking data and suggest an optimal route that is the one least crowded with occupant, from the current location of the occupant (e.g., desk) to the occupant destination in the facility (e.g., conference room X). The app may use the projected analysis (e.g., using machine learning, occupancy schedule for the facility, and/or activity schedule for the facility) to foresee occupancy of the enclosure during the requested movement time of the requesting user. The app may suggest an optimal route that is the one least crowded with occupant during the expected travel time, from the current location of the occupant (e.g., desk) to the occupant destination in the facility (e.g., conference room X). When the user begins travel from their location (e.g., desk) toward their requested destination (e.g., conference room X), the controller may review a tracking database to check for clusters of other occupants along the projected path (e.g., in real time, during the occupant's travel). When such a cluster is found, alternative routes may be evaluated to find and suggest another available route to the destinations, which is less crowded. Such less crowded route option may be automatically shared with the user by the app (e.g., pushed to the user).

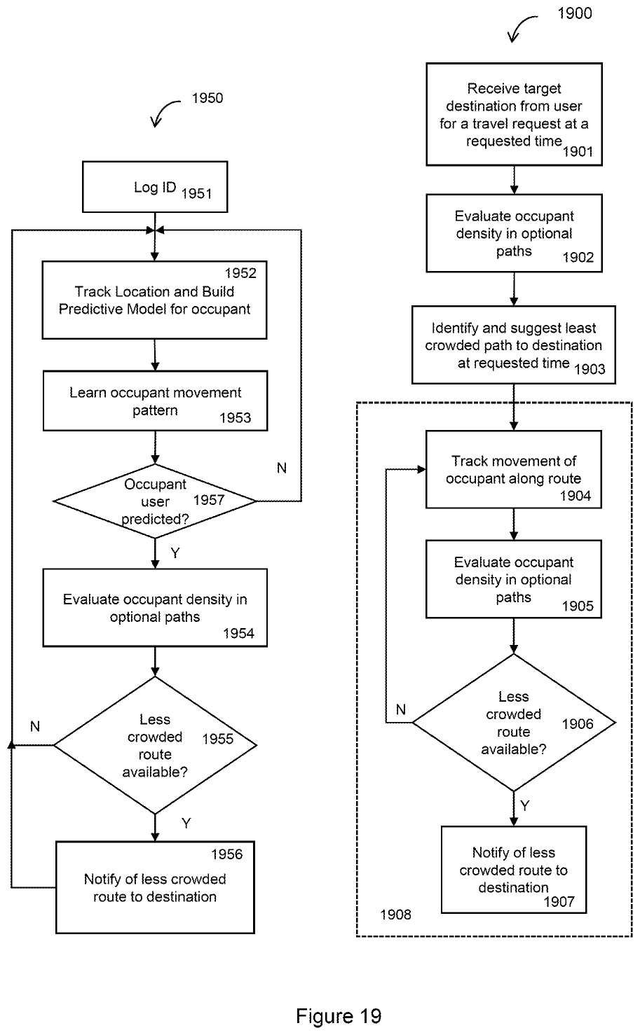

FIG. 19 shows an example of a flow chart 1900 depicting operation for suggesting optimal route to an occupant requesting to reach a destination in a facility in a least crowded route. A target route is input by the occupant in 1901. An identity and/or route of the occupant may be input (e.g., automatically) by the network (e.g., using sensors(s)) of the facility. The occupant may input his/her current location and/or identity manually to the app. Evaluation of occupant density in various routes in the enclosure from the occupant's current location to the occupant's target destination is evaluated in 1902, followed by identification and suggestion of the least crowded route (e.g., path) to the destination in 1903. An optional tracking of the route during travel is suggested in 1908 that includes tracking movement of the occupant (e.g., in real time) along the route in 1904, evaluating occupant density (e.g., in real time) along the route in 1905 and deciding whether a less crowded route is available (e.g., in real time) in 1906. When a less crowded route is available, the occupant is notified of an optional less crowded route.

In some embodiments, the availability of tracking data for facility occupants is utilized to aid in maintenance of physical distances between occupants (e.g., social distancing). As occupants are tracked within a facility, a learning module may compile the typical movements of individuals for various times of day and/or the occurrences of repeating events. Using the learned tendencies for movements of users, the learning module can anticipate where people are going as they move about. When a projected path of movement for a particular user is discerned by the learning module, a controller (e.g., using a processor) can evaluate conditions (e.g., crowded or not) on the expected path. In the event that conditions are crowded in the anticipated path of the user, a (e.g., push) notification may be sent to the user with a recommended route to avoid crowded areas (e.g., to maintain social distancing of the user during his/her taking the path). For example, a user may have a tracking history showing a recurring pattern of moving from their desk to a printer station, from the printer station to a file room, and then from the file room back to their desk. When the user begins travel from their desk toward the printer station, the controller may anticipate such a round trip and then review a tracking database to check for clusters of other occupants along the projected path. When such a cluster is found, alternative routes may be evaluated to find another available route to the destinations which is less or least crowded (e.g., to avoid other people). The alternate route can be automatically shared with the user by the app.

FIG. 19 shows an example of a flowchart 1950 depicting operations for suggesting optimal route to an occupant requesting to reach a destination in a facility in a least crowded route. At 1951, a user ID of an occupant present in the facility is logged. This can be done by identification of the occupant upon entry into the facility, or by any other logging of the occupant (e.g., manual logging by the occupant). While the user is present in the facility, location of the user is tracked at 1952. As data points accumulate for a user over time, a learning (and predictive) module analyzes the movements of the user as a function of time and location, as the data is built up (e.g., serving as a learning set for the learning module), to learn 1953 movement patterns (e.g., as a function of time) of the occupant in the enclosure. A check is made at 1957 to determine whether a learning module predicts a likelihood of a certain movement based at least in part on tracking of the user (e.g., based on previous movements routes, movement initiation location, movement destination, and/or movement time). If no movement is predicted, then further monitoring and refinement of the predictive model are performed at 1952. If a certain movement is predicted, then the predicted route is evaluated for occupant density (e.g., for potential interaction with building occupants and/or other potential risks) at 1954. At 1955, the crowdedness of occupants in various routes to the predicted destination are determined and compared. The occupant is notified of the least crowded route. If there is no better route available, then further monitoring and refinement of the predictive model and/or crowdedness of the route are performed at 1955. If a less crowded route is found then a at the occupant is notified at 1956 takeoff an optional better route. Then there is a return for further monitoring and refinement of the predictive model at 1952. The monitoring can continue whether the occupant takes the route or not. The monitoring can continue in real time during traveling of the occupant along the route. The crowd estimation may consider real time crowdedness and forecasted crowdedness (e.g., using projected analysis such as using machine learning, occupancy schedule for the facility, and/or activity schedule for the facility).

In some embodiments, environmental characteristics are monitored using any of the described sensor modalities to find abnormal characteristics of people and/or surfaces in a facility. For example, humidity changes may be monitored as an indication of excessive perspiration of a sick person. Similarity, gases or chemical concentrations can be monitored as indication an of various kinds of illness. In some embodiments, the sensors or sensor ensembles deployed in a facility are used to sense and/or identify the temperatures of designated surfaces that are targets for regular disinfection (e.g., furniture and/or fixture surfaces such as countertops, doors, table-tops, handles, windows, frames, etc.). Such surfaces may be chosen as a result of being significant reservoirs for infectious agents (e.g., pathogens) to collect and potentially be passed on to other occupants, e.g., if not disinfected. The surfaces can be targeted for regular cleaning and monitoring. Monitoring of the surface can be initiated manually or by otherwise detecting a cleaning activity. After cleaning (e.g., using typical disinfectants and/or other liquid) evaporation of the cleaning liquids (e.g. solvents) from the surface may cool the surface. A cleaning event may be detected by measuring surface temperature at a plurality of sample times and comparing a plurality of consecutive samples (e.g., two or more) to detect a temperature drop (e.g., above a threshold and/or temperature drop rate), for example, as the temperature of the surface gets reduced due to evaporation. Once a cleaning event has been identified, an elapsed time since the last cleaning of the surface can be detected. In some embodiments, a surface temperature may be intermittently or (e.g., substantially) continuously measured (e.g., at a predetermined sample rate) to determine how much time elapsed since the last cleaning, and optionally whether the surface requires a second cleaning (e.g., as too much time elapsed from the last cleaning event).

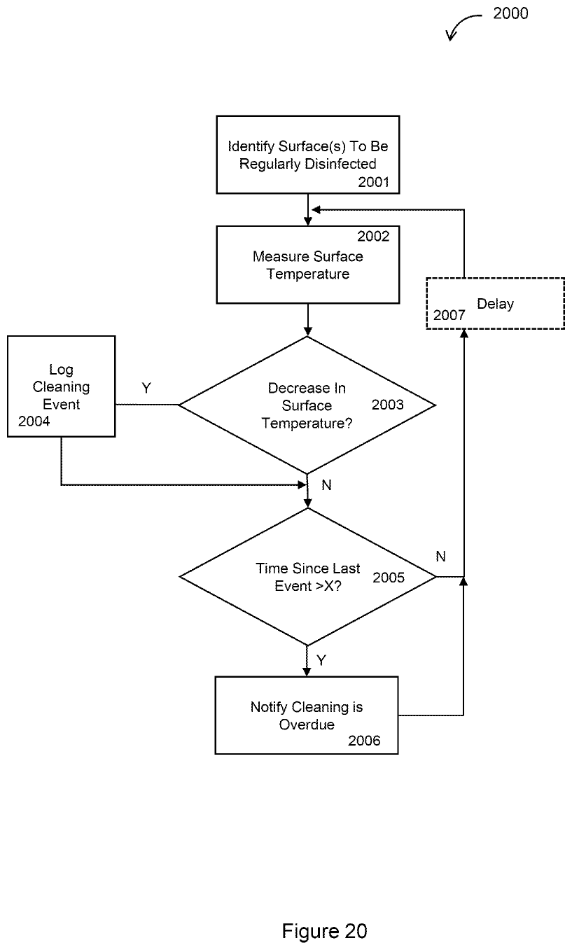

FIG. 20 shows a flowchart for one example of a method for monitoring cleaning of a surface. At least one surface to be cleaned (e.g., and disinfected) is identified at 2001. For example, the surfaces may be designated by a facility manager. At 2002, sensors (e.g., remote temperature sensors, IR thermal cameras, and/or air temperature sensors) are utilized to measure temperature at or near the surface(s) (e.g., as compared to an ambient (e.g., room) temperature). A check is performed at 2003 to determine whether there has been a predetermined decrease in a measured temperature of a particular surface (e.g., which is not accompanied by a matching decrease in the ambient temperature). The purpose of co-monitoring the ambient temperature may be to exclude the possibility that a surface temperature has dropped in response to a change in ambient temperature. If the surface temperature drops by a predetermined amount more than any concurrent drop in ambient temperature, then it is determined that cleaning has occurred, and the cleaning event is logged at 2004. At 2005, an elapsed time since the last cleaning event is compared to a time threshold (e.g., a threshold X, where X is a specified time period according to a requested cleaning schedule). If the elapsed time exceeds the threshold then a notification is sent at 2006 to initiate cleaning. For example, to inform a designated person (e.g., building manager) that cleaning of the surface is overdue. For example, to initiate an automatic cleaning agent (e.g., automatic wiper). After 2005 or 2006, a time delay 2007 may be optionally inserted before returning to 2002, e.g., for re-measuring the surface temperature (and optionally also the ambient temperature).

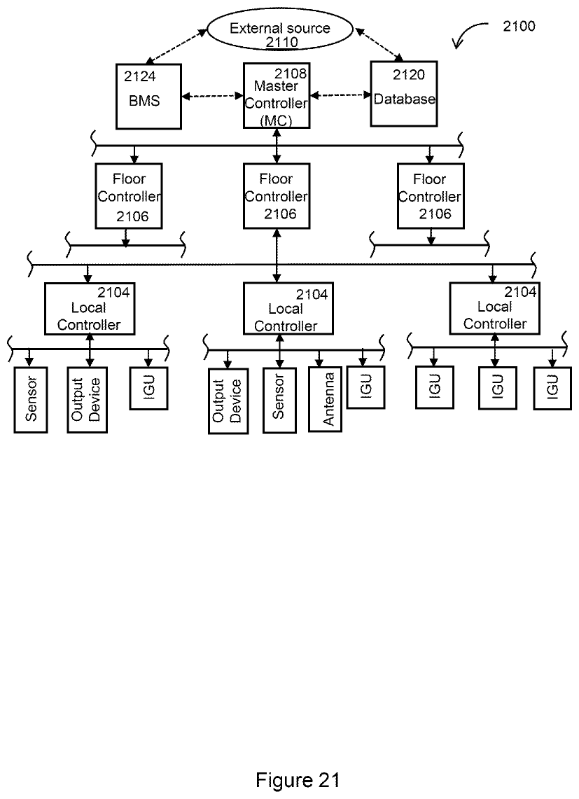

In some embodiments, the sensor(s) are operatively coupled to at least one controller and/or processor. Sensor readings may be obtained by one or more processors and/or controllers. A controller may comprise a processing unit (e.g., CPU or GPU). A controller may receive an input (e.g., from at least one sensor). The controller may comprise circuitry, electrical wiring, optical wiring, socket, and/or outlet. A controller may deliver an output. A controller may comprise multiple (e.g., sub-) controllers. The controller may be a part of a control system. A control system may comprise a master controller, floor (e.g., comprising network controller) controller, a local controller. The local controller may be a window controller (e.g., controlling an optically switchable window), enclosure controller, or component controller. For example, a controller may be a part of a hierarchal control system (e.g., comprising a main controller that directs one or more controllers, e.g., floor controllers, local controllers (e.g., window controllers), enclosure controllers, and/or component controllers). A physical location of the controller type in the hierarchal control system may be changing. For example: At a first time: a first processor may assume a role of a main controller, a second processor may assume a role of a floor controller, and a third processor may assume the role of a local controller. At a second time: the second processor may assume a role of a main controller, the first processor may assume a role of a floor controller, and the third processor may remain with the role of a local controller. At a third time: the third processor may assume a role of a main controller, the second processor may assume a role of a floor controller, and the first processor may assume the role of a local controller. A controller may control one or more devices (e.g., be directly coupled to the devices). A controller may be disposed proximal to the one or more devices it is controlling. For example, a controller may control an optically switchable device (e.g., IGU), an antenna, a sensor, and/or an output device (e.g., a light source, sounds source, smell source, gas source, HVAC outlet, or heater). In one embodiment, a floor controller may direct one or more window controllers, one or more enclosure controllers, one or more component controllers, or any combination thereof. The floor controller may comprise a floor controller. For example, the floor (e.g., comprising network) controller may control a plurality of local (e.g., comprising window) controllers. A plurality of local controllers may be disposed in a portion of a facility (e.g., in a portion of a building). The portion of the facility may be a floor of a facility. For example, a floor controller may be assigned to a floor. In some embodiments, a floor may comprise a plurality of floor controllers, e.g., depending on the floor size and/or the number of local controllers coupled to the floor controller. For example, a floor controller may be assigned to a portion of a floor. For example, a floor controller may be assigned to a portion of the local controllers disposed in the facility. For example, a floor controller may be assigned to a portion of the floors of a facility. A master controller may be coupled to one or more floor controllers. The floor controller may be disposed in the facility. The master controller may be disposed in the facility, or external to the facility. The master controller may be disposed in the cloud. A controller may be a part of, or be operatively coupled to, a building management system. A controller may receive one or more inputs. A controller may generate one or more outputs. The controller may be a single input single output controller (SISO) or a multiple input multiple output controller (MIMO). A controller may interpret an input signal received. A controller may acquire data from the one or more components (e.g., sensors). Acquire may comprise receive or extract. The data may comprise measurement, estimation, determination, generation, or any combination thereof. A controller may comprise feedback control. A controller may comprise feed-forward control. Control may comprise on-off control, proportional control, proportional-integral (PI) control, or proportional-integral-derivative (PID) control. Control may comprise open loop control, or closed loop control. A controller may comprise closed loop control. A controller may comprise open loop control. A controller may comprise a user interface. A user interface may comprise (or operatively coupled to) a keyboard, keypad, mouse, touch screen, microphone, speech recognition package, camera, imaging system, or any combination thereof. Outputs may include a display (e.g., screen), speaker, or printer. FIG. 21 shows an example of a control system architecture 2100 comprising a master controller 2108 that controls floor controllers 2106, that in turn control local controllers 2104. In some embodiments, a local controller controls one or more IGUs, one or more sensors, one or more output devices (e.g., one or more emitters), or any combination thereof. FIG. 21 shows an example of a configuration in which the master controller is operatively coupled (e.g., wirelessly and/or wired) to a building management system (BMS) 2124 and to a database 2120. Arrows in FIG. 21 represents communication pathways. A controller may be operatively coupled (e.g., directly/indirectly and/or wired and/wirelessly) to an external source 2110. The external source may comprise a network. The external source may comprise one or more sensor or output device. The external source may comprise a cloud-based application and/or database. The communication may be wired and/or wireless. The external source may be disposed external to the facility. For example, the external source may comprise one or more sensors and/or antennas disposed, e.g., on a wall or on a ceiling of the facility. The communication may be monodirectional or bidirectional. In the example shown in FIG. 21, the communication all communication arrows are meant to be bidirectional.

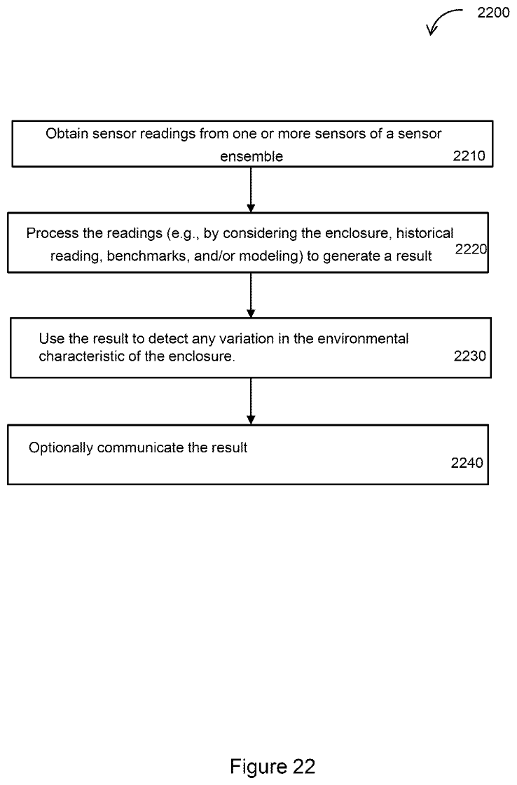

FIG. 22 shows a flowchart for a method 2200 for detecting a perturbation in an environmental characteristic of the enclosure. The method of FIG. 22 may be performed by an individual sensor of a sensor ensemble. The method of FIG. 22 may be performed by a first sensor coupled to (e.g., in communication with) a second sensor. The method of FIG. 22 may be directed by a controller coupled to (e.g., in communication with) the first and/or second sensors. The method of FIG. 22 begins at 2210, in which sensor readings are obtained from one or more sensors of a sensor ensemble. At 2220, readings are processed (e.g., by considering the enclosure, historical reading, benchmarks, and/or modeling) to generate a result. At 2230, the result is utilized to detect an environmental change (e.g., at a particular time and/or location), and/or to predict future readings of the one or more sensors. At 2240 the result may be optionally communicated, e.g., to an interested party.

In particular embodiments, sensor readings from a particular sensor may be correlated with sensor readings from a sensor of the same type or of a different type. Receipt of a sensor reading may give rise to a sensor accessing correlation data from other sensors disposed within the same enclosure. Based, at least in part, on the access correlation data, the reliability of a sensor may be determined or estimated. Responsive to determination or estimation of sensor reliability, a sensor output reading may be adjusted (e.g., increased/decreased). A reliability value may be assigned to a sensor based on adjusted sensor readings.

A sensor reading may be any type of reading, such as detection of movement of individuals within an enclosure, temperature, humidity, or any other property detected by the sensor. Sensor readings may be correlated with correlation data. The correlation data may be accessed from other sensors disposed in the enclosure. Correlation data may relate to output readings from a sensor of the same type or a sensor of a different type operating within the enclosure. In an example, a noise sensor may access data from a movement sensor to determine if one or more individuals have entered an enclosure. One or more individuals moving within an enclosure may emit a level of noise. In an example, output signals from a noise sensor may be corroborated by a second noise sensor and/or by a movement detector. Based at least in part on the accessed correlation data, ran analysis (e.g., evaluation) of the environmental characteristic at one or more position of the environment may be made. The one or more positions may correlate to a position of an individual in the environment (e.g., to detect any abnormal bodily characteristic of the individual(s). The environmental characteristic(s) perturbed by the individual(s) in the environment may be detected for any abnormal bodily characteristic. Once the environmental characteristic(s) detected are analyzed for any abnormal bodily characteristic, they may be reported (e.g., as disclosed herein).

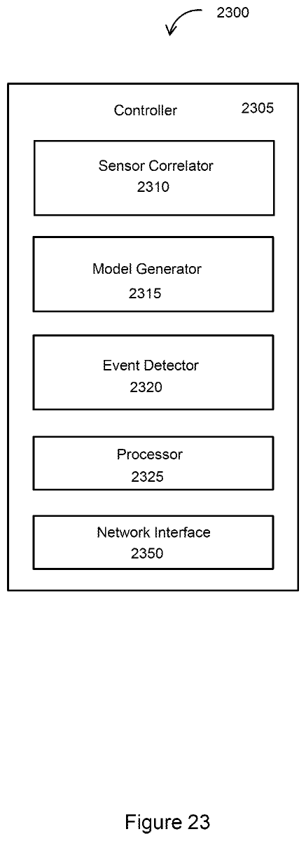

FIG. 23 shows an example of a controller 2305 for controlling one or more sensors. Controller 2305 comprises sensor correlator 2310, model generator 2315, event detector 2320, processor and memory 2325, and the network interface 2350. Sensor correlator 2310 operates to detect correlations between or among various sensor types. For example, an infrared radiation sensor measuring an increase in infrared energy may be positively correlated with an increase in measure temperature. A sensor correlator may establish correlation coefficients, such as coefficients for negatively-correlated sensor readings (e.g., correlation coefficients between −1 and 0). For example, the sensor correlator may establish coefficients for positively-correlated sensor readings (e.g., correlation coefficients between 0 and +1).

In some embodiments, the sensor data may be time dependent. In some embodiments, the sensor data may be space dependent. The model may utilize time and/or space dependency of the sensed parameter. A model generator may permit fitting of sensor readings as a function of one or more dimensions of an enclosure. In an example, a model provides sensor profile curves for carbon dioxide may utilize various gaseous diffusion models, which may allow prediction of a level of carbon dioxide at points in between sensor locations. Processor and memory may facilitate processing of models.

In some embodiments, the sensor and/or sensor ensemble may act as an event detector. The event detector may operate to direct activity of sensors in an enclosure. In an example, in response to event detector determining that very few individuals remain in an enclosure, event detector may direct carbon dioxide sensors to reduce a sampling rate. Reduction of a sampling rate may extend the life of a sensor (e.g., a carbon dioxide sensor). In another example, in response to event detector determining that a large number of individuals are present in a room, event detector may increase the sampling rate of a carbon dioxide sensor. In an example, in response to event detector receiving a signal from a glass breakage sensor, event detector may activate one or more movement detectors of an enclosure, one or more radar units of a detector. A network interface (e.g., 2350) may be configured or designed to communicate with one or more sensors via wireless communications links, wired communications links, or any combination thereof.

The controller may monitor and/or direct (e.g., physical) alteration of the operating conditions of the apparatuses, software, and/or methods described herein. Control may comprise regulate, manipulate, restrict, direct, monitor, adjust, modulate, vary, after, restrain, check, guide, or manage. Controlled (e.g., by a controller) may include attenuated, modulated, varied, managed, curbed, disciplined, regulated, restrained, supervised, manipulated, and/or guided. The control may comprise controlling a control variable (e.g. temperature, power, voltage, and/or profile). The control can comprise real time or off-line control. A calculation utilized by the controller can be done in real time, and/or offline. The controller may be a manual or a non-manual controller. The controller may be an automatic controller. The controller may operate upon request. The controller may be a programmable controller. The controller may be programed. The controller may comprise a processing unit (e.g., CPU or GPU). The controller may receive an input (e.g., from at least one sensor). The controller may deliver an output. The controller may comprise multiple (e.g., sub-) controllers. The controller may be a part of a control system. The control system may comprise a master controller, floor controller, local controller (e.g., enclosure controller, or window controller). The controller may receive one or more inputs. The controller may generate one or more outputs. The controller may be a single input single output controller (SISO) or a multiple input multiple output controller (MIMO). The controller may interpret the input signal received. The controller may acquire data from the one or more sensors. Acquire may comprise receive or extract. The data may comprise measurement, estimation, determination, generation, or any combination thereof. The controller may comprise feedback control. The controller may comprise feed-forward control. The control may comprise on-off control, proportional control, proportional-integral (PI) control, or proportional-integral-derivative (PID) control. The control may comprise open loop control, or closed loop control. The controller may comprise closed loop control. The controller may comprise open loop control. The controller may comprise a user interface. The user interface may comprise (or operatively coupled to) a keyboard, keypad, mouse, touch screen, microphone, speech recognition package, camera, imaging system, or any combination thereof. The outputs may include a display (e.g., screen), speaker, or printer.

The methods, systems and/or the apparatus described herein may comprise a control system. The control system can be in communication with any of the apparatuses (e.g., sensors) described herein. The sensors may be of the same type or of different types, e.g., as described herein. For example, the control system may be in communication with the first sensor and/or with the second sensor. The control system may control the one or more sensors. The control system may control one or more components of a building management system (e.g., lightening, security, and/or air conditioning system). The controller may regulate at least one (e.g., environmental) characteristic of the enclosure. The control system may regulate the enclosure environment using any component of the building management system. For example, the control system may regulate the energy supplied by a heating element and/or by a cooling element. For example, the control system may regulate velocity of an air flowing through a vent to and/or from the enclosure. The control system may comprise a processor. The processor may be a processing unit. The controller may comprise a processing unit. The processing unit may be central. The processing unit may comprise a central processing unit (abbreviated herein as “CPU”). The processing unit may be a graphic processing unit (abbreviated herein as “GPU”). The controller(s) or control mechanisms (e.g., comprising a computer system) may be programmed to implement one or more methods of the disclosure. The processor may be programmed to implement methods of the disclosure. The controller may control at least one component of the forming systems and/or apparatuses disclosed herein.

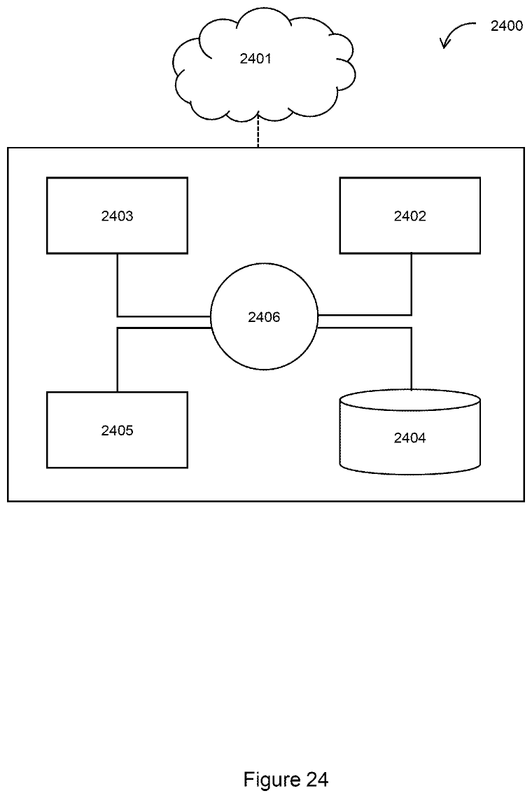

FIG. 24 shows a schematic example of a computer system 2400 that is programmed or otherwise configured to one or more operations of any of the methods provided herein. The computer system can control (e.g., direct, monitor, and/or regulate) various features of the methods, apparatuses and systems of the present disclosure, such as, for example, control heating, cooling, lightening, and/or venting of an enclosure, or any combination thereof. The computer system can be part of, or be in communication with, any sensor or sensor ensemble disclosed herein. The computer may be coupled to one or more mechanisms disclosed herein, and/or any parts thereof. For example, the computer may be coupled to one or more sensors, valves, switches, lights, windows (e.g., IGUs), motors, pumps, optical components, or any combination thereof. The computer system may comprise any of the at least one processor and/or circuit boards disclosed herein, e.g., in the context of temperature measurements.

The computer system can include a processing unit (e.g., 2406) (also “processor,” “computer and “computer processor” used herein). The computer system may include memory or memory location (e.g., 2402) (e.g., random-access memory, read-only memory, flash memory), electronic storage unit (e.g., 2404) (e.g., hard disk), communication interface (e.g., 2403) (e.g., network adapter) for communicating with one or more other systems, and peripheral devices (e.g., 2405), such as cache, other memory, data storage and/or electronic display adapters. In the example shown in FIG. 24, the memory 2402, storage unit 2404, interface 2403, and peripheral devices 2405 are in communication with the processing unit 2406 through a communication bus (solid lines), such as a motherboard. The storage unit can be a data storage unit (or data repository) for storing data. The computer system can be operatively coupled to a computer network (network) (e.g., 2401) with the aid of the communication interface. The network can be the Internet, an internet and/or extranet, or an intranet and/or extranet that is in communication with the Internet. In some cases, the network is a telecommunication and/or data network. The network can include one or more computer servers, which can enable distributed computing, such as cloud computing. The network, in some cases with the aid of the computer system, can implement a peer-to-peer network, which may enable devices coupled to the computer system to behave as a client or a server. The computer system may comprise any of the at least one processor and/or circuit boards disclosed herein, e.g., in the context of temperature measurements.

The processing unit can execute a sequence of machine-readable instructions, which can be embodied in a program or software. The instructions may be stored in a memory location, such as the memory 2402. The instructions can be directed to the processing unit, which can subsequently program or otherwise configure the processing unit to implement methods of the present disclosure. Examples of operations performed by the processing unit can include fetch, decode, execute, and write back. The processing unit may interpret and/or execute instructions. The processor may include a microprocessor, a data processor, a central processing unit (CPU), a graphical processing unit (GPU), a system-on-chip (SOC), a co-processor, a network processor, an application specific integrated circuit (ASIC), an application specific instruction-set processor (ASIPs), a controller, a programmable logic device (PLD), a chipset, a field programmable gate array (FPGA), or any combination thereof. The processing unit can be part of a circuit, such as an integrated circuit. One or more other components of the system 1800 can be included in the circuit.

The storage unit can store files, such as drivers, libraries and saved programs. The storage unit can store user data (e.g., user preferences and user programs). In some cases, the computer system can include one or more additional data storage units that are external to the computer system, such as located on a remote server that is in communication with the computer system through an intranet or the Internet.

The computer system can communicate with one or more remote computer systems through a network. For instance, the computer system can communicate with a remote computer system of a user (e.g., operator). Examples of remote computer systems include personal computers (e.g., portable PC), slate or tablet PC's (e.g., Apple® iPad, Samsung® Galaxy Tab), telephones, Smart phones (e.g., Apple® iPhone, Android-enabled device, Blackberry®), or personal digital assistants. A user (e.g., client) can access the computer system via the network.

Methods as described herein can be implemented by way of machine (e.g., computer processor) executable code stored on an electronic storage location of the computer system, such as, for example, on the memory 2402 or electronic storage unit 2404. The machine executable or machine-readable code can be provided in the form of software. During use, the processor 2406 can execute the code. In some cases, the code can be retrieved from the storage unit and stored on the memory for ready access by the processor. In some situations, the electronic storage unit can be precluded, and machine-executable instructions are stored on memory.

The code can be pre-compiled and configured for use with a machine have a processer adapted to execute the code or can be compiled during runtime. The code can be supplied in a programming language that can be selected to enable the code to execute in a pre-compiled or as-compiled fashion.

In some embodiments, the processor comprises a code. The code can be program instructions. The program instructions may cause the at least one processor (e.g., computer) to direct a feed forward and/or feedback control loop. In some embodiments, the program instructions cause the at least one processor to direct a closed loop and/or open loop control scheme. The control may be based at least in part on one or more sensor readings (e.g., sensor data). One controller may direct a plurality of operations. At least two operations may be directed by different controllers. In some embodiments, a different controller may direct at least two of operations (a), (b) and (c). In some embodiments, different controllers may direct at least two of operations (a), (b) and (c). In some embodiments, a non-transitory computer-readable medium cause each a different computer to direct at least two of operations (a), (b) and (c). In some embodiments, different non-transitory computer-readable mediums cause each a different computer to direct at least two of operations (a), (b) and (c). The controller and/or computer readable media may direct any of the apparatuses or components thereof disclosed herein. The controller and/or computer readable media may direct any operations of the methods disclosed herein.

In some embodiments, the at least one sensor is operatively coupled to a control system (e.g., computer control system). The sensor may comprise light sensor, acoustic sensor, vibration sensor, chemical sensor, electrical sensor, magnetic sensor, fluidity sensor, movement sensor, speed sensor, position sensor, pressure sensor, force sensor, density sensor, distance sensor, or proximity sensor. The sensor may include temperature sensor, weight sensor, material (e.g., powder) level sensor, metrology sensor, gas sensor, or humidity sensor. The metrology sensor may comprise measurement sensor (e.g., height, length, width, angle, and/or volume). The metrology sensor may comprise a magnetic, acceleration, orientation, or optical sensor. The sensor may transmit and/or receive sound (e.g., echo), magnetic, electronic, or electromagnetic signal. The electromagnetic signal may comprise a visible, infrared, ultraviolet, ultrasound, radio wave, or microwave signal. The gas sensor may sense any of the gas delineated herein. The distance sensor can be a type of metrology sensor. The distance sensor may comprise an optical sensor, or capacitance sensor. The temperature sensor can comprise Bolometer, Bimetallic strip, calorimeter, Exhaust gas temperature gauge, Flame detection, Gardon gauge, Golay cell, Heat flux sensor, Infrared thermometer, Microbolometer, Microwave radiometer, Net radiometer, Quartz thermometer, Resistance temperature detector, Resistance thermometer, Silicon band gap temperature sensor, Special sensor microwave/imager, Temperature gauge, Thermistor, Thermocouple, Thermometer (e.g., resistance thermometer), or Pyrometer. The temperature sensor may comprise an optical sensor. The temperature sensor may comprise image processing. The temperature sensor may comprise a camera (e.g., IR camera, CCD camera). The pressure sensor may comprise Barograph, Barometer, Boost gauge, Bourdon gauge, Hot filament ionization gauge, Ionization gauge, McLeod gauge, Oscillating U-tube, Permanent Downhole Gauge, Piezometer, Pirani gauge, Pressure sensor, Pressure gauge, Tactile sensor, or Time pressure gauge. The position sensor may comprise Auxanometer, Capacitive displacement sensor, Capacitive sensing, Free fall sensor, Gravimeter, Gyroscopic sensor, Impact sensor, Inclinometer, Integrated circuit piezoelectric sensor, Laser rangefinder, Laser surface velocimeter, LIDAR, Linear encoder, Linear variable differential transformer (LVDT), Liquid capacitive inclinometers, Odometer, Photoelectric sensor, Piezoelectric accelerometer, Rate sensor, Rotary encoder, Rotary variable differential transformer, Selsyn, Shock detector, Shock data logger, Tilt sensor, Tachometer, Ultrasonic thickness gauge, Variable reluctance sensor, or Velocity receiver. The optical sensor may comprise a Charge-coupled device, Colorimeter, Contact image sensor, Electro-optical sensor, Infra-red sensor, Kinetic inductance detector, light emitting diode (e.g., light sensor), Light-addressable potentiometric sensor, Nichols radiometer, Fiber optic sensor, Optical position sensor, Photo detector, Photodiode, Photomultiplier tubes, Phototransistor, Photoelectric sensor, Photoionization detector, Photomultiplier, Photo resistor, Photo switch, Phototube, Scintillometer, Shack-Hartmann, Single-photon avalanche diode, Superconducting nanowire single-photon detector, Transition edge sensor, Visible light photon counter, or Wave front sensor. The one or more sensors may be connected to a control system (e.g., to a processor, to a computer). The sensor may comprise complementary metal oxide semiconductor (CMOS).

In various embodiments, a network infrastructure supports a control system for one or more windows such as electrochromic (e.g., tintable) windows. The control system may comprise one or more controllers operatively coupled (e.g., directly or indirectly) to one or more windows. While the disclosed embodiments describe electrochromic windows (also referred to herein as “optically switchable windows,” “tintable windows”, or “smart windows”), the concepts disclosed herein may apply to other types of switchable optical devices including, for example, a liquid crystal device, or a suspended particle device. For example, a liquid crystal device and/or a suspended particle device may be implemented instead of, or in addition to, an electrochromic device. Tintable windows may operate using liquid crystal devices, suspended particle devices, microelectromechanical systems (MEMS) devices (such as microshutters), or any technology known now, or later developed, that is configured to control light transmission through a window. Windows (e.g., with MEMS devices for tinting) are described in U.S. patent application Ser. No. 14/443,353, filed May 15, 2015, titled “MULTI-PANE WINDOWS INCLUDING ELECTROCHROMIC DEVICES AND ELECTROMECHANICAL SYSTEMS DEVICES,” that is incorporated herein by reference in its entirety. In some cases, one or more tintable windows can be located within the interior of a building, e.g., between a conference room and a hallway. In some cases, one or more tintable windows can be used in automobiles, trains, aircraft, and other vehicles, e.g., in lieu of a passive and/or non-tinting window.

In some embodiments, bodily characteristics of an individual may be performed at certain locations of the body. For example, temperature may be measured on the forehead. At least one sensor may be disposed in a structure (e.g., fixture) to measure the bodily characteristic. The sensor may focus on the bodily location to sense and/or identify the bodily characteristic. For example, the sensor may focus on the forehead to measure the temperature. The sensor may be directed to focus on a certain lateral (e.g., horizontal) distance from the sensor. The distance may correspond to the distance of the bodily location. The distance may correspond to a designated location of the individual from the sensor. The sensor may be directed to focus on a certain vertical distance from the sensor. The vertical distance may correspond to the vertical distance of the bodily location. The distance may correspond to an average location of the bodily location in the population, e.g., depending on age group and/or gender.

In some embodiments, the sensor(s) are operatively coupled to a network. At least one controller operatively coupled to network (e.g., one or more processors operatively coupled to the network) may direct the sensor(s) to focus on the bodily location based at least in part on image recognition of facial landmarks. Facial landmark recognition may utilized one or more (e.g., other) sensors such as sensors for visible and/or IR sensors. The sensors may be configured to identify the individual based at least in part on (i) the individual's temperature as compared to the surrounding and/or background, (ii) facial landmark features of the individual. The lateral (e.g., horizontal) distance of the individual from the sensor(s) may be estimated using distance between facial features and/or size of facial features, and their comparison to an average population. For example, distance between eyes. For example, size of a pupil. The lateral distance may be estimated using a combination of IR sensor and visible sensor (e.g., camera) data, that identify an individual based at least in part on the heat signature in an environment having a different (e.g., lower) heat signature. The sensor used at least in part to identify the bodily location (e.g., forehead) of the individual can be the same or different from the sensor used to measure the bodily characteristic (e.g., temperature) of the individual.

In some embodiments, the bodily characteristic(s) (e.g., temperature) is measured at a lateral distance from the sensor (e.g., at a focal distance from the sensor). The person can be disposed at about the lateral distance of the measurements. The lateral distance may be at least about 0.1 meter (m), 0.3 m, 0.6 m, 0.9 m, or 1 m. The lateral distance of the measurements from the sensor can be between any of the aforementioned distances (e.g., from about 0.1 m to about 1 m). The sensor may have a dwell time during which the bodily characteristic may be measured. The dwell time may be at most about 0.25 seconds (s), 0.5 s, 1 s, 1.5 s, 2 s, 3 s, 4 s, or 5 s. The dwell time may be of any value between the aforementioned values (e.g., from about 0.25 s to about 5 s). The thermal characteristic (e.g., temperature) can be measured with an accuracy of at least about +/−0.7° C., 0.5° C., 0.25° C., or a higher accuracy. The sensor (e.g., as part of a camera) utilized for the measurement may have a horizontal and vertical fields of view. The vertical field of view may be of at least about 30 degrees (°), 40°, 55°, 60°, 70°, 80°, 90°, 100°, 110°, 120°, or 150°. The horizontal field of view may be of at least about 30°, 40°, 55°, 60°, 65°, 70°, 75°, 80°, 90°, or 100°. The vertical field of view may be larger than the vertical field of view. Larger may be by about 1.1 times (*), 1.2*, 1.4*, 1.5*, 1.7*, 1.9*, or 2.0*.

At times, a plurality of sensors may be utilized to view the bodily characteristic. The density of measurements over time of the plurality of sensors may be (e.g., substantially) similar. For example, a thermal IR camera and a depth camera may be utilized to ascertain a user's bodily location (e.g., forehead) and/or measure the bodily characteristics (e.g., temperature). The sensor(s) may be disposed at a location that facilitates focusing on the bodily location (e.g., withing the horizontal and/or vertical field of view of the user). The sensor(s) may be operatively coupled to actuator(s) that facilitate its translation (e.g., horizontally and/or vertically) to adjust capturing the bodily location of the user within a field of view(s) of the sensor. The sensor(s) may be stationary. The translation may be manual or automatic (e.g., using at least one controller).

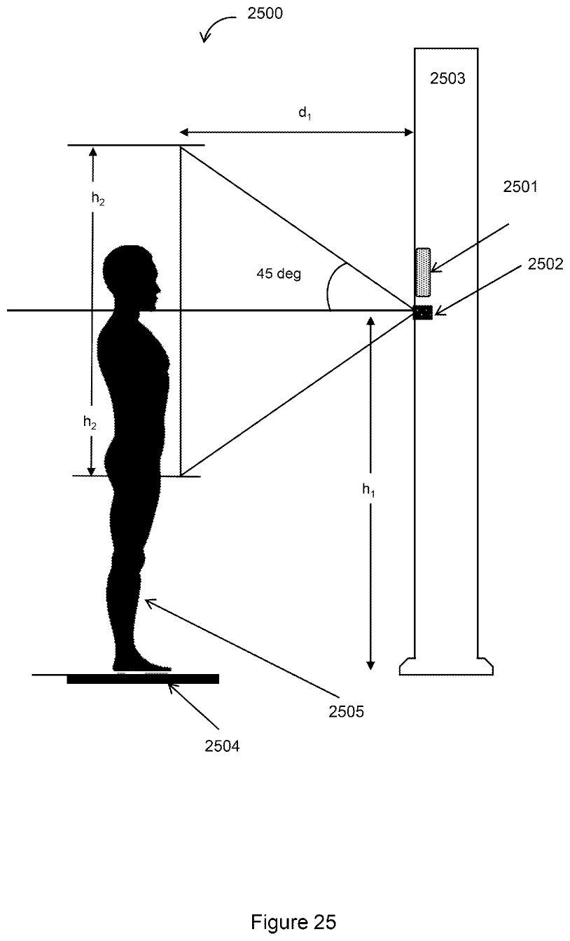

FIG. 25 shows an example of a user 2505 that is subject to measurements of bodily characteristic of temperature. An IR sensors 2502 is disposed in a structure 2503 or attached thereto. A depth camera 2501 is similarly disposed to the structure 2503 or attached thereto. For example, at least one of the sensors can be disposed in a framing (e.g., in a cavity of the framing). For example, at least one of the sensors can be attached to an exterior of the framing. The user 2505 is situated at a designated location 2504 (e.g., 362 of FIG. 3). The IR sensor 2502 is deposed at an average chin height of a user hi, and at a designated distance di from the designated location 2504. The IR sensor 2502 has a vertical field of view of 90 degrees.

In some embodiments, evaluating bodily characteristic(s) of an individual comprises a plurality of operations. For example, the evaluation can comprise identification of facial landmarks of the user and/or distance of the user from the sensor(s) (e.g., actual and/or expected). A control system may direct the sensor(s) to focus of a bodily location (e.g., based at least in part on the facial landmark recognition and/or distance of the user from the sensor(s)). Once the sensor(s) is configured to focus on the bodily location, the sensor(s) acquire measurement(s) from the bodily location. The measurements may be processed (e.g., adjusted according to various adjustment methodologies) to generate a result of the measured bodily characteristic(s). The result may be compared with a threshold (e.g., value), and a report may be generated. The report may be sent to the user, to authorities, to management, or any combination thereof. The report may contain the adjusted bodily characteristic(s) (e.g., to reflect real value of the bodily characteristic(s)), variance from normal value, and any remedial and/or promotional measure actions (e.g., suggestions and/or directions). The report may be utilized as disclosed herein. The non-manipulated temperature measurements, the processed results, the comparison with the threshold, and/or the report may be saved in one or more databases. The databases may be operatively coupled to the network. The data of the database may be utilized to increase the accuracy of the reported. In some embodiments, the measurements of the bodily characteristic(s) are performed in a contactless manner.

In some embodiments, the raw data of the bodily characteristics of a user measured by the sensor does not accurately reflect the actual bodily characteristics of the user. The raw data require adjustment. The adjustment may be performed automatically (e.g., by a processor). The manner of adjustment may be suggested by an artificial intelligence (AI) computational scheme. The AI may comprise a learning module. The learning module may utilize historic measurements of individuals and/or objects having the subject characteristic (e.g., temperature), as compared to a ground truth (e.g., a local thermometer providing an accurate reading). The learning module may utilize synthetic measurements as part of its learning set. The learning module may utilize simulation as part of its learning set. For example, an IR sensor measuring temperature of an individual at a distance at time t, can be compared to a thermometer measuring the individual's temperature at the time t. The adjustment may consider modeling (e.g., physics modeling) that emulate the subject characteristic measured by the sensors. For example, when the characteristic is temperature, black body radiation at a position of an average individual forehead may be simulated and fed to the learning module as a synthetic measurement as part of its learning set. The learning module (including machine learning) may utilize regression and/or classification algorithms. An output of the machine learning module may be a (e.g., lateral) distance of the subject from the sensor(s) and/or the bodily characteristic (e.g., temperature) measured.

In some embodiments, the bodily characteristic is measured using a sensor array (e.g., a camera having a sensor array such as an IR or a visible light camera). The sensor array may comprise at least about 25 pixels, 32 pixels, 800 pixels, 1080 pixels, 1280 pixels, or 1920 pixels in its FLS. (e.g., the array may be 25×25, 25×32, or 32×32 sensor array). The sensor array may comprise at least about 1 megapixels (Mpxl), 4 Mpxl, 8 Mpxl, 10 Mpxl, or 12 Mpxl at its FLS. The sensor may measure a wide operational range, e.g., wide span of the bodily characteristic. For example, the temperature sensor may be configured to measure a temperature spanning from about −40° C. to about 85° C. operational temperature range, or from about −40° C. to about 300° C. operational temperature range. The sensor may be a high accuracy sensor. For example, the temperature sensor may have an accuracy of at least about ±1° C., or ±0.5° C. (or any other temperature accuracy value disclosed herein). The sensor array (e.g., camera having the sensor array) may have an adjustable focus (e.g., automatically adjustable using at least one controller). The camera may have one or more lenses. The sensor array may be sensitive to at least the visible spectrum (e.g., comprise an RGB sensor). The sensor array may be sensitive to at least the infrared spectrum. The sensor may be included in a camera comprising stereo vision. The sensor may be part of a camera. The camera may have a shutter (e.g., a rolling shutter). The sensor may have a small pixel size. The small pixel size may have a FLS of at most about 1.2 micrometers (μm), 1.4 μm, 1.5 μm, 2.0 μm, 2.5 μm, or 3 μm.

In some embodiments, the sensor may be free to move. Movements of the sensor may be controller (e.g., automatically by at least one controller). Movements of the sensor may be effectuated by an actuator operatively coupled to the sensor. The sensor may be configured to have at least 1, 2, 3, 4, 5, or 6 degrees of freedom. The six degrees of freedom may comprise forward, backward, up, down, left, right, pitch, yaw, or roll.

In some embodiments, a depth camera is utilized to filter noise, and/or to differentiate the user from a background. The camera may comprise stereo vision. The camera may comprise a plurality of sensors spaced apart, e.g., configured to enable the stereo vision capability. The camera module may comprise a processor. The depth camera may include a sensor (e.g., as part of a sensor array) sensitive to the visible spectrum (e.g., Red Green Blue (RGB) sensor), and/or a rolling shutter. The depth camera module may integrate data from IR and visible sensors. The depth camera may comprise IR sensor, IR laser, or a visible sensor. For example, the depth camera may comprise a plurality of visible sensors and one IR sensor and/or laser. For example, the depth camera may comprise a plurality of IR sensors and/or lasers and one visible sensor. The depth camera may comprise a laser (e.g., IR laser). The depth camera may be a web-camera. The depth camera may project and/or sense infrared radiation. The depth camera may utilize comparison of captured data (e.g., sensed information) from two sensors spaced (e.g., horizontally and/or vertically) apart from each other.

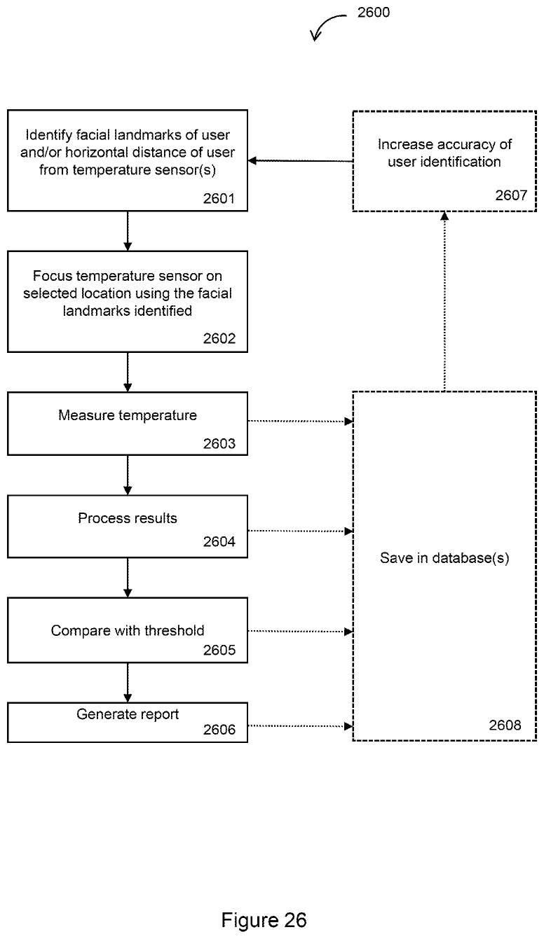

FIG. 26 shows an example of a flowchart depicting (e.g., contactless) evaluation of a temperature of an individual. Identification of facial landmarks of the user and/or distance of the user from the sensor(s) (e.g., actual and/or expected) is performed in operation 2601. Focusing the sensor(s) on a bodily location is performed in operation 2602 (e.g., based at least in part on the facial landmark recognition and/or distance of the user from the sensor(s)). Once the sensor(s) is configured to focus on the bodily location, the sensor(s) acquire measurement(s) in operation 2603, from the bodily location. The measurements are processed in operation 2604 (e.g., adjusted according to various adjustment methodologies) to generate a result of the measured bodily characteristic(s). The result is compared with a threshold (e.g., value) in operation 2605, and a report is generated in operation 2606. The non-manipulated temperature measurements, the processed results, the comparison with the threshold, and/or the report are optionally saved in one or more databases in operation 2608. The databases may be operatively coupled to the network. The data of the database are optionally utilized in operation 2607 to increase the accuracy of the reported. The temperature can be measured, processed, and provided as an output (e.g., to the user) within at most about 0.25 seconds (sec), 0.5 sec, 1 sec, 1.5 sec, 2 sec, 3 sec, or 5 sec.

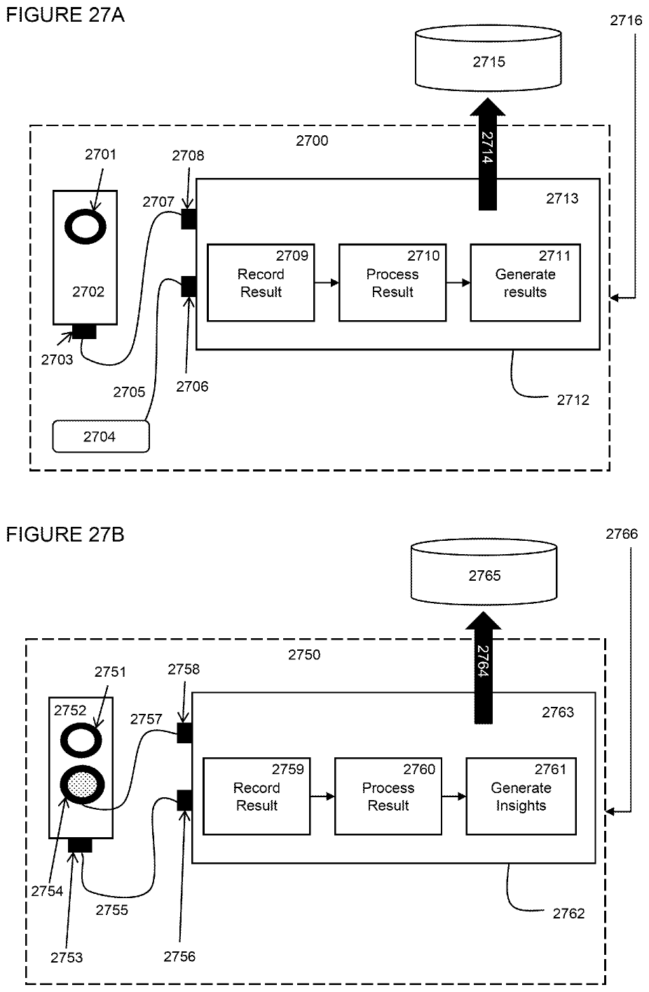

FIGS. 27A and 27B shows various options to perform temperature measurements, e.g., in a configuration similar to the one shown in FIG. 25. FIG. 27A shows an example of two sensors comprising a thermal (IR) camera 2701 and optical camera 2704. The thermal camera is disposed in a housing 2702 separate from that of the optical camera 2704. For example, the thermal camera may be housed in a device ensemble, while the optical camera is not housed in that device ensemble. The thermal camera 2701 may be coupled to at least one processor 2713 via cabling 2707 and connectors 2703 and 2708 (e.g., USB connectors, or any other connector, e.g., as disclosed herein). The optical camera 2704 may be coupled to a processor via cabling 2705 and connector 2706 (e.g., USB connector, or any other connector, e.g., as disclosed herein). The at least one processor may be configured to record the results accumulated by the two cameras in operation 2709, which results are processed in operation 2710, and results (e.g., insights) are generated in operation 2711. The at least one processor 2713 is connected to power source 2712. The at least one processor 2713 is operatively coupled via link 2714 (e.g., wired and/or wireless connection such as WiFi connection) to a storage (e.g., database) 2715. The measurement system 2700 as well as the database 2715 are operatively coupled to the network 2716, e.g., that controls the facility in which the cameras are disposed. The at least one processor 2713 and the database 2715 may or may not be disposed in the facility. FIG. 27B shows an example of two sensors comprising a thermal (IR) camera 2751 and optical camera 2754. The thermal camera and the optical camera are disposed in a housing 2752. For example, the thermal and optical cameras may be housed in a device ensemble. The cameras 2751 and 2754 may be coupled to at least one processor 2763 via cabling. The optical camera may utilize a separate cabling from that of the thermal camera. For example, cabling 2757 may couple the optical camera to the at least one coprocessor 2763 via connector 2758, and the thermal camera 2751 may be coupled via cabling 2755 to the at least one processor 2763 via connectors 2753 and 2756. The connectors may be USB connectors, or any other connector (e.g., as disclosed herein). The at least one processor 2763 may be configured to record the results accumulated by the two cameras in operation 2759, which results are processed in operation 2760, and results (e.g., insights) are generated in operation 2761. The at least one processor 2763 is connected to power source 2762. The at least one processor 2763 is operatively coupled via link 2764 (e.g., wired and/or wireless connection such as WiFi connection) to a storage (e.g., database) 2765. The measurement system 2750 as well as the database 2715 are operatively coupled to the network 2766, e.g., that controls the facility in which the cameras are disposed. The at least one processor 2763 and the database 2765 may or may not be disposed in the facility. The optical camera may be a depth camera. The device ensemble may include processing capabilities. For example, the at least one processor (e.g., 2763 or 2713) may at least partially reside in the device ensemble. For example, the at least one processor (e.g., 2763 or 2713) may reside in the device ensemble. For example, the at least one processor is a plurality of processors, at least one of which resides in the device ensemble. Processing the results may comprise cleaning from noise and/or calibrating the captured sensor measurements. The noise may arise from the background surrounding the user. Saving in the database may comprise saving in a log file. The electrical required for the data processing (e.g., 2712 or 2762) may comprise at most 2V, 4V, 5V, or 10 Volts (V) and at most 1 A, 2 A, or 3 amperes (A). The at least one processor (e.g., 2763 or 2713) may comprise a CPU or a GPU. The at least one processor may comprise a media player. The at least one processor may be included in a circuit board. The circuit board may comprise a Jetson Nano™ Developer Kit by NVIDIA®, (e.g., 2 GB or 4 GB developer kit) or Raspberry-Pi kit (e.g., 1 GB, 2 GB, 4 GB, or 8 GB developer kit). The at least one processor may be operatively coupled to a plurality of ports comprising at least one media port (e.g., a DisplayPort, HDMI, and/or micro-HDMI), USB, or an audio-video jack, e.g., that may be included in the circuit board. The at least one processor may be operatively coupled to a Camera Serial Interface (CSI), or a Display Serial Interface (DSI), e.g., as part of the circuit board. The at least one processor is configured to support communication such as ethernet (e.g., Gigabit Ethernet). The circuitry board may comprise a Wi-Fi functionality, a Bluetooth functionality, or a wireless adapter. The wireless adapter may be configured to comply with a wireless networking standard in the 802.11 set of protocols (e.g., USB 802.11ac). The wireless adapter may be configured to provide a high-throughput wireless local area networks (WLANs), e.g., on at least about a 5 GHz band. The USB port may have a transfer speed of at least about 480 megabits per second (Mbps), 4,800 Mbps, or 10,000 Mbps. The at least one processor may comprise a synchronous (e.g., clocked) processor. The clock speed of the processor may be of at least about 1.2 Gigahertz (GHz), 1.3 GHz, 1.4 GHz, 1.5 GHz, or 1.6 GHz. The at least one processor may comprise a random access memory (RAM). The RAM may comprise a double data rate synchronous dynamic RAM (SDRAM). The RAM may be configured for mobile devices (e.g., laptop, pad, or mobile phone such as cellular phone). The RAM may comprise a Low-Power Double Data Rate (LPDDR) RAM. The RAM may be configured to permit a channel that is at least about 16, 32, or 64 bit wide.

The at least one processor may comprise a single circuit board computer (SBC). The at least one processor may be configured to run a plurality of neural networks in parallel (e.g., for image classification, object detection, segmentation, and/or speech processing). The at least one processor may be powered by at most about 10 watts (W), 8 W, 5 W, or 4 W.

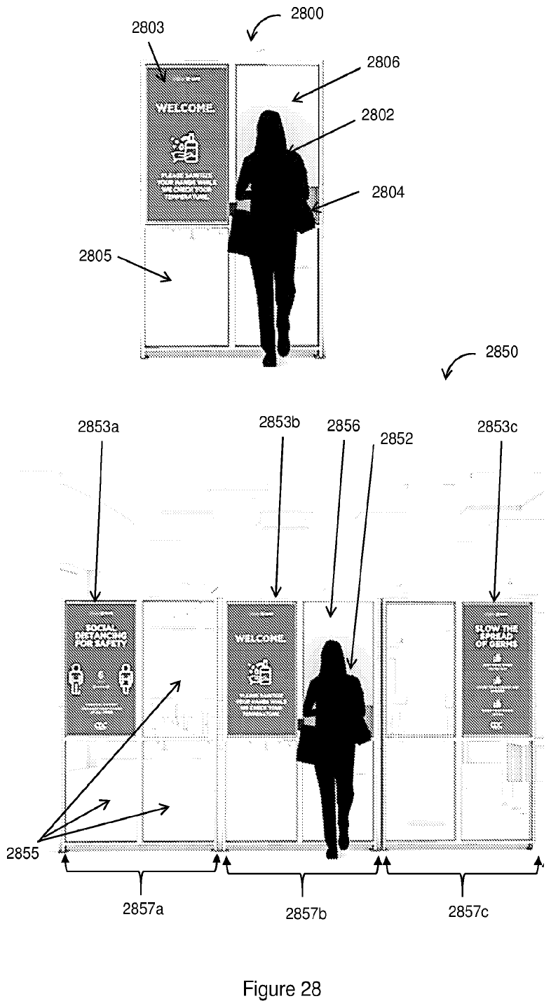

In some embodiments, a framing station is utilized to provide an interactive experience with a user. FIG. 28 shows an example of a framing system 2800 and a user 2802 having an interactive experience with the framing system. The framing system frames an informative board 2803 that can comprise stills or a media display displaying a time varying digital media. The framing station frames transparent boards such as 2805 that can be a window (e.g., glass or polymeric window). The window may or may not be a tintable window. Framing system can have a cavity 2804 into which the user can reach. The cavity may have a maximum depth of the framing system. The framing system may include one or more sensors and/or emitters operatively coupled to the network (e.g., and to the control system). The framing system may be modular. FIG. 28 shows an example of framing system 2850 that is constructed from a plurality of modular units 2857a, 2857b, and 2857c. The modular framing system units comprise transparent boards (e.g., windows) such as 2855; informative boards 2853a, 2853b, and 2853c that can include a poster board, a white board, a magnetic board, a cork board, or a media display. Each of framing systems 2857a, 2857b, and 2857c is divided as a 2×2 matrix framing four sections (e.g., 2853a and 2855). Modular framing system unit 5357b includes an opaque board 2856 that covers a portion of a matrix section, while facilitates a user 2852 to reach into a cavity in the framing system in a similar manner to cavity 2804. Framing system 2857b is similar to framing system 2800. The framing system may be utilized as a kiosk servicing one or more individuals (e.g., simultaneously).

In some embodiments, the framing system includes internal framing portions that are integrated together to a single framing system. The framing system can include cabling and one or more interactive devices. The one or more interactive device may include dispensers, sensors, and/or emitters. Sensors can include optical (e.g., electromagnetic) sensors. The emitters may comprise lighting, projector, or media display. The internal framing portions may be integrated with each other in one or more various joint types. The joint types may comprise linear joints or non-linear (e.g., staggered) joints. The joints may comprise butt, dovetail, mitered, mortise-and-tanon, biscuit, picket, rabbet, scarf joint, V-joint, lap joint, strap joint, or tongue-and-groove joint. The butt joint may comprise a simple butt joint, or double butt lap joint. The lap joint may comprise a double butt lap joint, half lap, plain lap joint, beveled lap joint, double lap joint, or joggle lap joint. The strap joint may comprise a single strap joint, double strap joint, recessed double strap joint, or beveled double strap joint. The tongue and groove joint may comprise a landed scarf tongue and groove joint.

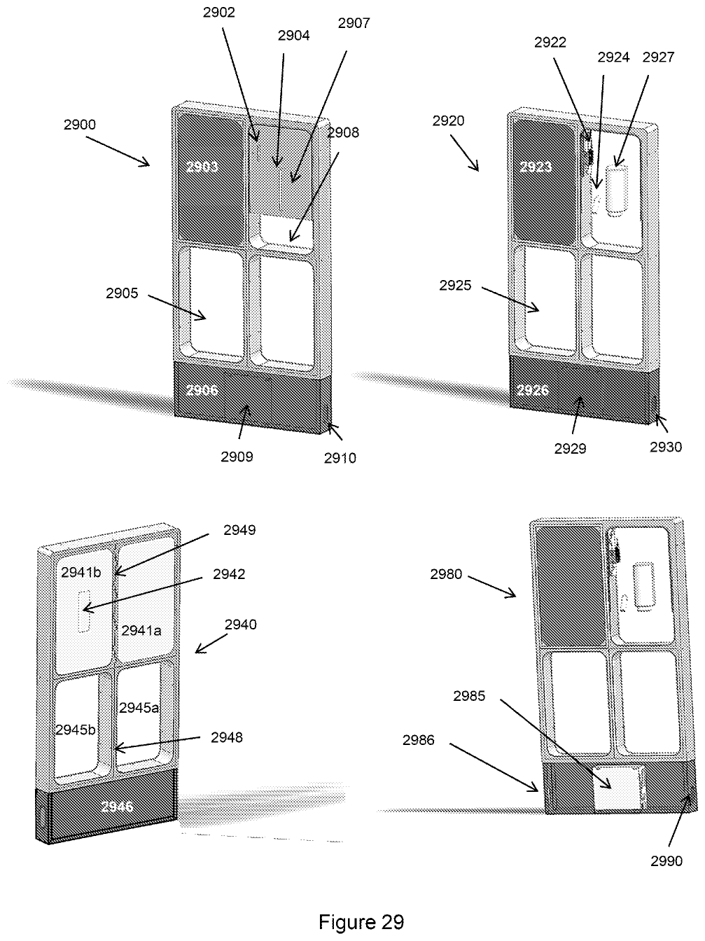

In some embodiments, the framing system (also herein referred to as “framing apparatus”) comprises a casing configured to house one or more processors and/or wiring. The casing may comprise one or more openings. The opening(s) may facilitate operatively coupling (e.g., wired and/or wirelessly connecting) the framing system to the network (e.g., local network of the facility). The opening(s) may facilitate servicing one or more components of the framing system disposed in the casing. For example, the opening may facilitate servicing the wiring and/or processor(s) disposed in the casing. Servicing comprises maintenance, replacement, or introduction of new components. The openings may comprise a lid or door that is reversibly openable and closeable. The lid or door may be fastened to the body of the casing by one or more hingers or screws. The lid or door may comprise a mechanism that facilitates snapping the lid or door (respectively) to the body of the casing. An opening of the casing may be disposed at the front, back, or side of the casing, with the front being a side designed to be confronted by a user interacting with the interactive framing system. For example, framing systems 2900 depicts the front side of the framing system, and framing system 2940 depicts its back side view. At times, the interactive framing system is designed for interaction on both its opposing side with a plurality of users. In that case the lid or door of the casing may be at one side designed for interacting with a user, or at its opposing side designed for interacting with another user (e.g., whether simultaneously or non-simultaneously). An internal space of the framing portions (that form the framing system) may be utilized to house wiring and/or device(s) (e.g., sensors or emitters. E.g., projector 342 of FIG. 3). An internal space of the framing portions (that form the framing system) may be utilized to house wiring, whereas the device(s) (e.g., sensors or emitters) may be attached to an exterior of the framing portion(s) (e.g., as sensors 2922 of FIG. 29).

FIG. 29 shows an example of a framing system 2900 that frames display board 2903 that can be a media display, opaque board 2907 having an opening 2904 through which one may be able to see a level of a disinfectant disposed in a dispenser of the framing system, and openings 2902 for one or more sensors (e.g., cameras or any other electromagnetic sensing device(s)). Framing 2900 is configured to frame transparent boards such as 2905 (e.g., windows). Framing 2900 is configured to house network, communication, and/or control related devices in casing 2906. Framing system 2900 is constructed as a 2×2 matrix that can house various boards such as opaque board 2907, display board 2903, and transparent board 2905. Framing system 2900 includes a service opening 2909 (e.g., to service electronic components such as processor(s), and/or wiring) as part of the casing 2906, and a wiring opening 2910 (e.g., that facilitates operatively coupling (e.g., connecting) the framing system to the network (e.g., local network of the facility).

FIG. 29 shows an example of a framing system 2920 that frames display board 2923 that can be a media display, sensors 2922 attached to an exterior side of framing 2920. Framing 2920 houses a projector 2924. Projector 2924 can project a word and/or an image. For example, the projector can project a directory sign suggesting a user where to stand (e.g., similar to projected image 342 projecting image 346 in FIG. 3). The projector 2924 is disposed such that it is aligned with an edge of the opaque board 2907 to be able to project the image in a manner unobstructed by the display board. Framing 2920 houses a dispenser 2927 (e.g., dispensing disinfectant or another sanitary substance such as liquid, foam, or gel). Framing 2920 is configured to frame transparent boards such as 2925 (e.g., windows). Framing 2920 is configured to house network, communication, and/or control related devices in casing 2926. Framing system 2920 is constructed as a 2×2 matrix that can house various boards such as opaque board, display board 2923, and transparent board 2925. Framing system 2920 is another depiction of framing system 2900 in which the opaque board 2907 is removed. Framing system 2920 includes a service opening 2929 (e.g., to service electronic components such as processor(s), and/or wiring) as part of the casing 2926, and a wiring opening 2930 (e.g., that facilitates operatively coupling (e.g., connecting) the framing system to the network (e.g., local network of the facility).

FIG. 29 shows an example of a framing system 2940 that is a representation of a back of framing system 2900. Framing system 2940 frames display opaque boards 2941a and 2941b. Area 2942 indicates where the dispenser is located between the back opaque board 2941b and the front opaque board 2907, which back and front directions are relative to an intended user of the interactive framing system. Framing 2940 is configured to frame transparent boards 2945a and 2945b (e.g., windows). Framing 2940 is configured to house network, communication, and/or control related devices in casing 2946. Framing system 2940 shows an example of framing portions supporting transparent board 2945a and 2945b that are flush together having a linear border 2948 (e.g., a butt joint); and framing portions supporting opaque board 2941a and 2941b that are staggered together having border 2949 (e.g., a dovetail joint).

FIG. 29 shows an example of a framing system 2980 that is a representation of framing system 2900 in which the casing 2906 is open. Framing system 2980 is configured to house network, communication, and/or control related devices in casing 2986 in which a processor 2985 is disposed, which processor is operatively coupled to the network (e.g., to power and communication), and is operatively coupled to the sensors, projector, dispenser, and any media display (e.g., 2903 can be a media display) framed by the framing system. The framing system can be configured to standalone in a space (e.g., in a room), or can be disposed adjacent to a wall. For example, back boards 2491a and 2941b can face the wall. Framing system 2980 includes wiring opening 2990 (e.g., that facilitates operatively coupling (e.g., connecting) the framing system to the network (e.g., local network of the facility).

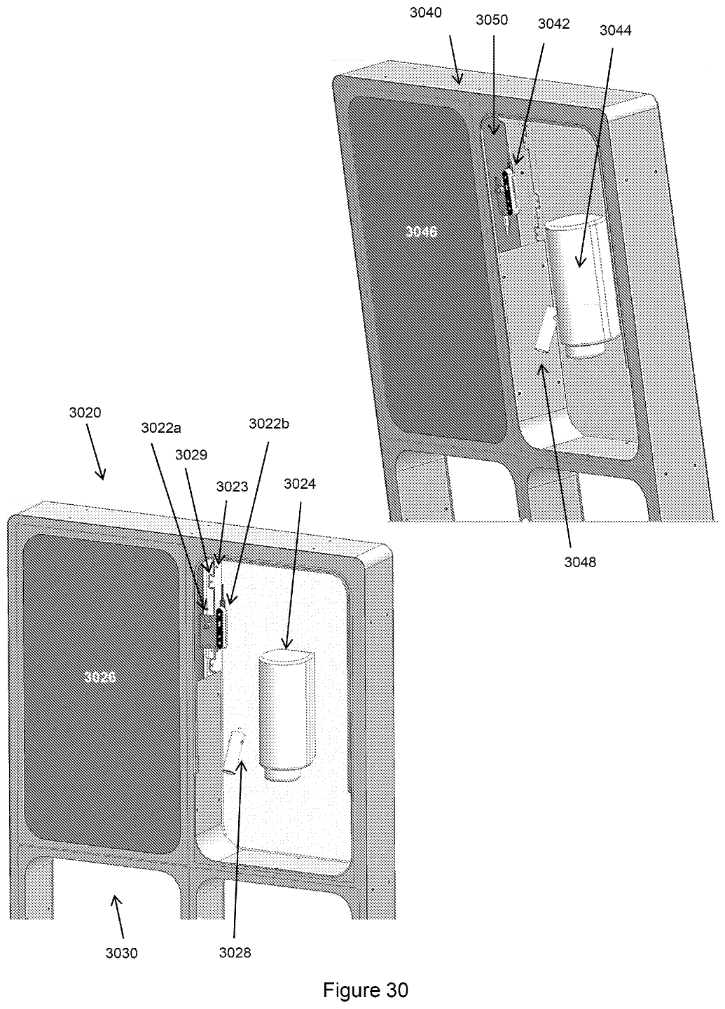

FIG. 30 shows an example of framing system 3020 that frames display board 3026 that can be a media display, sensors 3022a and 3022b attached to an exterior side of framing 3020. Framing 3020 houses a projector 3028. Projector 3028 can project a word or an image. For example, the projector can project a directory sign suggesting a user where to stand (e.g., similar to projected image 342 projecting image 346 in FIG. 3). Projector 3024 is disposed such that it is aligned with an edge of the opaque board 2907 to be able to project the image in a manner unobstructed by the display board. Framing 3020 houses a dispenser 3024 (e.g., dispensing disinfectant or another sanitary substance such as liquid, foam, or gel). Framing 3020 is configured to frame transparent boards such as 3030 (e.g., windows). Framing system 3020 is a magnification of framing system 2920. Framing system 3020 depicts staggered connection 3029 between the framing partition of display board 3026 and the framing portion housing sensors 3022a and 3022b, projector 3028, and dispenser 3024. Each portions of the staggered connection are fastened by screws such as 3023.

FIG. 30 shows an example of framing system 3040 that depicts another angle of framing system 3040 that houses the dispenser 3044, projector 3048, and sensors 3042 attached to an external side of framing 3048. Part of an interior of framing system 3040 is exposed in 3050. This exposed portion at least partially covered by opaque board 2907 and 2941b, and is separated from reach of the user.

In some embodiments, the interactive framing system is configured to service user(s) on one of its sides. In some embodiments, the interactive framing system is configured to service user(s) on both of its sides. FIG. 29 shows various representation of an interactive framing system as 2900, 2920, 2940, and 2980. The framing system shown in FIG. 29 is configured to service a user at its frontal side shown in 2900, and not service any user in its back side shown in 2940. However, the framing system can be also interactive at the back side. For example, opaque board 2941b can substituted by a media display or a bulletin board. For example, opaque board 2941a can be substituted for opaque board such as 2907 that allows a user to reach into a cavity such as 2908, and facilitate any of the framing system functionalities such as operatively coupling to one or more sensors (e.g., 2922, 2924), one or more emitters, disinfectant dispenser, hygienic dispenser, medication dispenser, medical equipment dispenser, equipment dispenser such as tool dispenser (e.g., screws and/or bolds), and/or dispenser configured to dispenser protective gear (e.g., gloves, goggles and/or masks). The interactive framing can be disposed in a factory, in a medical facility, in a bank, in a hotel, in a shopping center, in a restaurant, in an educational facility (e.g., school, college or university), in an office building, in a mass transit station (e.g., train station, or an airport), or in a governmental building. The interactive framing can be disposed in a residential building such as an apartment complex.

While preferred embodiments of the present invention have been shown, and described herein, it will be obvious to those skilled in the art that such embodiments are provided by way of example only. It is not intended that the invention be limited by the specific examples provided within the specification. While the invention has been described with reference to the afore-mentioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations, or relative proportions set forth herein which depend upon a variety of conditions and variables. It should be understood that various alternatives to the embodiments of the invention described herein might be employed in practicing the invention. It is therefore contemplated that the invention shall also cover any such alternatives, modifications, variations, or equivalents. It is intended that the following claims define the scope of the invention and that methods and structures within the scope of these claims and their equivalents be covered thereby.

1. A method for tracking a plurality of individuals in a facility, comprising:
(a) using a sensor system to sense a first identity having a first position at a first time and a second identity having a second position at a second time, wherein the sensor system is operatively coupled to a local network disposed in the facility, which sensor system comprises a plurality of sensors configured to sense and/or identify the first identity, the first position, the first time, the second identity, the second position, and the second time, which local network is configured to facilitate control of at least one other device of the facility;
(b) tracking movement of the first identity over a time period to generate a first tracking information, and tracking movement of the second identity over the time period to generate a second tracking information; and
(c) evaluating a distance from the first tracking information to the second tracking information relative to a distance threshold.

2. The method of claim 1, wherein the plurality of sensors includes a plurality of geolocation sensors that are time synchronized.

3. The method of claim 1, wherein the sensor system is comprised of a device ensemble mounted at a fixed location in the facility.

4. The method of claim 1, further comprising:
(d) associating the first position and the first time with the first identity to generate a first association, and associating the second position and the second time with the second identity to generate a second association; and
(e) comparing the first association with the second association to evaluate a distance from the first identity to the second identity relative to the distance threshold.

5. The method of claim 1, further comprising evaluating whether the first tracking information and the second tracking information were at a distance below the distance threshold for a cumulative time relative to a time threshold.

6-7. (canceled)

8. The method of claim 1, further comprising using the local network to transmit at least a fourth generation, or a fifth generation cellular communication and data comprising media.

9-10. (canceled)

11. The method of claim 1, further comprising using the network to control a tintable window disposed in the facility.

12-27. (canceled)

28. A method for monitoring disinfection of surfaces of a facility, comprising:
(A) using a sensor system to sense a plurality of temperature samples of an object surface at a plurality of sample times, which sensor system is disposed in the facility and is operatively coupled to a local network of the facility, which local network is configured to control at least one other device of the facility that is operatively coupled to the local network;
(B) comparing consecutive temperature samples of the plurality of temperature samples to generate a comparison;
(C) detecting a cleaning event when the comparison indicates a temperature drop below a temperature threshold;
(E) monitoring an elapsed time since a last cleaning event; and
(F) generating a notification when the elapsed time exceeds a time threshold.

29. The method of claim 28, wherein the sensor system is coupled to a local network disposed in the facility in which the object surface is disposed.

30. The method of claim 29, further comprising using the local network to transmit data comprising media.

31. The method of claim 28, wherein the sensor system remotely senses the temperature samples.

32. The method of claim 28, wherein the sensor system is operatively coupled to a hierarchical control system comprising a plurality of controllers.

33-39. (canceled)

40. A method of detecting a bodily characteristic of an individual in a facility, comprising:
(a) using a sensor system to sense an environmental characteristic in presence of the individual on a plurality of occasions, which sensor system is disposed in the facility and is operatively coupled to a local network that is configured to facilitate control of at least one other device of the facility;
(b) analyzing (i) the plurality of environmental characteristic data samples, and (ii) a threshold indicative of abnormal bodily characteristic, to generate an analysis; and
(c) using the analysis to generate a report of presence and/or absence of the indication of abnormal bodily characteristic of the individual.

41. The method of claim 40, wherein the environmental characteristic is detectibly perturbed by the presence of the individual, as compared to absence of the individual from the environment.

42. The method of claim 40, wherein collecting a plurality of environmental characteristic data samples of the individual for the plurality of occasions is to quantify a normal bodily characteristic of the individual, wherein the analysis further comprises analyzing a relative difference between a recent one of the data samples and the normal qualified, and wherein the threshold is a difference threshold.

43. The method of claim 40, wherein the sensor system comprises an electromagnetic sensor.

44. The method of claim 40, wherein the sensor system comprises a first electromagnetic sensor configured to detect a first radiation range, and a second electromagnetic sensor configured to detect a second radiation range having at least one portion that does not overlap the first radiation range.

45. The method of claim 40, further comprising focusing at least one sensor of the sensor system on one or more facial landmark features of the individual to measure the environmental characteristics.

46. The method of claim 40, further comprising focusing at least one sensor of the sensor system on depth placement of the individual to measure the environmental characteristics.

47. The method of claim 40, wherein evaluating the characteristic comprises filtering environmental characteristics attributed to the background.

48-60. (canceled)
